(19) United States
(12) Patent Application Publication
(10) Pub. No.: US 2011/0111342 A1
(43) Pub. Date: May 12, 2011

(54) PHOTORESIST COMPOSITION

(75) Inventors: Koji ICHIKAWA, Osaka (JP); Kazuhiko HASHIMOTO, Osaka (JP); Jung Hwan HAH, Osaka (JP)

(73) Assignee: SUMITOMO CHEMICAL COMPANY LIMITED, Tokyo (JP)

(21) Appl. No.: 12/941,408

(22) Filed: Nov. 8, 2010

(30) Foreign Application Priority Data
Nov. 10, 2009 (JP) 2009-256692

(51) Int. Cl. G03F 7/004; G03F 7/20

(52) U.S. Cl. 430/270.1; 430/325

(57) ABSTRACT

The present invention provides a photoresist composition comprising a resin comprising a structural unit derived from a compound represented by the formula (I):

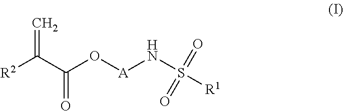

wherein R¹ represents a C1-C6 fluorine-containing alkyl group, R² represents a hydrogen atom or a methyl group, and A represents a C1-C10 divalent saturated hydrocarbon group, and being insoluble or poorly soluble in an aqueous alkali solution but becoming soluble in an aqueous alkali solution by the action of an acid, and an acid generator represented by the formula (II):

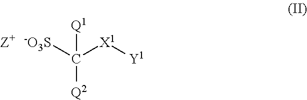

wherein Q¹ and Q² each independently represent a fluorine atom or a C1-C6 perfluoroalkyl group, X¹ represents a single bond or a C1-C17 divalent saturated hydrocarbon group in which one or more —CH₂— can be replaced by —O— or —CO—,
Y¹ represents a C1-C36 aliphatic hydrocarbon group which can have one or more substituents, etc., and Z⁺ represents an organic counter cation.

This nonprovisional application claims priority under 35 U.S.C. §119(a) on Patent Application No. 2009-256692 filed in JAPAN on Nov. 10, 2009, the entire contents of which are hereby incorporated by reference.

### FIELD OF THE INVENTION

The present invention relates to a photoresist composition.

### BACKGROUND OF THE INVENTION

A photoresist composition is used for semiconductor microfabrication employing a lithography process.

JP 2009-237379 A1 discloses a photoresist composition comprising a resin (X1) having structural units derived from a monomer represented by the formula (D), a monomer represented by the formula (B) and a monomer represented by the formula (J), a resin (X2) having structural units derived from a monomer represented by the formula (D), a monomer represented by the formula (B), a monomer represented by the formula (J) and a monomer represented by the formula (K), and tolyldiphenylsulfonium perfluorobutanesulfonate as an acid generator.

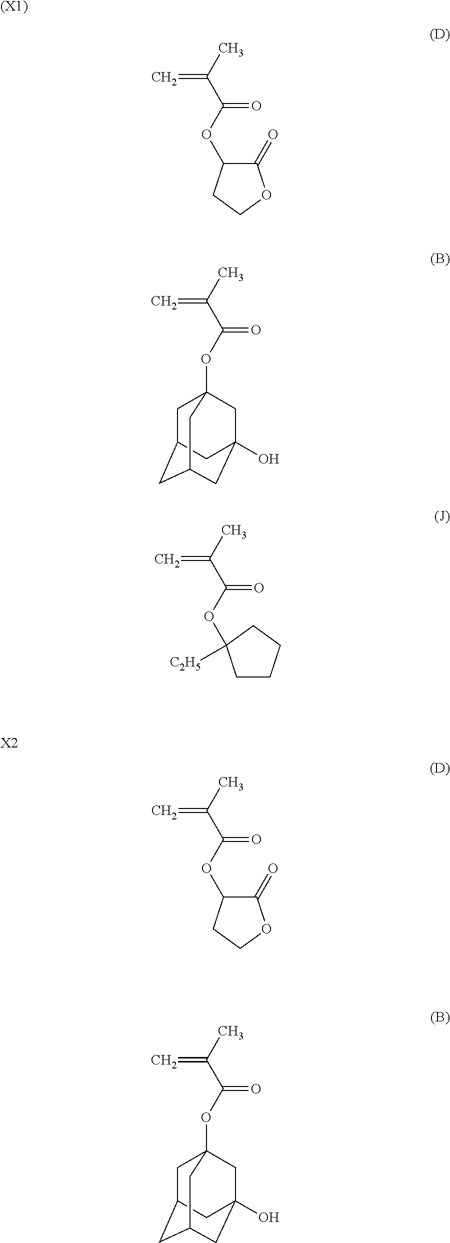

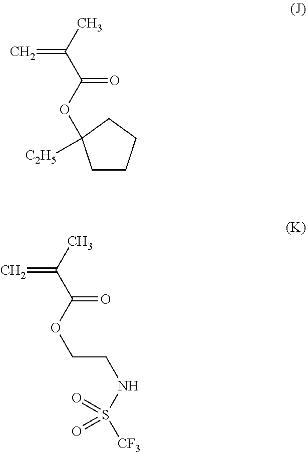

### SUMMARY OF THE INVENTION

The present invention is to provide a photoresist composition.

The present invention relates to the followings:

<1> A photoresist composition comprising a resin comprising a structural unit derived from a compound represented by the formula (I):

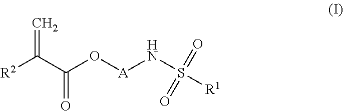

wherein R¹ represents a C1-C6 fluorine-containing alkyl group, R² represents a hydrogen atom or a methyl group, and A represents a C1-C10 divalent saturated hydrocarbon group, and being insoluble or poorly soluble in an aqueous alkali solution but becoming soluble in an aqueous alkali solution by the action of an acid, and an acid generator represented by the formula (II):

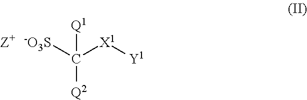

wherein Q¹ and Q² each independently represent a fluorine atom or a C1-C6 perfluoroalkyl group, X¹ represents a single bond or a C1-C17 divalent saturated hydrocarbon group in which one or more —CH₂— can be replaced by —O— or —CO—,
Y¹ represents a C1-C36 aliphatic hydrocarbon group which can have one or more substituents, a C3-C36 saturated cyclic hydrocarbon group which can have one or more substituents, or a C6-C36 aromatic hydrocarbon group which can have one or more substituents, and one or more —CH₂— in the aliphatic hydrocarbon group and the saturated cyclic hydrocarbon group can be replaced by —O— or —CO—, and Z⁺ represents an organic counter cation;
<2> The photoresist composition according to <1>, wherein X¹ is *—CO—O—X³— wherein X³ represents a single bond or a C1-C15 alkylene group and * represents a binding position to —C(Q¹)(Q²)—;
<3> The photoresist composition according to <1> or <2>, wherein Z⁺ is a triarylsulfonium cation;
<4> The photoresist composition according to any one of <1> to <3>, which further comprises a basic compound;
<5> A process for producing a photoresist pattern comprising the following steps (1) to (5):

(1) a step of applying the photoresist composition according to any one of <1> to <4> on a substrate,

(2) a step of forming a photoresist film by conducting drying,

(3) a step of exposing the photoresist film to radiation,

(4) a step of baking the exposed photoresist film, and

(5) a step of developing the baked photoresist film with an alkaline developer, thereby forming a photoresist pattern.

### DESCRIPTION OF PREFERRED EMBODIMENTS

The photoresist composition of the present invention comprises a polymer comprising a structural unit derived from a compound represented by the formula (I):

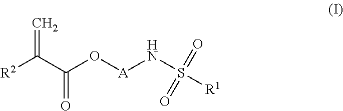

wherein R¹ represents a C1-C6 fluorine-containing alkyl group, R² represents a hydrogen atom or a methyl group, and A represents a C1-C10 divalent saturated hydrocarbon group (hereinafter, simply referred to as Compound (I)), and being insoluble or poorly soluble in an aqueous alkali solution but becoming soluble in an aqueous alkali solution by the action of an acid (hereinafter, simply referred to as Resin (A)).

Resin (A) is insoluble or poorly soluble in an alkali aqueous solution but becomes soluble in an alkali aqueous solution by the action of an acid, and comprises a structural unit derived from Compound (I).

Examples of the C1-C6 fluorine-containing alkyl group include a difluoromethyl group, a perfluoromethyl group, a 1,1-difluoroethyl group, a 2,2-difluoroethyl group, a 2,2,2-trifluoroethyl group, a perfluoroethyl group, a 1,1,2,2-tetrafluoropropyl group, a 1,1,2,2,3,3-hexafluoropropyl group, a perfluoroethylmethyl group, a 1-(trifluoromethyl)-1,2,2,2-tetrafluoroethyl group, a perfluoropropyl group, 1,1,2,2-tetrafluorobutyl group, a 1,1,2,2,3,3-hexafluorobutyl group, 1,1,2,2,3,3,4,4-octafluorobutyl group, a perfluorobutyl group, a 1,1-bis(trifluoromethyl)-2,2,2-trifluoroethyl group, a 2-(perfluoropropyl)ethyl group, a 1,1,2,2,3,3,4,4-octafluoropentyl group, a perfluoropentyl group, a 1,1,2,2,3,3,4,4,5,5-decafluoropentyl group, a 1,1,-bis(trifluoromethyl)-2,2,3,3,3-pentafluoropropyl group, a 2-(perfluorobutyl)ethyl group, a 1,1,2,2,3,3,4,4,5,5-decafluorohexyl group, a 1,1,2,2,3,3,4,4,5,5,6,6-dodecafluorohexyl group, a perfluoropentylmethyl group and a perfluorohexyl group.

R¹ is preferably a C1-C4 fluorine-containing alkyl group, is more preferably a C1-C4 perfluoroalkyl group, and is still more preferably a perfluoromethyl group, a perfluoroethyl group or a perfluoropropyl group, and especially preferably a perfluoromethyl group.

Examples of the C1-C10 divalent saturated hydrocarbon group include a C1-C10 linear alkanediyl group such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group and a decane-1,10-diyl group; a C2-C10 branched alkanediyl group such as a propane-1,2-diyl group, a 1-methylpropane-1,3-diyl group, a 2-methylpropane-1,3-diylgroup, a 2-methylpropane-1,2-diyl group, a 1-methylbutane-1,4-diyl group and a 2-methylbutane-1,4-diyl group; a C2-C10 alkylidene group such as an ethylidene group, a propylidene group and an isopropylidene group; a C3-C10 cycloalkanediyl group such as a cyclobutane-1,3-diyl group, a cyclopentane-1,3-diyl group, a cyclohexane-1,4-diyl group and a cyclooctane-1,5-diyl group; a C7-C10 divalent saturated cyclic hydrocarbon group such as a norbornane-1,4-diyl group, a norbornane-2,5-diyl group, an admantane-1,5-diyl group and an adamantane-2,6-diyl group; and groups formed by combining two or more above-mentioned groups.

Examples of Compound (I) include the followings.

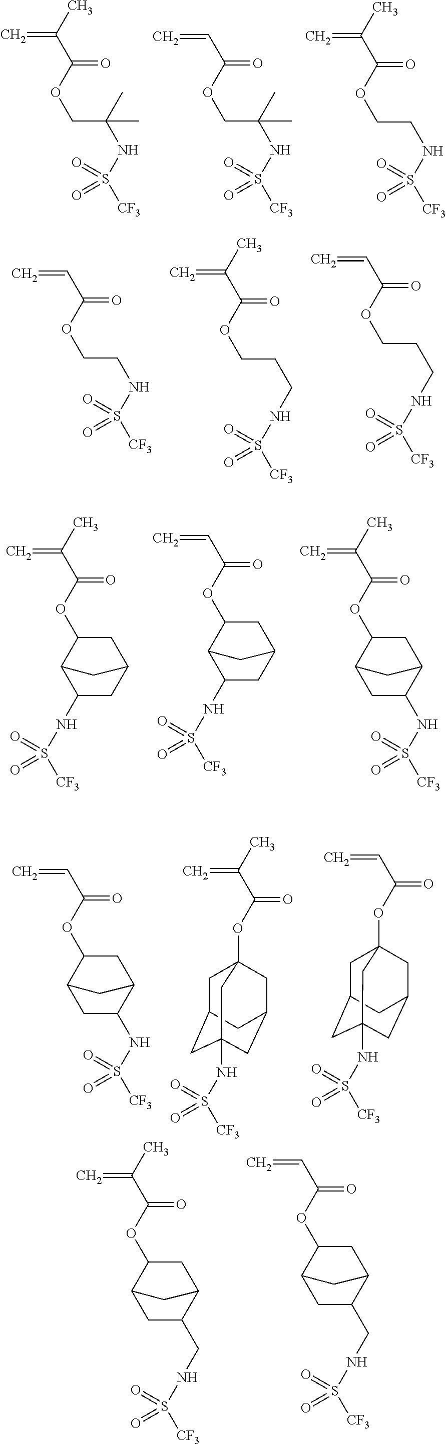

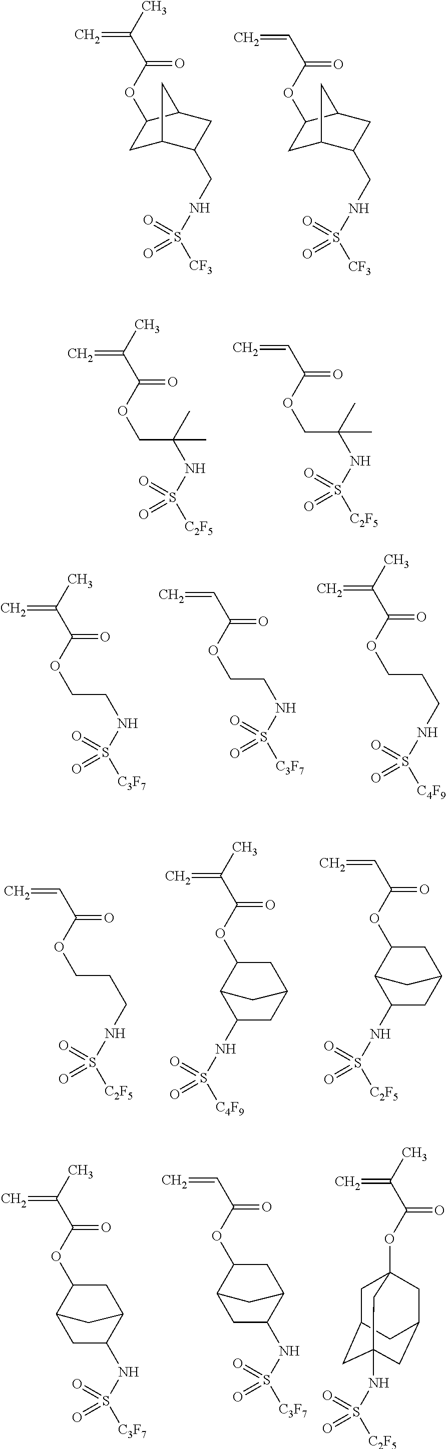

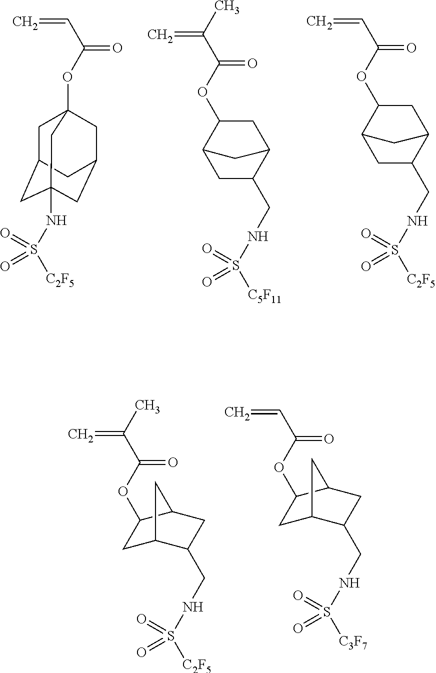

The content of the structural unit derived from Compound (I) in Resin (A) is usually 1 to 30% by mole, preferably 3 to 25% by mole and more preferably 5 to 20% by mole based on 100% by mole of all the structural units of Resin (A).

Resin (A) can have two or more kinds of structural units derived from Compound (I).

Resin (A) usually has a structural unit derived from a monomer having an acid-labile group, and can be produced by polymerizing one or more monomers having an acid-labile group with Compound (I).

In this specification, “an acid-labile group” means a group capable of being eliminated by the action of an acid.

Examples of the acid-labile group include a group represented by the formula (I):

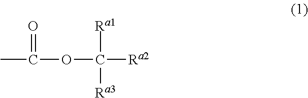

wherein R^{a1}, R^{a2} and R^{a3} independently each represent an aliphatic hydrocarbon group or a saturated cyclic hydrocarbon group, and R^{a1} and R^{a2} can be bonded each other to form a ring together with a carbon atom to which R^{a1} and R^{a2} are bonded.

Examples of the aliphatic hydrocarbon group include a C1-C8 alkyl group. Specific examples of the C1-C8 alkyl group include a methyl group, an ethyl group, a propyl group, an isopropyl group, a butyl group, a pentyl group, a hexyl group, a heptyl group and an octyl group. The saturated cyclic hydrocarbon group may be monocyclic or polycyclic, and preferably has 3 to 20 carbon atoms. Examples of the saturated cyclic hydrocarbon group include a monocyclic alicyclic hydrocarbon group such as a C3-C20 cycloalkyl group (e.g. a cyclopentyl group, a cyclohexyl group, a methylcyclohexyl group, a dimethylcyclohexyl group, a cycloheptyl group and a cyclooctyl group) and a polycyclic alicyclic hydrocarbon group such as a decahydronaphthyl group, an adamantyl group, a norbornyl group, a methylnorbornyl group, and the followings:

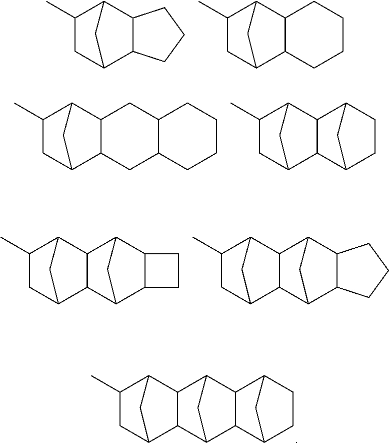

Examples of the ring formed by bonding R^{a1} and R^{a2} each other include the following groups and the ring preferably has 5 to 20 carbon atoms.

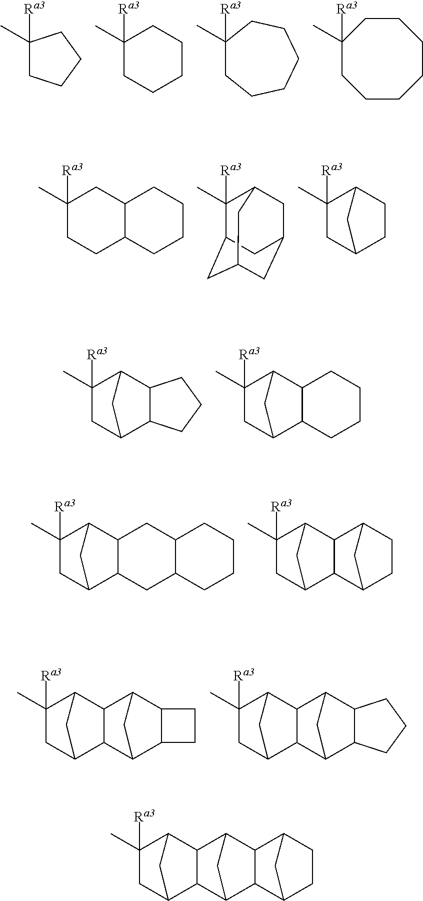

wherein R^{a1} is the same as defined above.

The group represented by the formula (I) wherein R^{a1}, R^{a2} and R^{a3} independently each represent a C1-C8 alkyl group such as a tert-butyl group, the group represented by the formula (I) wherein R^{a1} and R^{2e} are bonded each other to form an adamantyl ring and R^{a3} is a C1-C8 alkyl group such as a 2-alkyl-2-adamantyl group, and the group represented by the formula (I) wherein R^{a1} and R^{a2} are C1-C8 alkyl groups and R^{a3} is an adamantyl group such as a 1-(1-adamantyl)-1-alkylalkoxycarbonyl group are preferable.

The monomer having an acid-labile group is preferably an acrylate monomer having an acid-labile group in its side chain or a methacryalte monomer having an acid-labile group in its side chain. In this specification, “(meth)acrylate monomer” means a monomer having a structure represented by CH₂═CH—CO— or CH₂═C(CH₃)—CO—, and “acrylate monomer” means a monomer having a structure represented by CH₂═CH—CO—, and “methacrylate monomer” means a monomer having a structure represented by CH₂═C(CH₃)—CO—.

Preferable examples of the monomer having an acid-labile group include (meth)acrylate monomers having C5-C20 saturated cyclic hydrocarbon group. As (meth)acrylate monomers having C5-C20 saturated cyclic hydrocarbon group, preferred are monomers represented by the formulae (a1-1) and (a1-2):

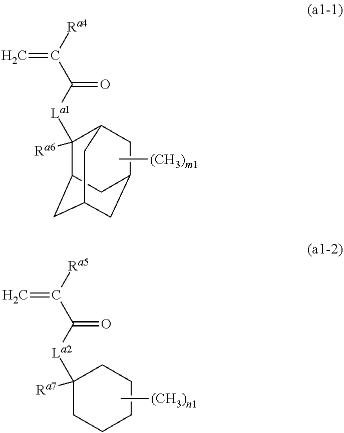

wherein R^{a4} and R^{a5} each independently represents a hydrogen atom or a methyl group, R^{a6} and R^{a7} each independently represents a C1-C8 aliphatic hydrocarbon group or a C3-C10 saturated cyclic hydrocarbon group, L^{a1} and L^{a2} each independently represents *—O— or *—O—(CH₂)ₖ₁—CO—O— in which * represents a binding position to —CO—, and k1 represents an integer of 1 to 7, m1 represents an integer of 0 to 14 and n1 represents an integer of 0 to 10.

The aliphatic hydrocarbon group preferably has 1 to 6 carbon atoms, and the saturated cyclic hydrocarbon group preferably has 3 to 8 carbon atoms and more preferably 3 to 6 carbon atoms.

Examples of the aliphatic hydrocarbon group include a C1-C8 alkyl group such as a methyl group, an ethyl group, a propyl group, an isopropyl group, a butyl group, a tert-butyl group, a 2,2-dimethylethyl group, a 1-methylpropyl group, a 2,2-dimethylpropyl group, a 1-ethylpropyl group, a 1-methylbutyl group, a 2-methylbutyl group, a 3-methylbutyl group, a 1-propylbutyl group, a pentyl group, a 1-methylpentyl group, a hexyl group, a 1,4-dimethylhexyl group, a heptyl group, a 1-methylheptyl group and an octyl group. Examples of the saturated cyclic hydrocarbon group include a cyclohexyl group, a methylcyclohexyl group, a dimethylcyclohexyl group, a cycloheptyl group, a methylcycloheptyl group, a norbornyl group and a methylnorbornyl group.

L^{a1} is preferably *—O— or *—O—(CH₂)_{f1}—CO—O— in which * represents a binding position to —CO—, and f1 represents an integer of 1 to 4, and is more preferably *—O— or *—O—CH₂—CO—O—, and is especially preferably *—O—. L^{a2} is preferably *—O— or *—O—(CH₂)_{f1}—CO—O— in which * represents a binding position to —CO—, and f1 is the same as defined above, and is more preferably *—O— or *—O—CH₂—CO—O—, and is especially preferably *—O—.

In the formula (a1-1), m1 is preferably an integer of 0 to 3, and is more preferably 0 or 1. In the formula (a1-2), n1 is preferably an integer of 0 to 3, and is more preferably 0 or 1.

Particularly when the photoresist composition contains a resin derived from a monomer having a bulky structure such as a saturated cyclic hydrocarbon group, the photoresist composition having excellent resolution tends to be obtained.

Examples of the monomer represented by the formula (a1-1) include the followings.

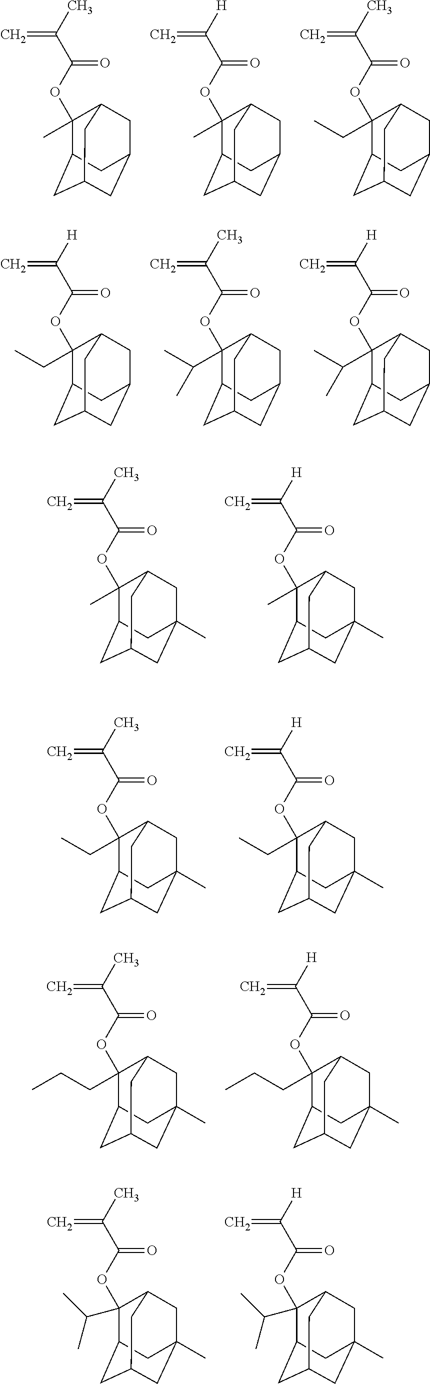

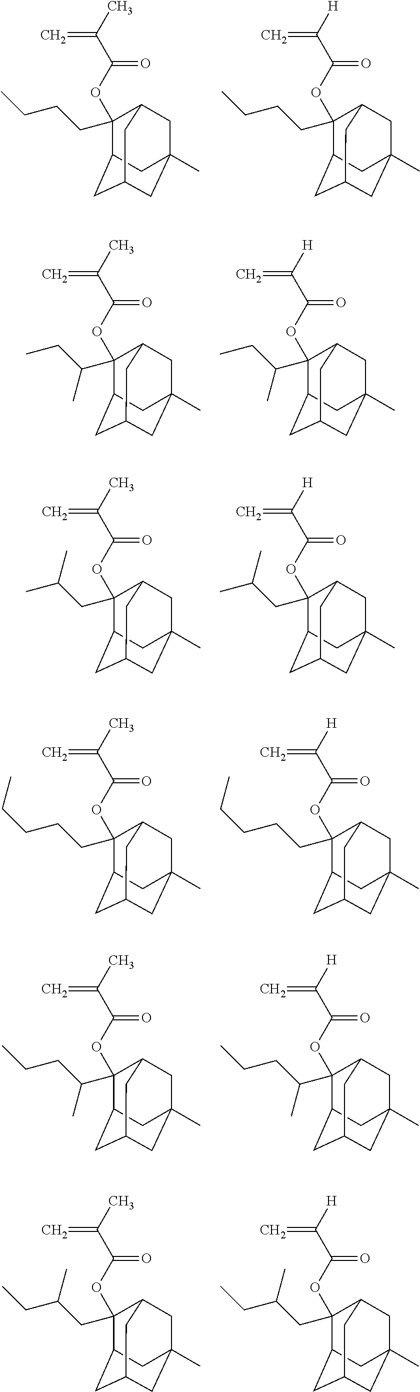

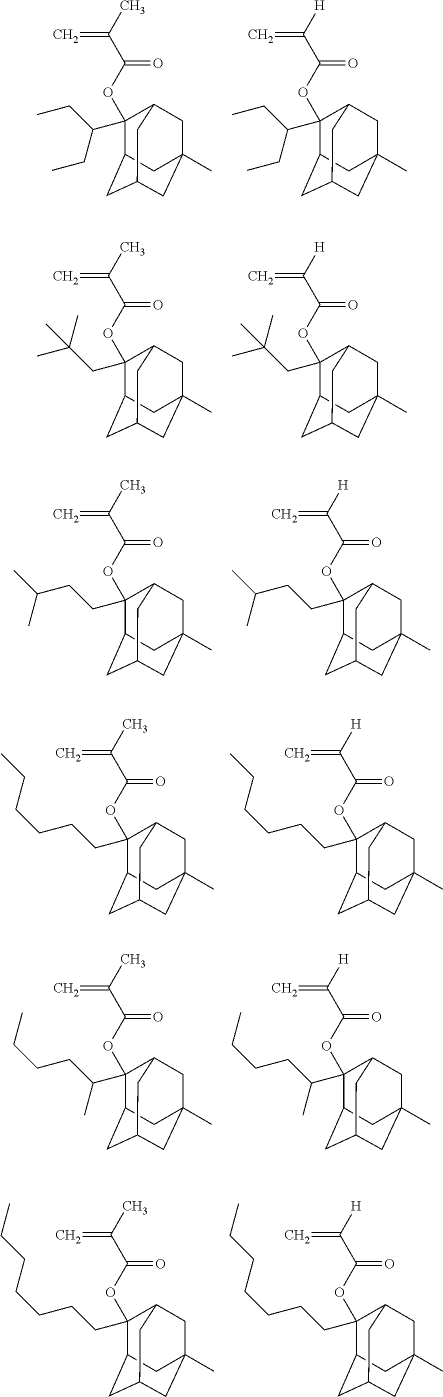

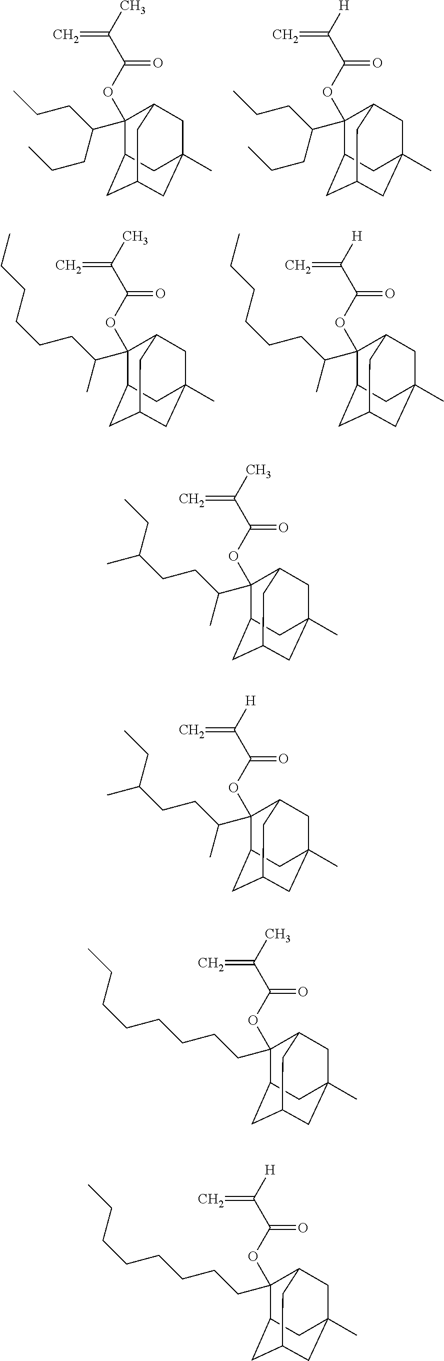

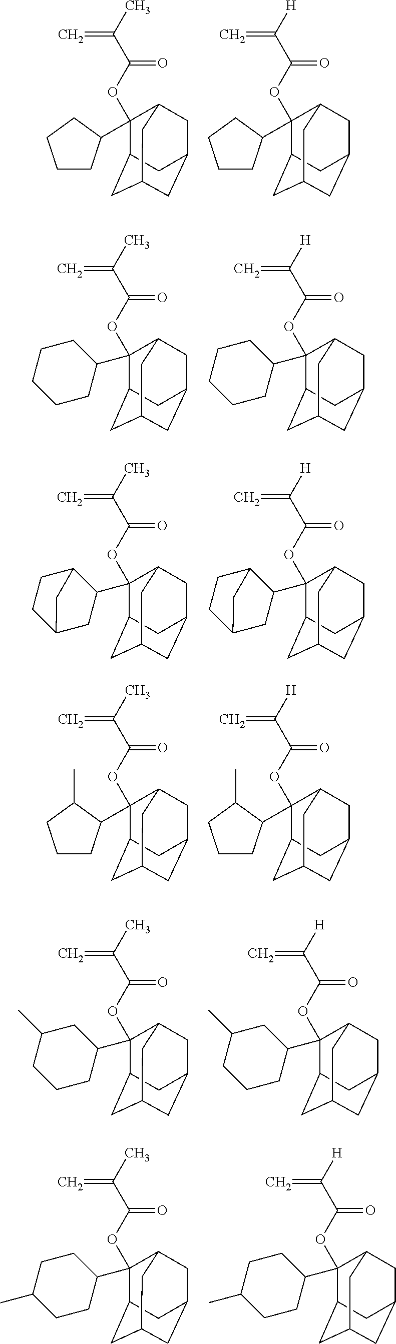

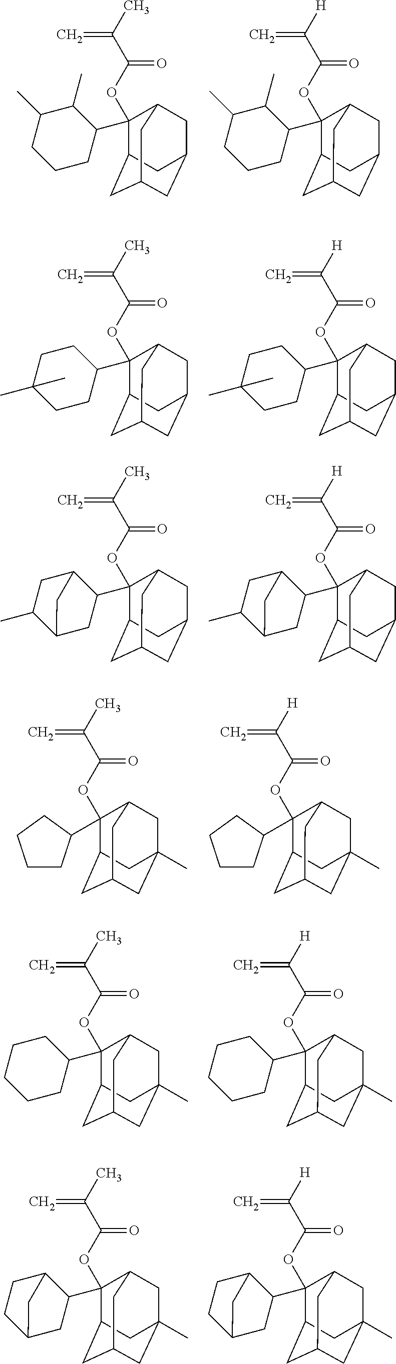

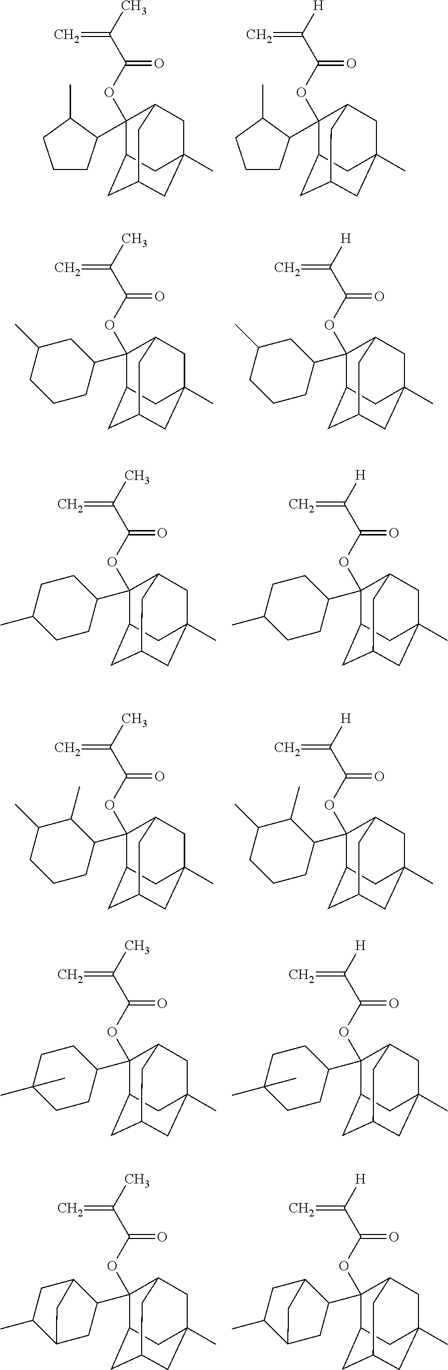

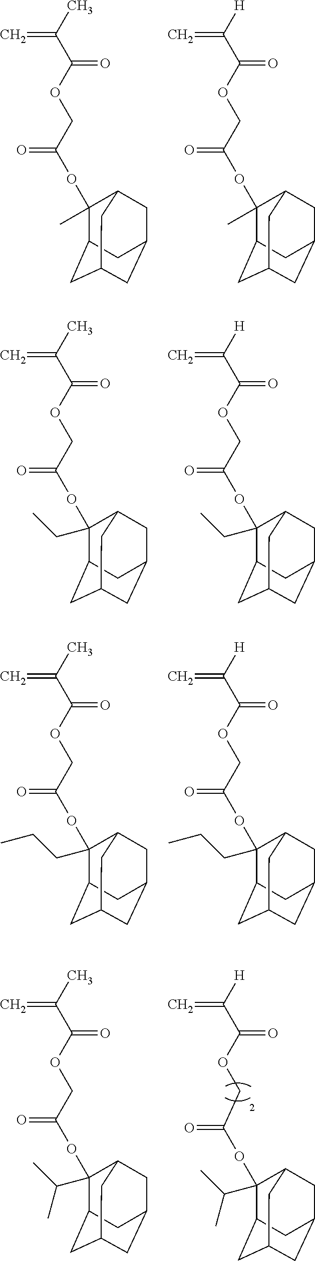

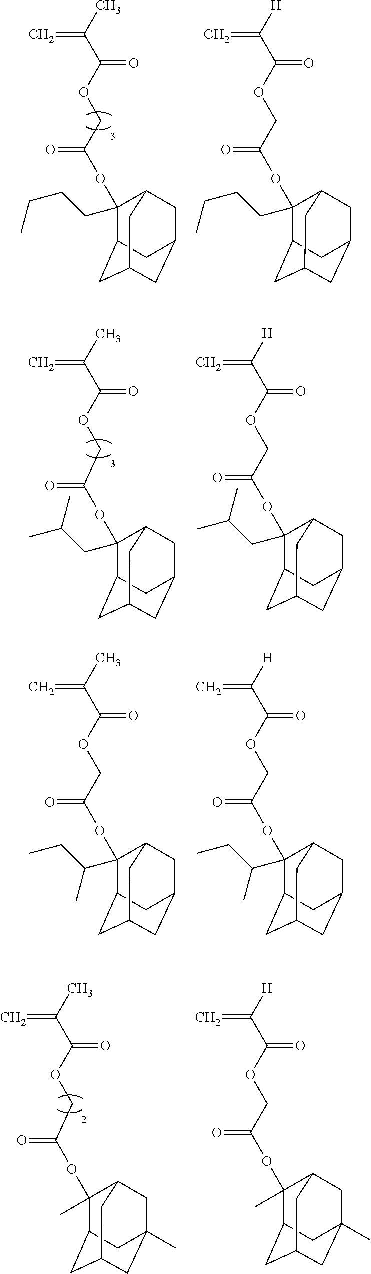

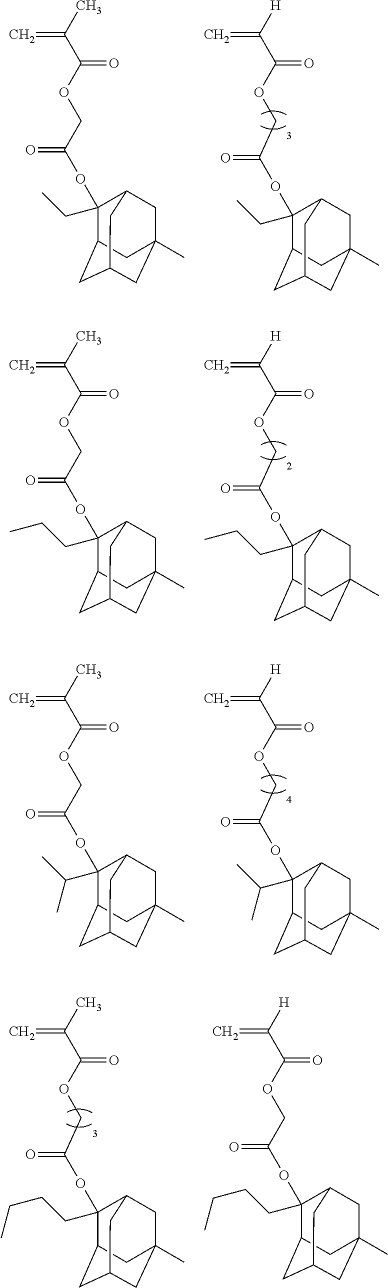

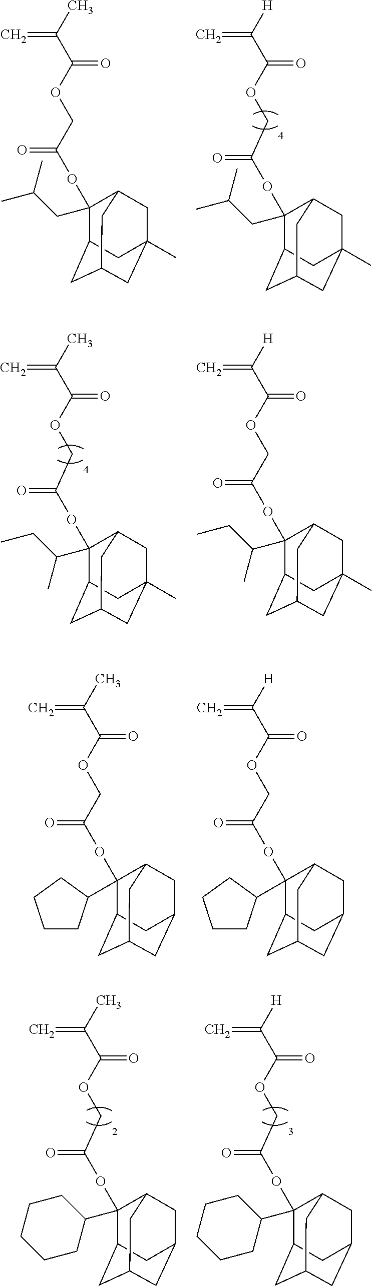

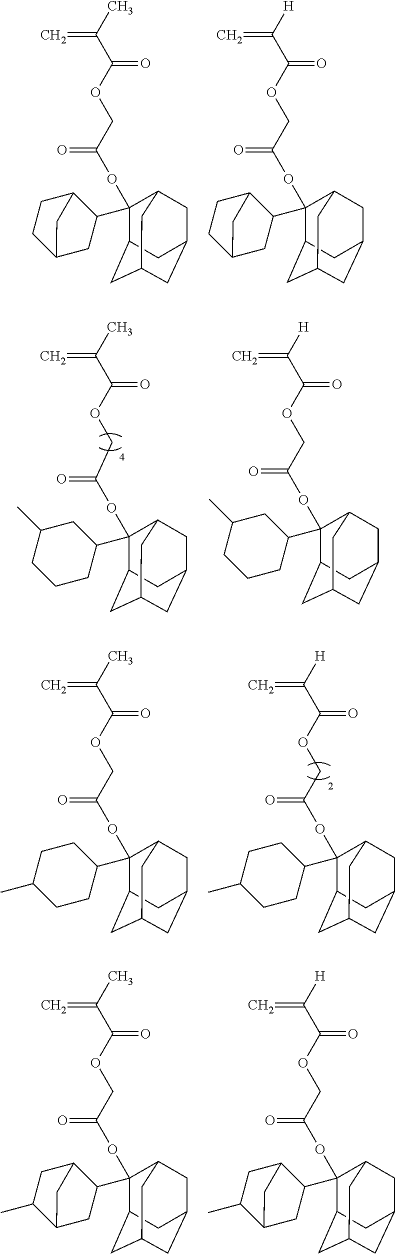

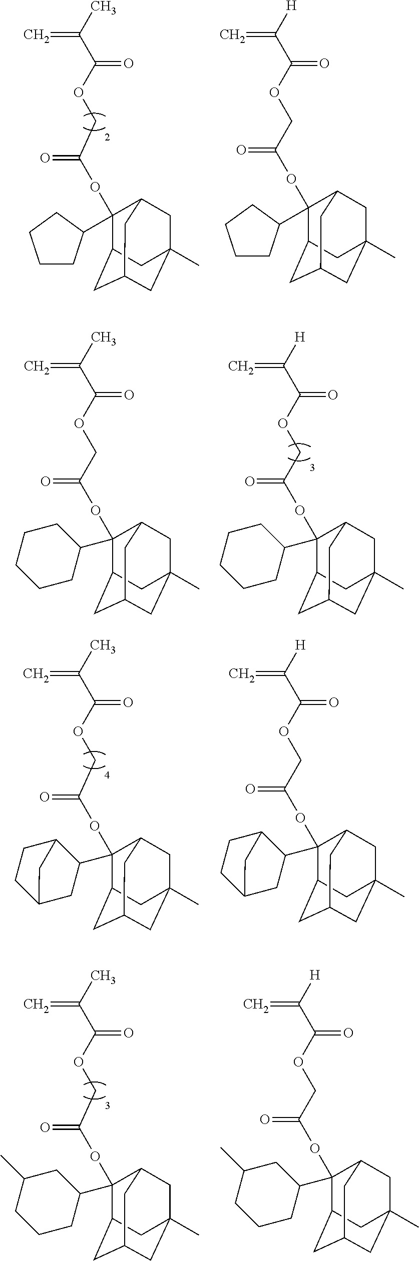

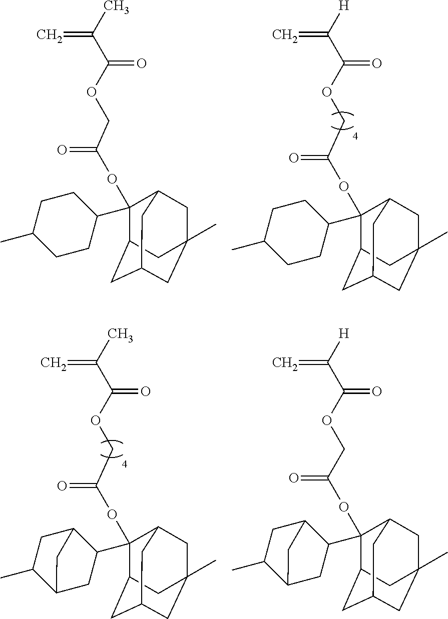

Among them, preferred are 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate and 2-isopropyl-2-adamantyl methacrylate, and more preferred are 2-methyl-2-adamantyl methacrylate, 2-ethyl-2-adamantyl methacrylate, and 2-isopropyl-2-adamantyl methacrylate.

Examples of the monomer represented by the formula (a1-2) include the followings.

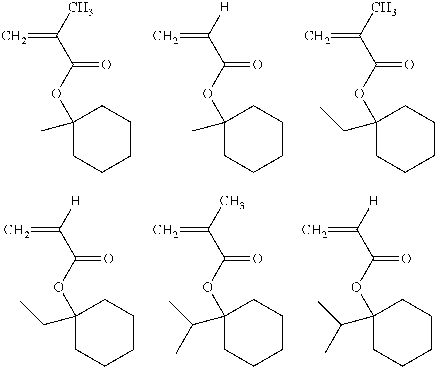

Among them, preferred are 1-ethyl-1-cyclohexyl acrylate and 1-ethyl-1-cyclohexyl methacrylate, and more preferred is 1-ethyl-1-cyclohexyl methacrylate.

The content of the structural unit derived from a monomer having an acid-labile group in Resin (A) is usually 10 to 95% by mole, preferably 15 to 90% by mole and more preferably 20 to 85% by mole based on 100% by mole of all the structural units of Resin (A).

Other examples of the monomer having an acid-labile group include a monomer represented by the formula (a1-3):

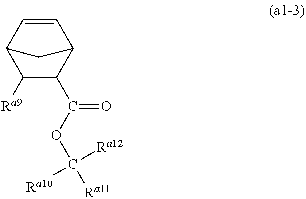

wherein R^{as} represents a hydrogen atom, a C1-C3 aliphatic hydrocarbon group which can have one or more hydroxyl groups, a carboxyl group, a cyano group or a —COOR^{a13} group in which R^{a13} represents a C1-C8 aliphatic hydrocarbon group or a C3-C8 saturated cyclic hydrocarbon group, and the C1-C8 aliphatic hydrocarbon group and the C3-C8 saturated cyclic hydrocarbon group can have one or more hydroxyl groups, and one or more —CH₂— in the C1-C8 aliphatic hydrocarbon group and the C3-C8 saturated cyclic hydrocarbon group can be replaced by —O— or —CO—, R^{a10}, R^{a11} and R^{a12} each indepently represent a C1-C12 aliphatic hydrocarbon group or a C3-C12 saturated cyclic hydrocarbon group, and R^{a10} and R^{a11} can be bonded each other to form a ring together with the carbon atom to which R^{a10} and R^{a11} are bonded, and the C1-C12 aliphatic hydrocarbon group and the C3-C12 saturated cyclic hydrocarbon group can have one or more hydroxyl groups, and one or more —CH₂— in the C1-C12 aliphatic hydrocarbon group and the C3-C12 saturated cyclic hydrocarbon group can be replaced by —O— or —CO—.

Examples of the C1-C3 aliphatic hydrocarbon group which can have one or more hydroxyl groups include a methyl group, an ethyl group, a propyl group, a hydroxymethyl group and a 2-hydroxyethyl group. Examples of R^{a13} include a methyl group, an ethyl group, a propyl group, a 2-oxo-oxolan-3-yl group and a 2-oxo-oxolan-4-yl group. Examples of R^{a10}, R^{a11} and R^{a12} include a methyl group, an ethyl group, a cyclohexyl group, a methylcyclohexyl group, a hydroxycyclohexyl group, an oxocyclohexyl group and an adamantyl group, and examples of the ring formed by bonding R^{a10} and R^{a11} each other together with the carbon atom to which R^{a10} and R^{a11} are bonded include a cyclohexane ring and an adamantane ring.

Examples of the monomer represented by the formula (a1-3) include tert-butyl 5-norbornene-2-carboxylate, 1-cyclohexyl-1-methylethyl 5-norbornene-2-carboxylate, 1-methylcyclohexyl 5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxylcyclohexyl)-1-methylethyl 5-norbornene-2-carboxylate, 1-methyl-1-(4-oxocyclohexyl)ethyl 5-norbornene-2-carboxylate and 1-(1-adamantyl)-1-methylethyl 5-norbornene-2-carboxylate.

When Resin (A) has a structural unit derived from the monomer represented by the formula (a1-3) the photoresist composition having excellent resolution and higher dry-etching resistance tends to be obtained.

When Resin (A) contains the structural unit derived form the monomer represented by the formula (a1-3), the content of the structural unit derived from the monomer represented by the formula (a1-3) is usually 10 to 95% by mole and preferably 15 to 90% by mole and more preferably 20 to 85% by mole based on total molar of all the structural units of Resin (A).

Other examples of the monomer having an acid-labile group include a monomer represented by the formula (a1-4):

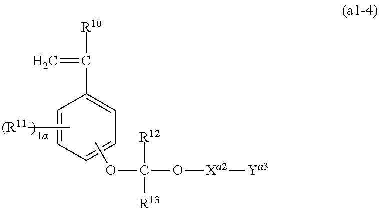

wherein R¹⁰ represents a hydrogen atom, a halogen atom, a C1-C6 alkyl group or a C1-C6 halogenated alkyl group, R¹¹ is independently in each occurrence a halogen atom, a hydroxyl group, a C1-C6 alkyl group, a C1-C6 alkoxy group, a C2-C4 acyl group, a C2-C4 acyloxy group, an acryloyl group or a methacryloyl group, la represents an integer of 0 to 4, R¹² and R¹³ each independently represent a hydrogen atom or a C1-C12 hydrocarbon group, X^{a2} represents a single bond or a C1-C17 divalent saturated hydrocarbon group in which one or more —CH₂— can be replaced by —O—, —CO—, —S—, —SO₂— or —N(R^{c})— wherein R^{c} represents a hydrogen atom or a C1-C6 alkyl group, and which can have one or more substituents, and Y^{a3} represents a C1-C12 aliphatic hydrocarbon group, a C3-C18 saturated cyclic hydrocarbon group or a C6-C18 aromatic hydrocarbon group, and the C1-C12 aliphatic hydrocarbon group, the C2-C18 saturated cyclic hydrocarbon group and the C6-C18 aromatic hydrocarbon group can have one or more substituents.

Examples of the halogen atom include a chlorine atom, a bromine atom and an iodine atom.

Examples of the C1-C6 alkyl group include a methyl group, an ethyl group, a propyl group, an isopropyl group, a butyl group, an isobutyl group, a sec-butyl group, a tert-butyl group, a pentyl group and a hexyl group, and a C1-C4 alkyl group is preferable and a C1-C2 alkyl group is more preferable and a methyl group is especially preferable.

Examples of the C1-C6 halogenated alkyl group include a trifluoromethyl group, a pentafluoroethyl group, a heptafluoropropyl group, a heptafluoroisopropyl group, a nonafluorobutyl group, a nonafluoro-sec-butyl group, a nonafluoro-tert-butyl group, a perfluoropentyl group and a perfluorohexyl group.

R¹⁰ is preferably a hydrogen atom, a methyl group or a trifluoromethyl group, and is more preferably a hydrogen atom or a methyl group.

Examples of the C1-C6 alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group, and a C1-C4 alkoxy group is preferable and a C1-C2 alkoxy group is more preferable and a methoxy group is especially preferable.

Examples of the C2-C4 acyl group include an acetyl group, a propionyl group and a butyryl group, and examples of the C2-C4 acyloxy group include an acetyloxy group, a propionyloxy group and a butyryloxy group.

Examples of the C1-C12 hydrocarbon group include a C1-C12 aliphatic hydrocarbon group such as a methyl group, an ethyl group, a propyl group, an isopropyl group, a butyl group, an isobutyl group, a sec-butyl group, a tert-butyl group, a pentyl group, a hexyl group, a heptyl group, an octyl group, a 2-ethylhexyl group, a nonyl group, a decyl group, an undecyl group and a dodecyl group, and a C3-C12 saturated cyclic hydrocarbon group such as a cyclohexyl group, an adamantyl group, a 2-alkyl-2-adamantyl group, a 1-(1-adamantyl)-1-alkyl group and an isobornyl group.

Examples of the C1-C17 divalent saturated hydrocarbon group include a C1-C17 alkanediyl group such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, a undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group, and a cyclohexane-1,4-diyl group. Examples of the substituents of the C1-C17 divalent saturated hydrocarbon group include a halogen atom such as a fluorine atom, and a hydroxyl group. Examples of the substituted C1-C17 divalent saturated hydrocarbon group include the followings.

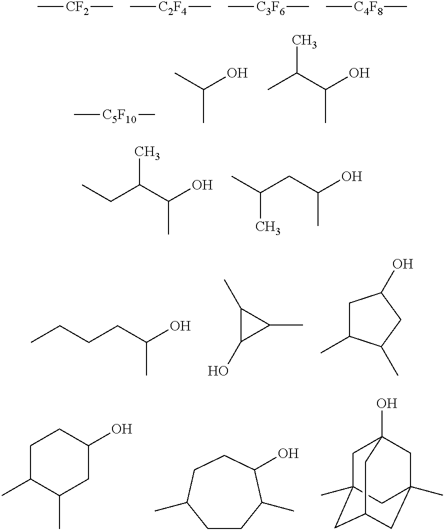

Examples of the C1-C17 divalent saturated hydrocarbon group in which one or more —CH₂— are replaced by —O—, —CO—, —S—, —SO₂— or —N(R^{c})— include the followings.

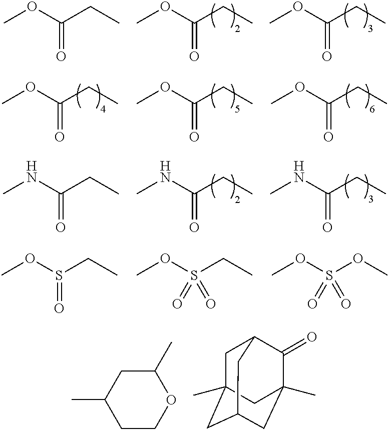

Examples of the C1-C12 aliphatic hydrocarbon group include a methyl group, an ethyl group, a propyl group, an isopropyl group, a butyl group, an isobutyl group, a sec-butyl group, a tert-butyl group, a pentyl group, a hexyl group, a heptyl group, an octyl group, a 2-ethylhexyl group, a nonyl group, a decyl group, an undecyl group and a dodecyl group. Examples of the C3-C18 saturated cyclic hydrocarbon group include a cyclopropyl group, a cyclobutyl group, a cyclopentyl group, a cyclohexyl group, a cycloheptyl group, a cyclooctyl group, a cyclononyl group, a cyclodecyl group, a norbornyl group, a 1-adamantyl group, a 2-adamantyl group, an isobornyl group and the following groups.

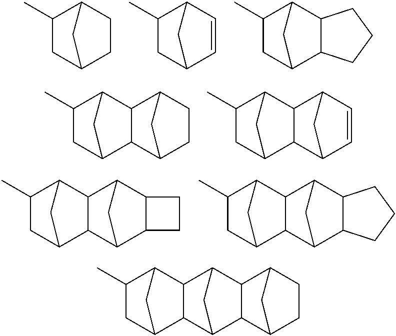

Examples of the C6-C18 aromatic hydrocarbon group include a phenyl group, a naphthyl group, an anthryl group, a p-methylphenyl group, a p-tert-butylphenyl group and a p-adamantylphenyl group.

Examples of the monomer represented by the formula (a1-4) include the followings.

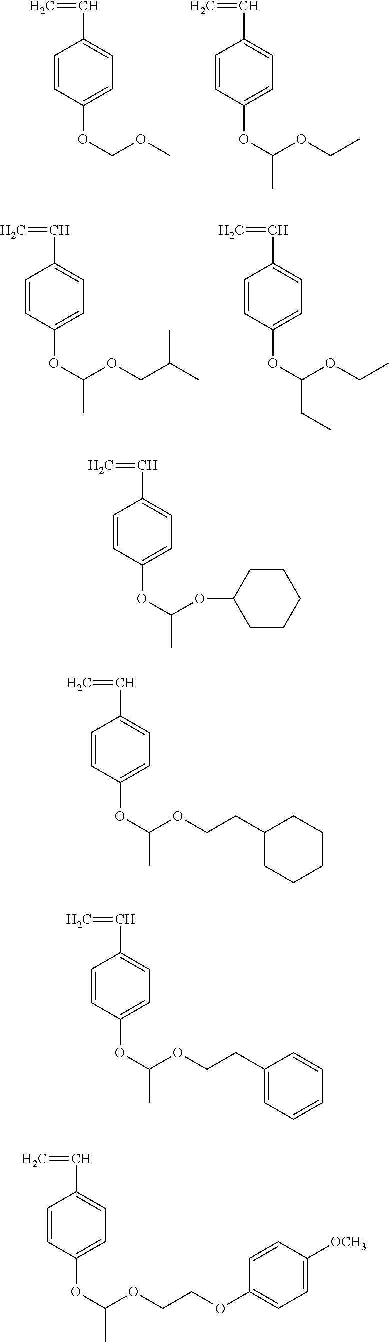

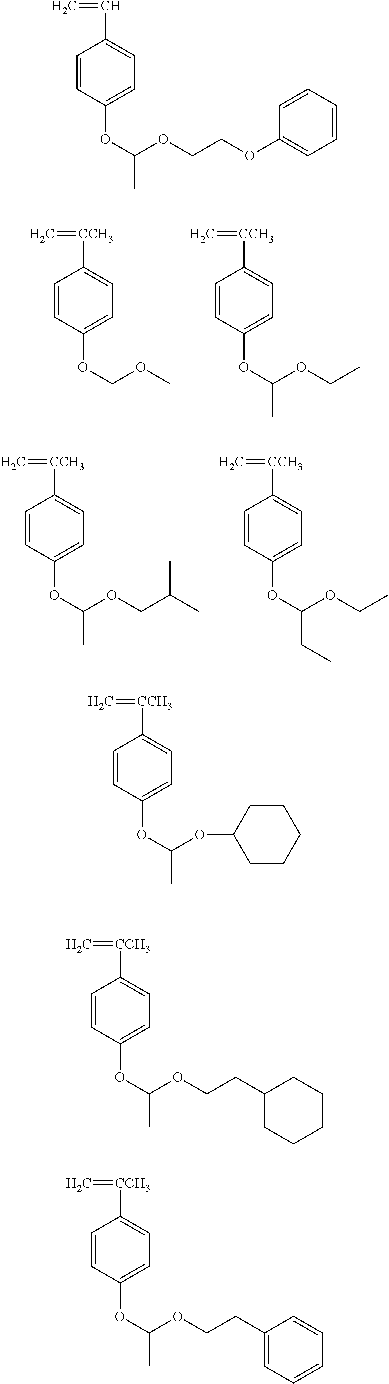

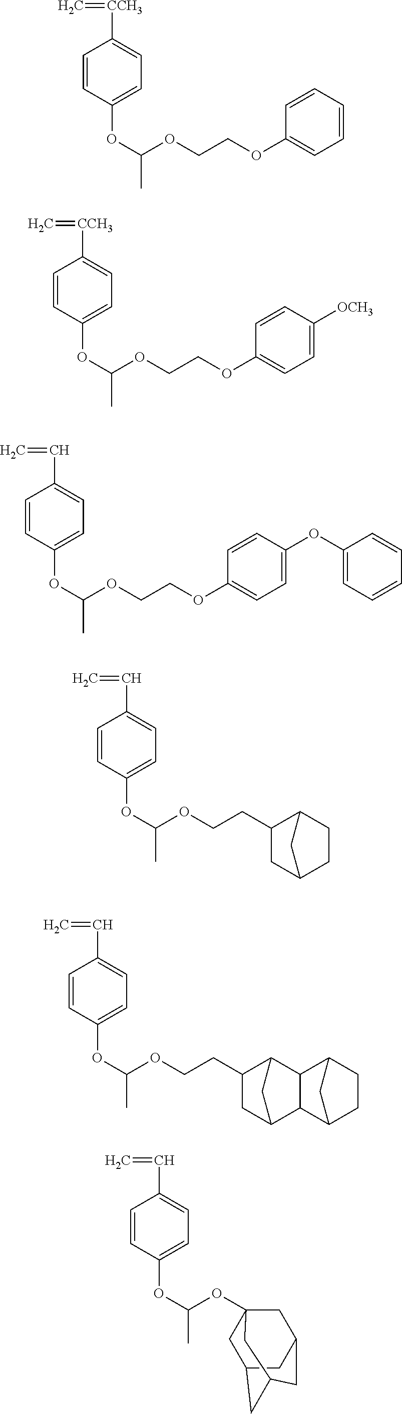

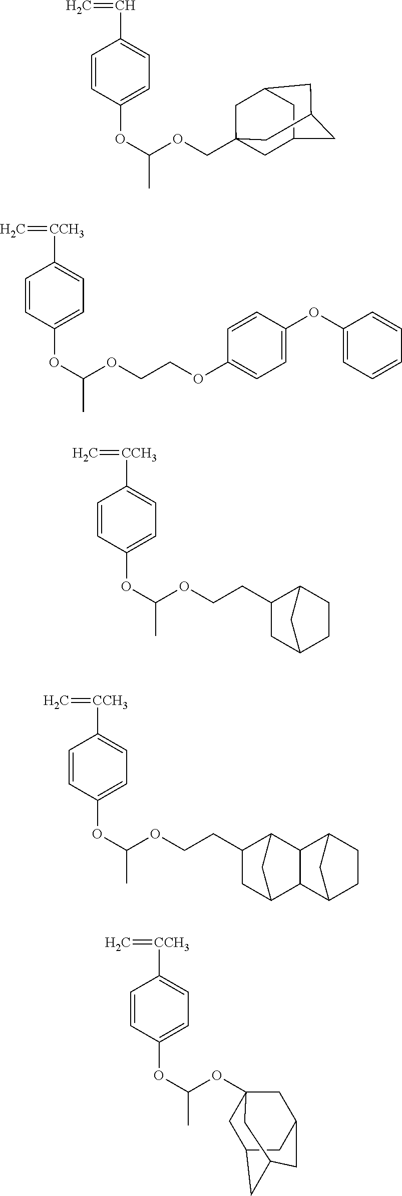

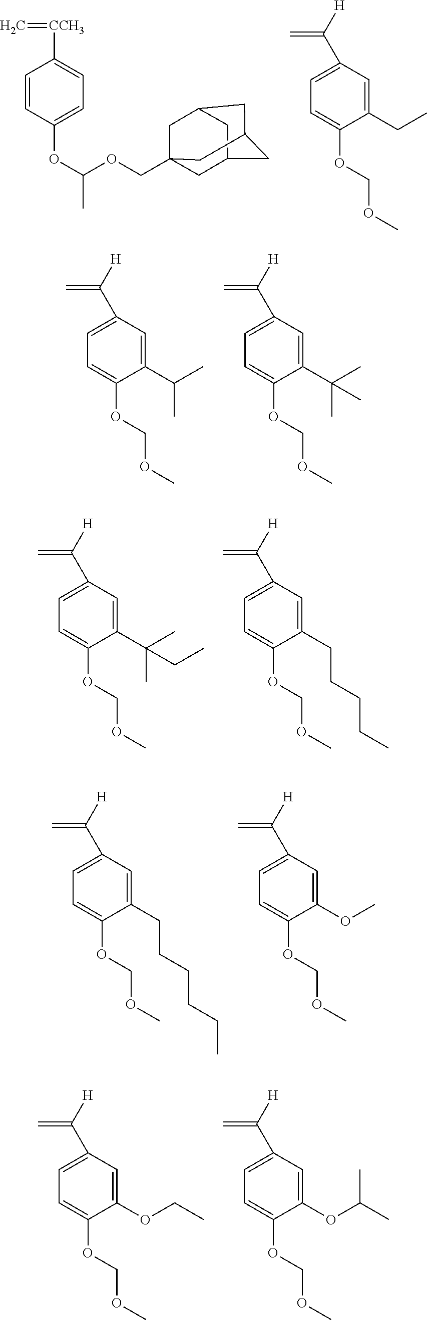

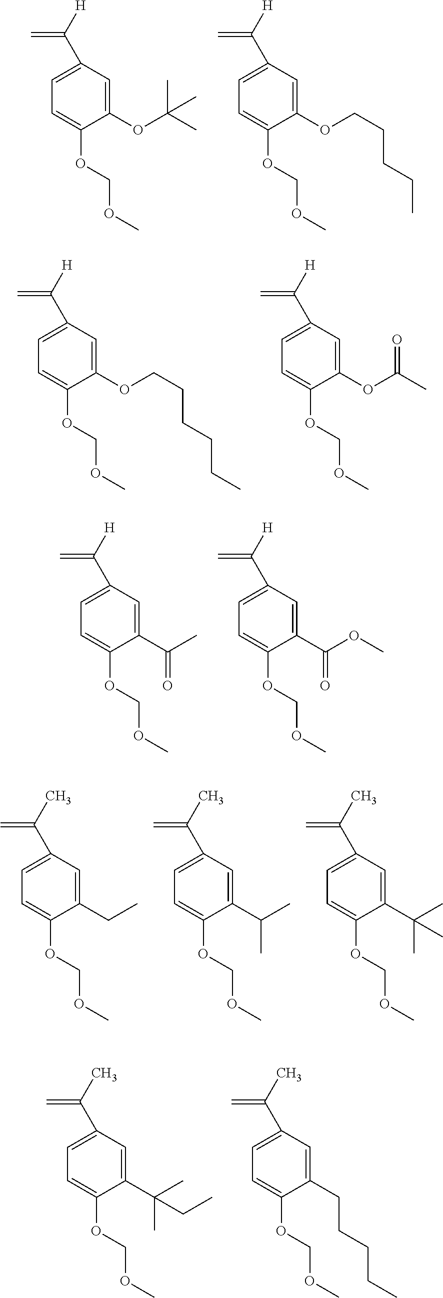

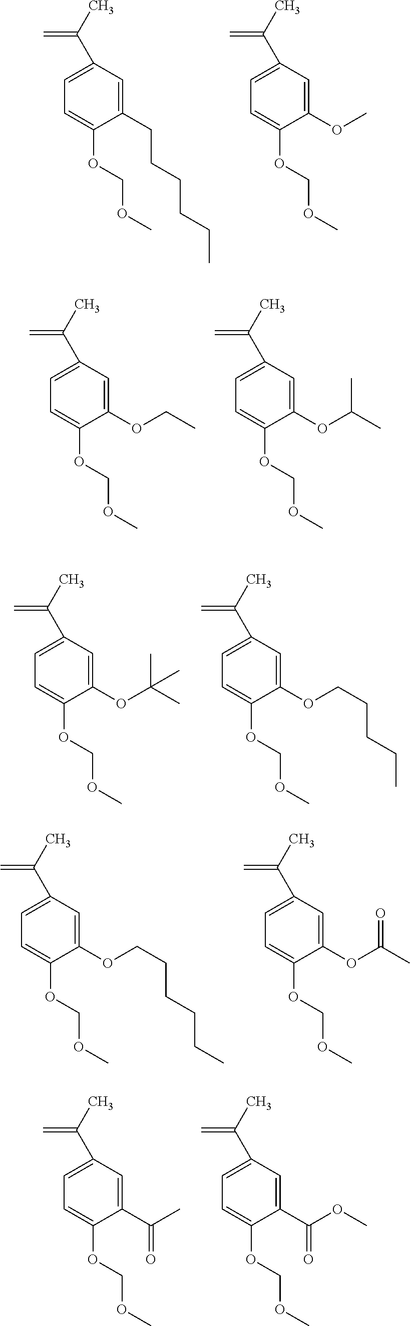

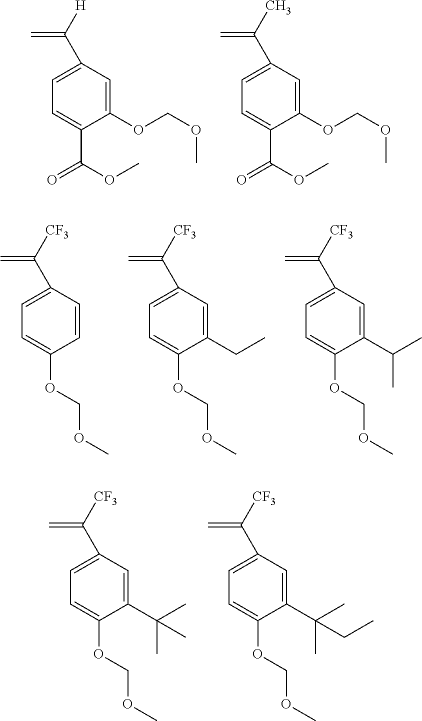

When Resin (A) contains the structural unit derived form the monomer represented by the formula (a1-4), the content of the structural unit derived from the monomer represented by the formula (a1-4) is usually 10 to 95% by mole and preferably 15 to 90% by mole and more preferably 20 to 85% by mole based on total molar of all the structural units of Resin (A).

Resin (A) can have two or more kinds of structural units derived from the monomers having an acid-labile group.

Resin (A) preferably contains the structural units derived from Compound (I), the structural unit derived from the monomer having an acid-labile group and a structural unit derived from the monomer having no acid-labile group other than Compound (I). Resin (A) can have two or more kinds of structural units derived from the monomers having no acid-labile group other than Compound (I).

When Resin (A) contains the structural units derived from Compound (I), the structural unit derived from the monomer having an acid-labile group and the structural unit derived from the monomer having no acid-labile group other than Compound (I), the content of the structural unit derived from the monomer having an acid-labile group is usually 10 to 80% by mole and preferably 20 to 60% by mole based on total molar of all the structural units of Resin (A). The content of the structural unit derived from a monomer having an adamantyl group, especially the monomer represented by the formula (a1-1) in the structural unit derived from the monomer having no acid-labile group, is preferably 15% by mole or more from the viewpoint of dry-etching resistance of the photoresist composition.

The monomer having no acid-labile group other than Compound (I) preferably contains one or more hydroxyl groups or a lactone ring. When Resin (A) contains the structural unit derived from the monomer having no acid-labile group and having one or more hydroxyl groups or a lactone ring, a photoresist composition having good resolution and adhesiveness of photoresist to a substrate tends to be obtained.

Examples of the monomer having no acid-labile group and having one or more hydroxyl groups include a monomer represented by the formula (a2-0):

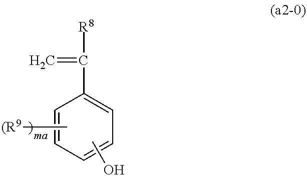

wherein R⁸ represents a hydrogen atom, a halogen atom, a C1-C6 alkyl group or a C1-C6 halogenated alkyl group, R⁹ is independently in each occurrence a halogen atom, a hydroxyl group, a C1-C6 alkyl group, a C1-C6 alkoxy group, a C2-C4 acyl group, a C2-C4 acyloxy group, an acryloyl group or a methacryloyl group, ma represents an integer of 0 to 4, and
a monomer represented by the formula (a2-1):

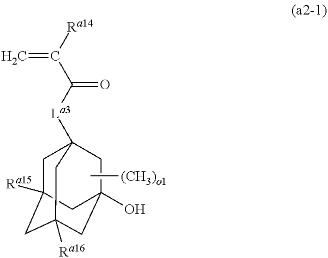

wherein R^{a14} represents a hydrogen atom or a methyl group, R^{a15} and R^{a16} each independently represent a hydrogen atom, a methyl group or a hydroxyl group, L^{a3} represents *—O— or *—O—(CH₂)ₖ₂—CO—O— in which * represents a binding position to —CO—, and k2 represents an integer of 1 to 7, and of represents an integer of 0 to 10.

When KrF excimer laser (wavelength: 248 nm) lithography system, or a high energy laser such as electron beam and extreme ultraviolet is used as an exposure system, the resin containing the structural unit derived from the monomer represented by the formula (a2-0) is preferable, and when ArF excimer laser (wavelength: 193 nm) is used as an exposure system, the resin containing the structural unit derived from the monomer represented by the formula (a2-1) is preferable.

In the formula (a2-0), examples of the halogen atom include a fluorine atom, examples of the C1-C6 alkyl group include a methyl group, an ethyl group, a propyl group, an isopropyl group, a butyl group, an isobutyl group, a sec-butyl group, a tert-butyl group, a pentyl group and a hexyl group, and a C1-C4 alkyl group is preferable and a C1-C2 alkyl group is more preferable and a methyl group is especially preferable. Examples of the C1-C6 halogenated alkyl group include a trifluoromethyl group, a pentafluoroethyl group, a heptafluoropropyl group, a heptafluoroisopropyl group, a nonafluorobutyl group, a nonafluoro-sec-butyl group, a nonafluoro-tert-butyl group, a perfluoropentyl group and a perfluorohexyl group. Examples of the C1-C6 alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group, and a C1-C4 alkoxy group is preferable and a C1-C2 alkoxy group is more preferable and a methoxy group is especially preferable. Examples of the C2-C4 acyl group include an acetyl group, a propionyl group and a butyryl group, and examples of the C2-C4 acyloxy group include an acetyloxy group, a propionyloxy group and a butyryloxy group. In the formula (a2-0), ma is preferably 0, 1 or 2, and is more preferably 0 or 1, and especially preferably 0.

The resin containing the structural unit derived from the monomer represented by the formula (a2-0) and the structural unit derived from the compound having an acid generator can be produced, for example, by polymerizing the compound having an acid generator and a monomer obtained by protecting a hydroxyl group of the monomer represented by the formula (a2-0) with an acetyl group followed by conducting deacetylation of the obtained polymer with a base.

Examples of the monomer represented by the formula (a2-0) include the followings.

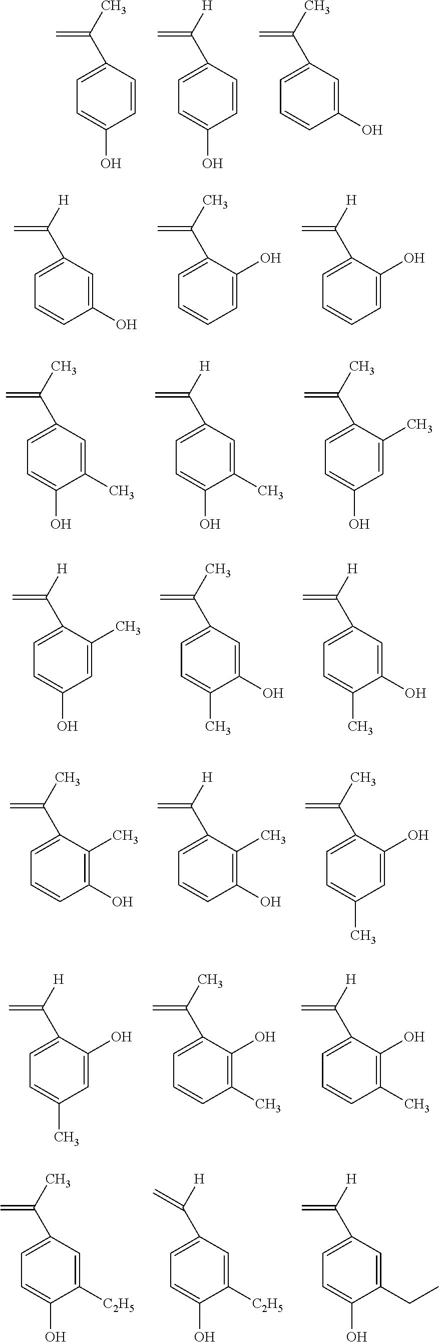

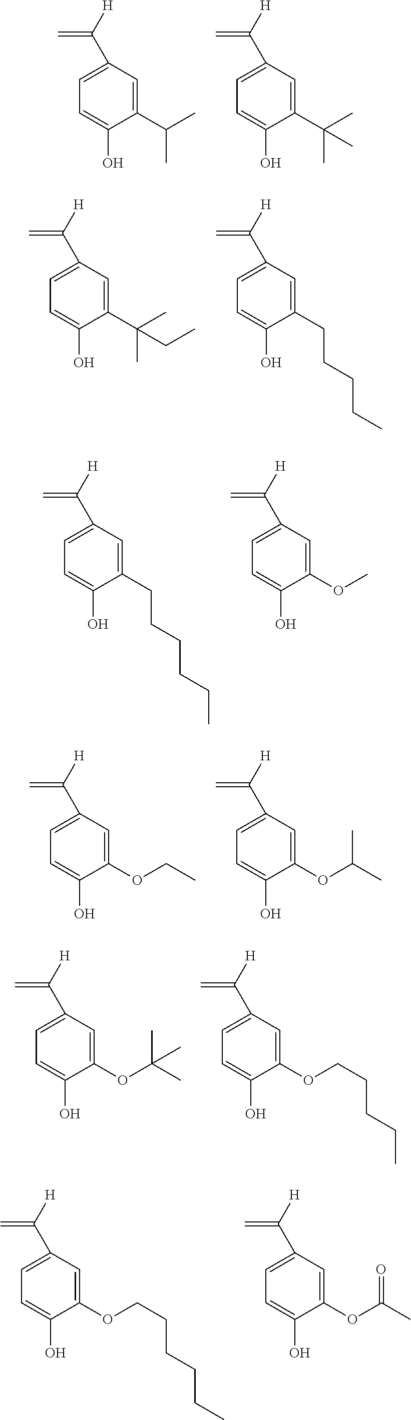

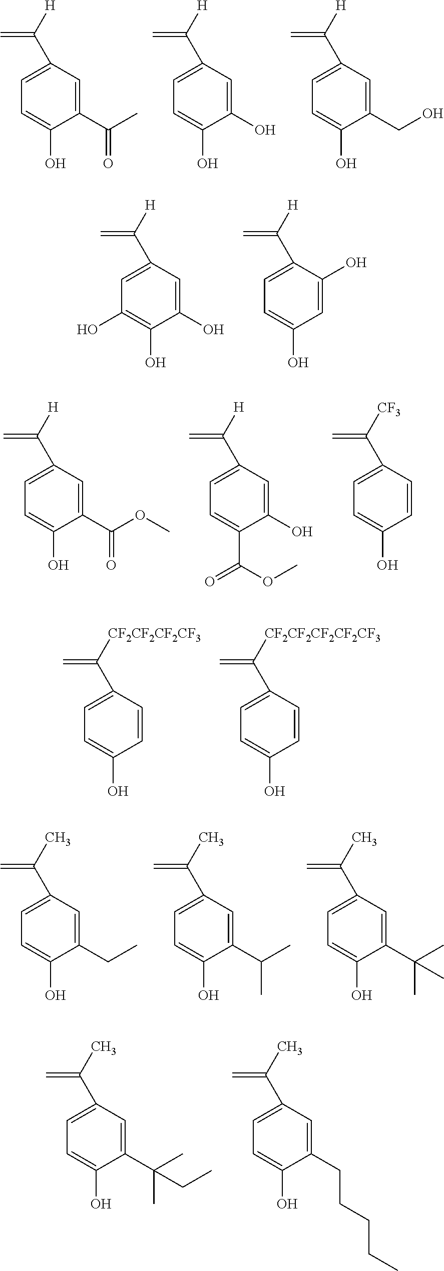

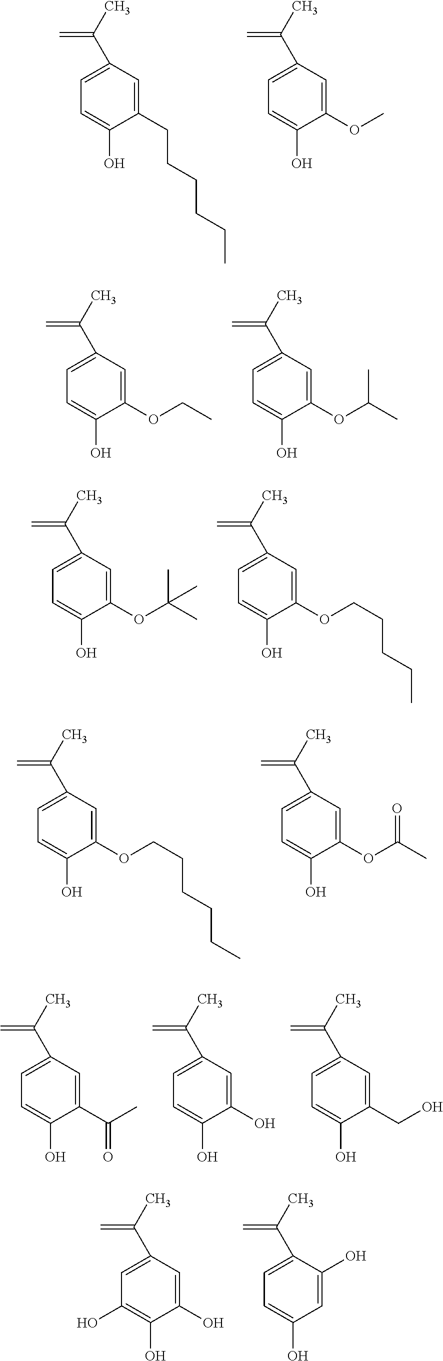

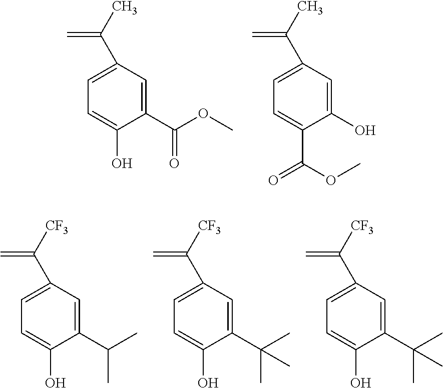

Among them, preferred are 4-hydroxystyrene and 4-hydroxy-α-methylstyrene.

When Resin (A) contains the structural unit derived from the monomer represented by the formula (a2-0), the content of the structural unit derived from the monomer represented by the formula (a2-0) is usually 5 to 90% by mole and preferably 10 to 85% by mole and more preferably 15 to 80% by mole based on total molar of all the structural units of Resin (A).

In the formula (a2-1), R^{a14} is preferably a methyl group, R^{a15} is preferably a hydrogen atom, R^{a16} is preferably a hydrogen atom or a hydroxyl group, L^{a1} is preferably *—O— or *—O—(CH₂)_{f2}—CO— in which * represents a binding position to —CO—, and f2 represents an integer of 1 to 4, and is more preferably *—O—, and of is preferably 0, 1, 2 or 3 and is more preferably 0 or 1.

Examples of the monomer represented by the formula (a2-1) include the followings, and 3-hydroxy-1-adamantyl acrylate, 3-hydroxy-1-adamantyl methacrylate, 3,5-dihydroxy-1-adamantyl acrylate, 3,5-dihydroxy-1-adamantyl methacrylate, 1-(3,5-dihydroxy-1-adamantyloxycarbonyl)methyl acrylate and 1-(3,5-dihydroxy-1-adamantyloxycarbonyl)methyl methacrylate are preferable, and 3-hydroxy-1-adamantyl methacrylate and 3,5-dihydroxy-1-adamantyl methacrylate are more preferable.

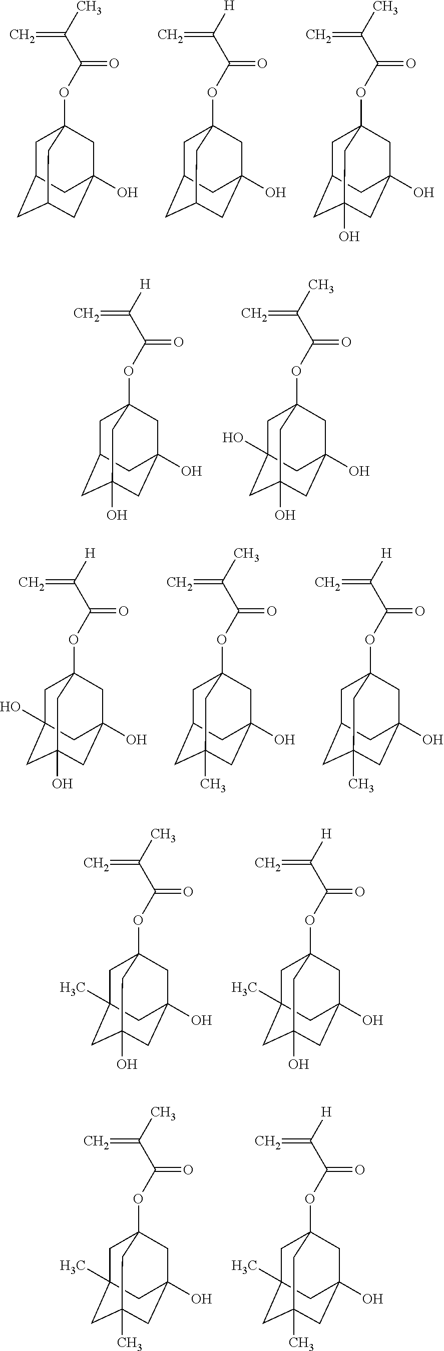

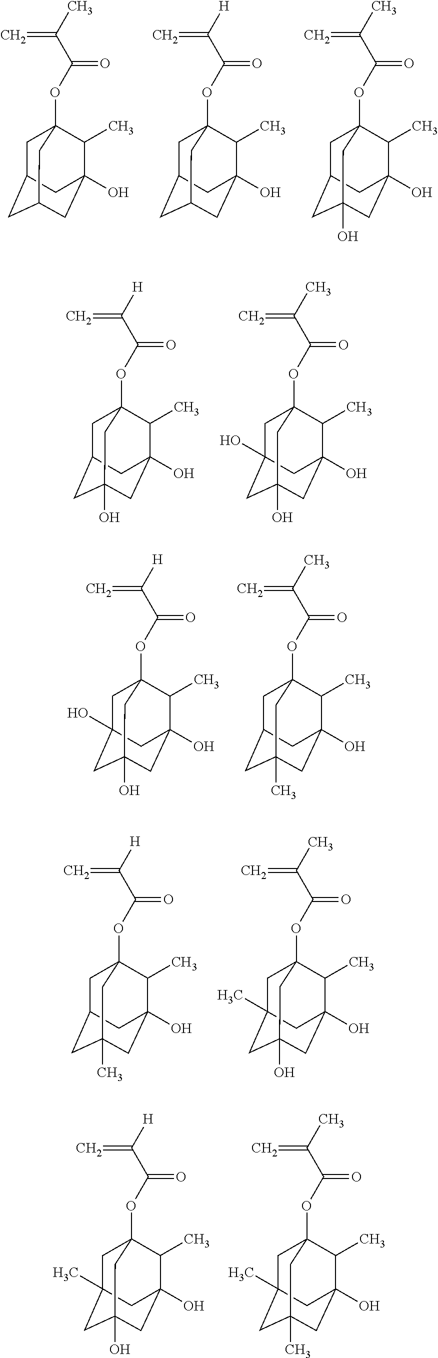

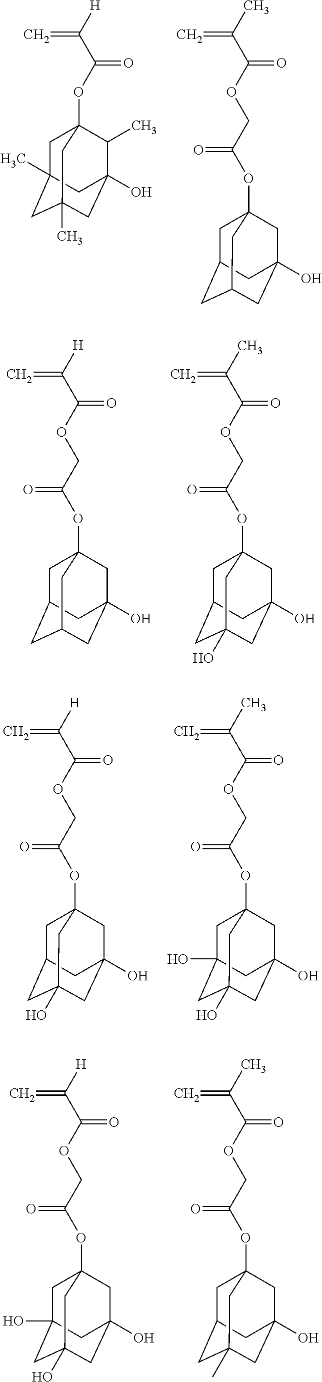

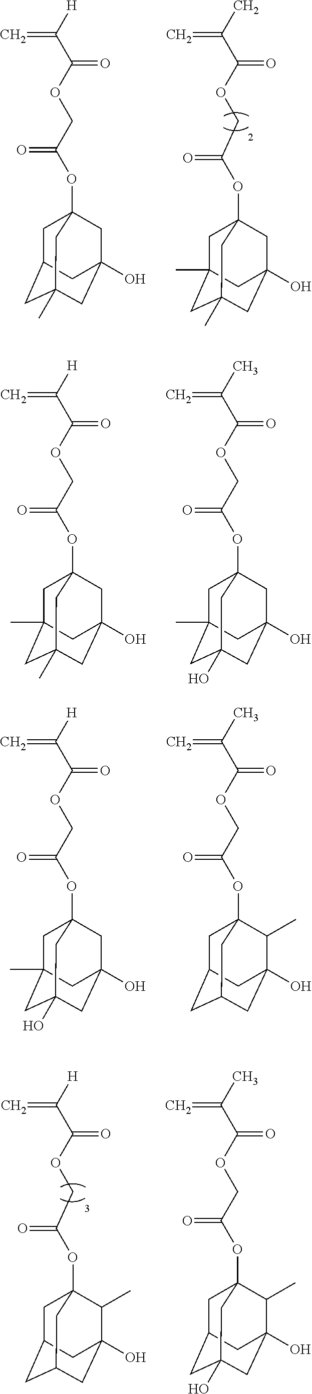

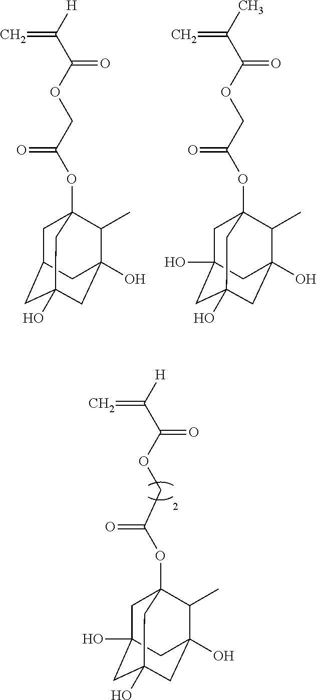

When Resin (A) contains the structural unit derived from the monomer represented by the formula (a2-1), the content of the structural unit derived from the monomer represented by the formula (a2-1) is usually 3 to 45% by mole and preferably 5 to 40% by mole and more preferably 5 to 35% by mole based on total molar of all the structural units of Resin (A).

Examples of the lactone ring of the monomer having no acid-labile group and having a lactone ring include a monocyclic lactone ring such as β-propiolactone ring, γ-butyrolactone ring and γ-valerolactone ring, and a condensed ring formed from a monocyclic lactone ring and the other ring. Among them, preferred are γ-butyrolactone ring and a condensed lactone ring formed from γ-butyrolactone ring and the other ring.

Preferable examples of the monomer having no acid-labile group and a lactone ring include the monomers represented by the formulae (a3-1), (a3-2) and (a3-3):

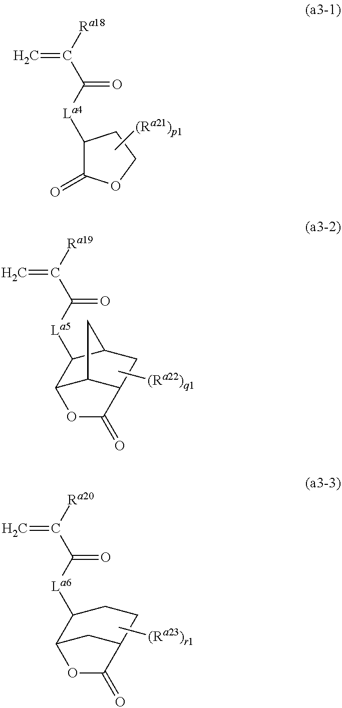

wherein L^{a4}, L^{a5} and L^{a6} each independently represent *—O— or *—O—(CH₂)ₖ₃—CO—O— in which * represents a binding position to —CO— and k3 represents an integer of 1 to 7, R^{a18}, R^{a19} and R^{a20} each independently represent a hydrogen atom or a methyl group, R^{a21} represents a C1-C4 aliphatic hydrocarbon group, R^{a22} and R^{a23} are independently in each occurrence a carboxyl group, a cyano group or a C1-C4 aliphatic hydrocarbon group, and p1 represents an integer of 0 to 5, q1 and r1 independently each represent an integer of 0 to 3.

It is preferred that L^{a4}, L^{a5} and L^{a6} each independently represent *—O— or *—O—(CH₂)_{d1}—CO—O— in which * represents a binding position to —CO— and d1 represents an integer of 1 to 4, and it is more preferred that L^{a4}, L^{a5} and L^{a6} are *—O—R^{a18}, R^{a19} and R^{a20} are preferably methyl groups. R^{a21} is preferably a methyl group. It is preferred that R^{a22} and R^{a23} are independently in each occurrence a carboxyl group, a cyano group or a methyl group. It is preferred that p1 is an integer of 0 to 2, and it is more preferred that p1 is 0 or 1. It is preferred that q1 and r1 independently each represent an integer of 0 to 2, and it is more preferred that q1 and r1 independently each represent 0 or 1.

Examples of the monomer represented by the formula (a3-1) include the followings.

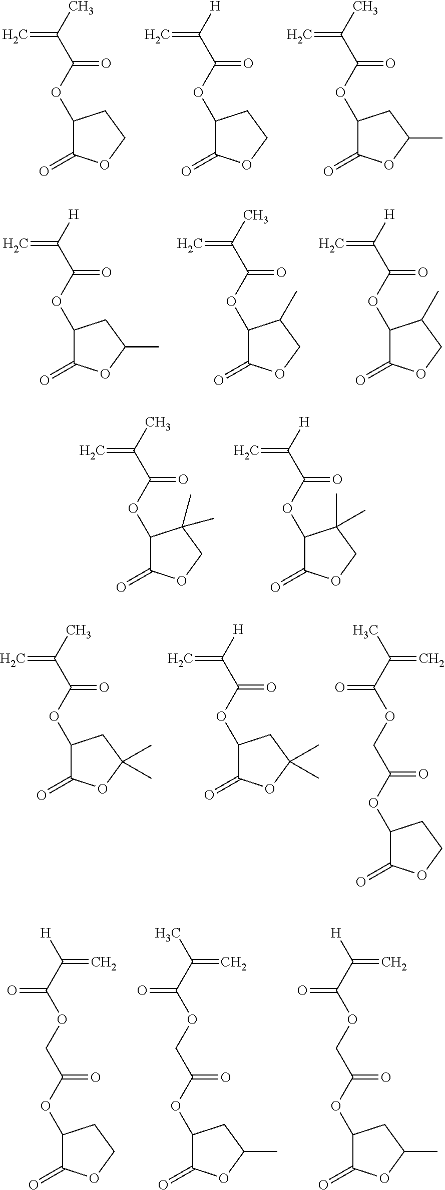

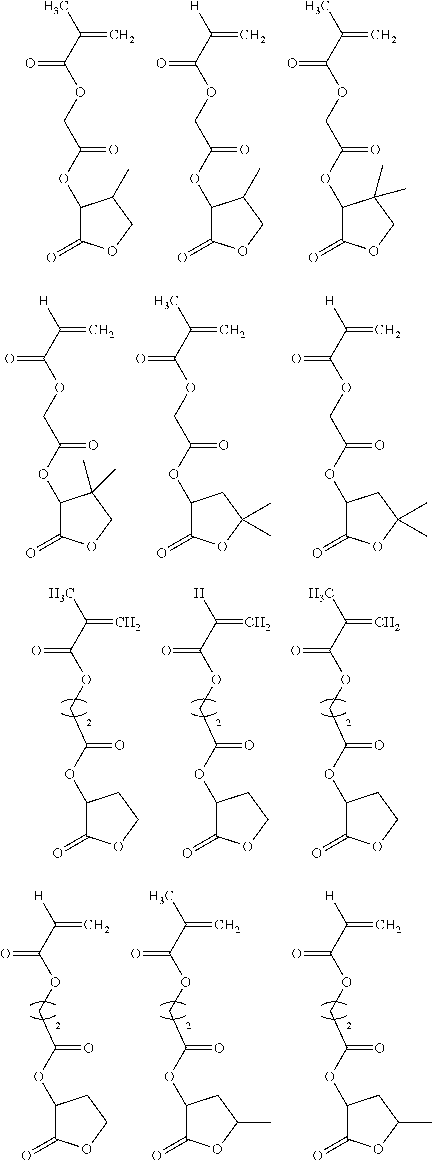

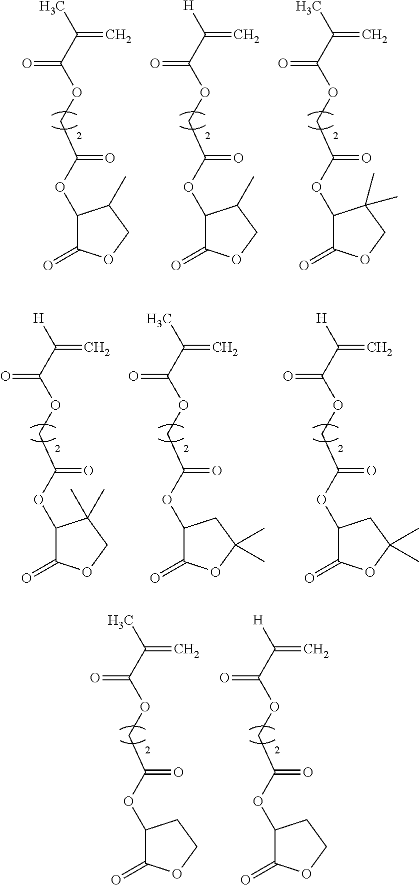

Examples of the monomer represented by the formula (a3-2) include the followings.

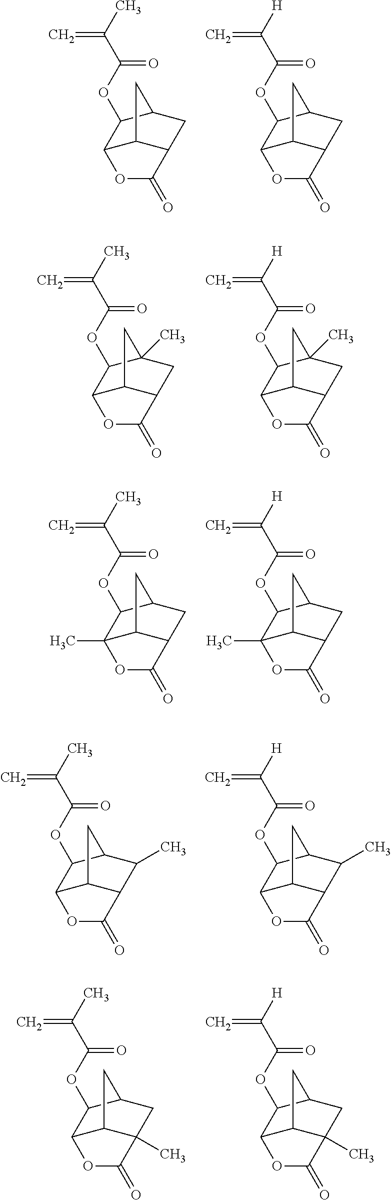

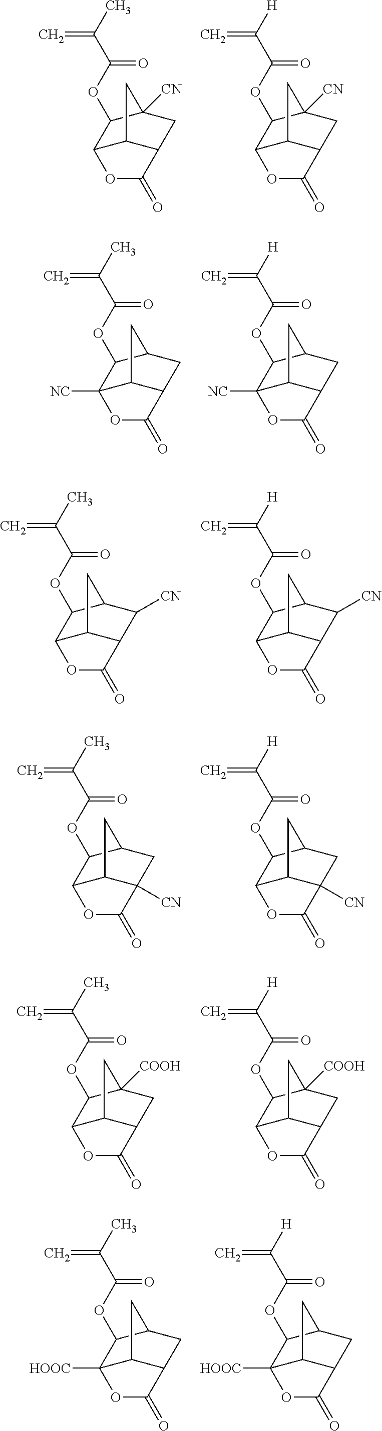

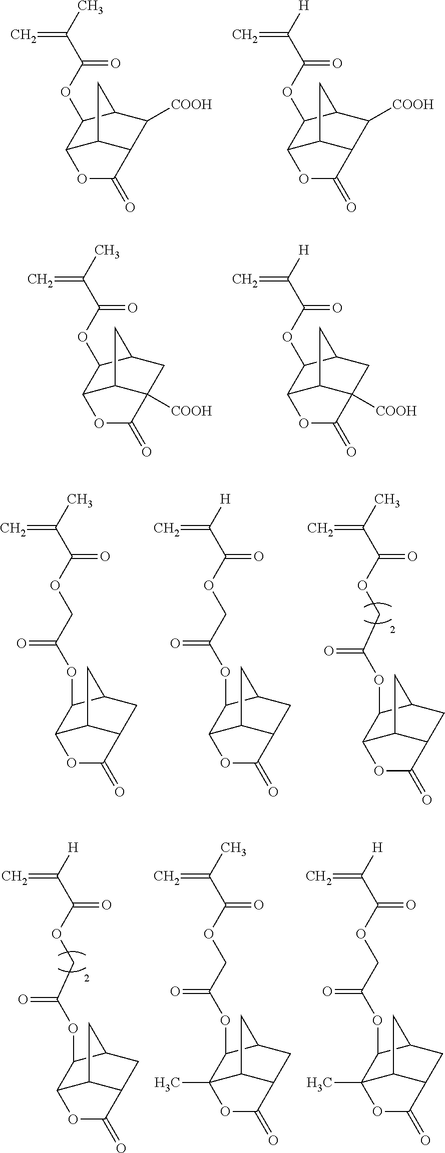

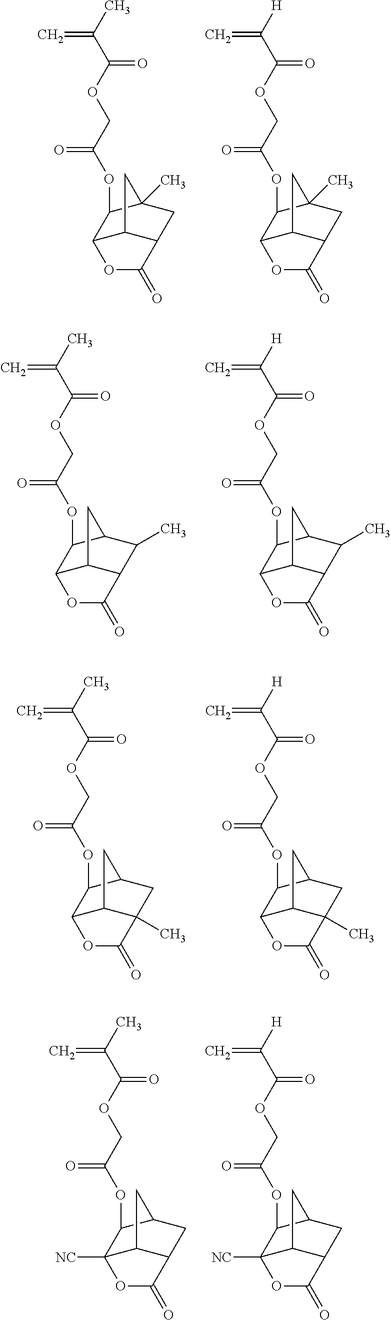

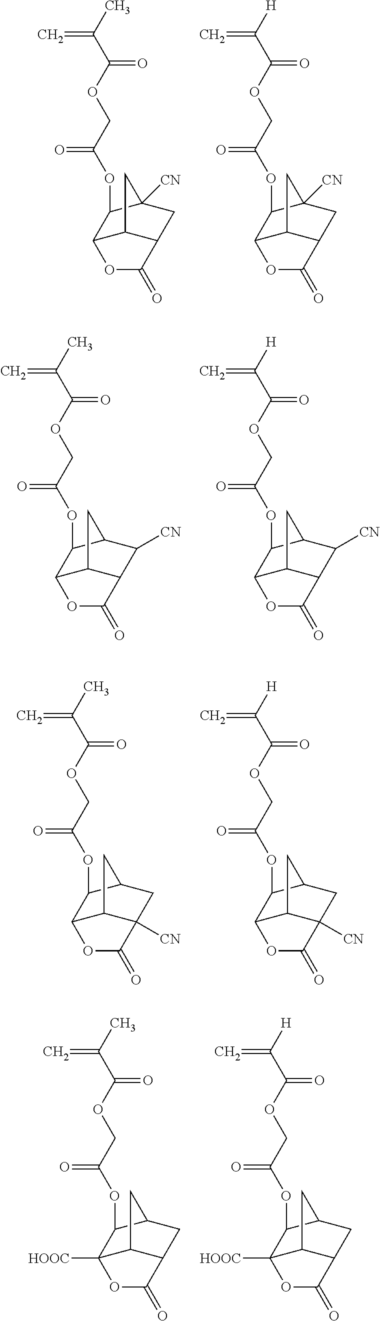

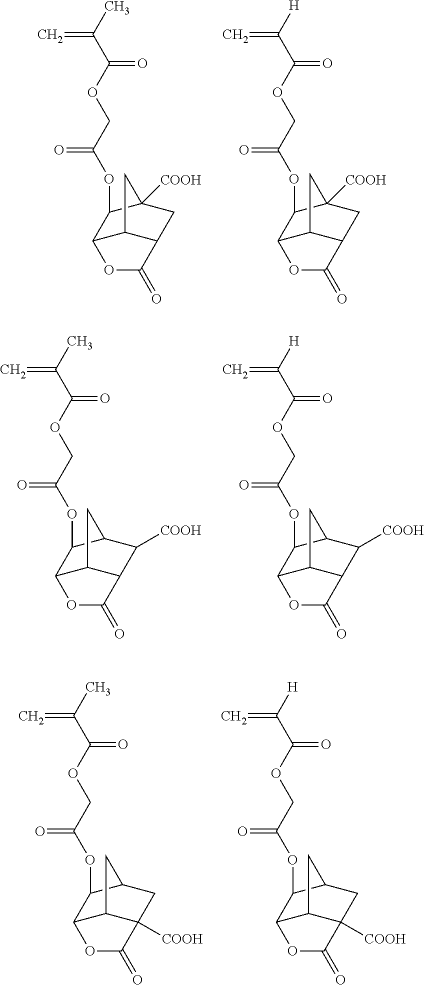

Examples of the monomer represented by the formula (a3-3) include the followings.

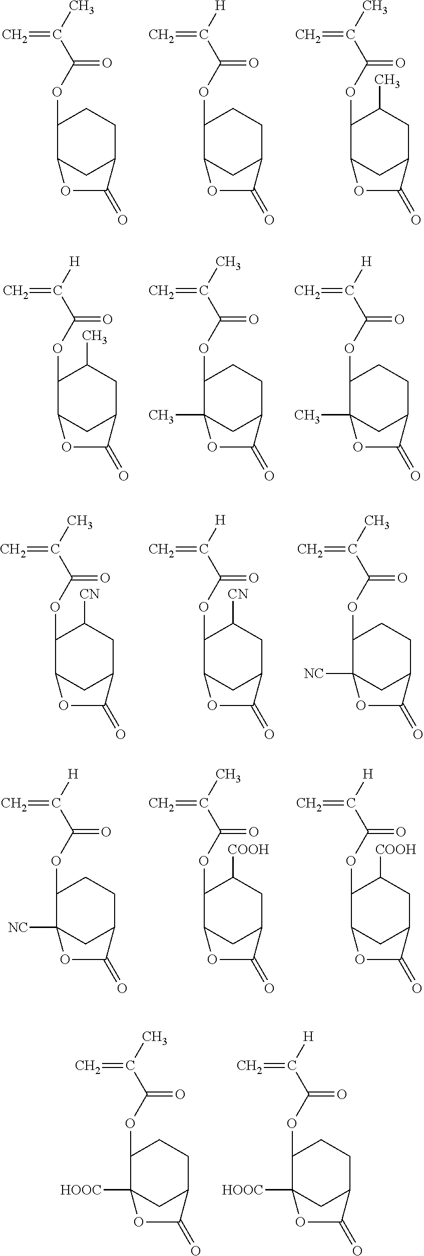

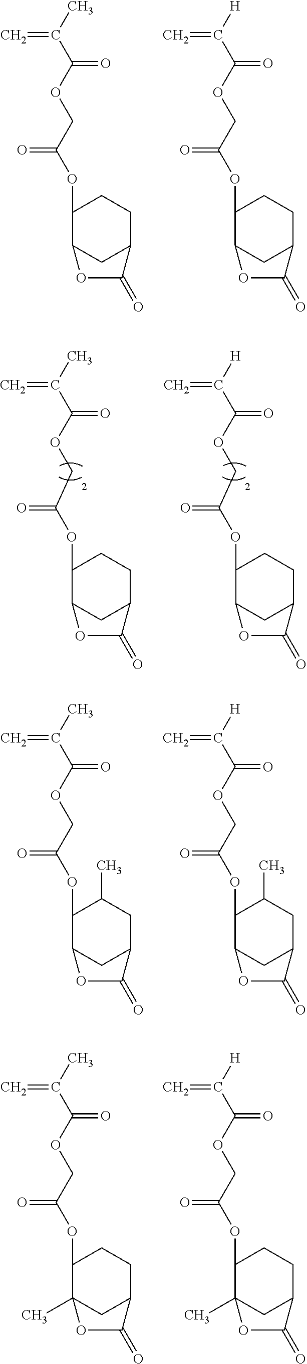

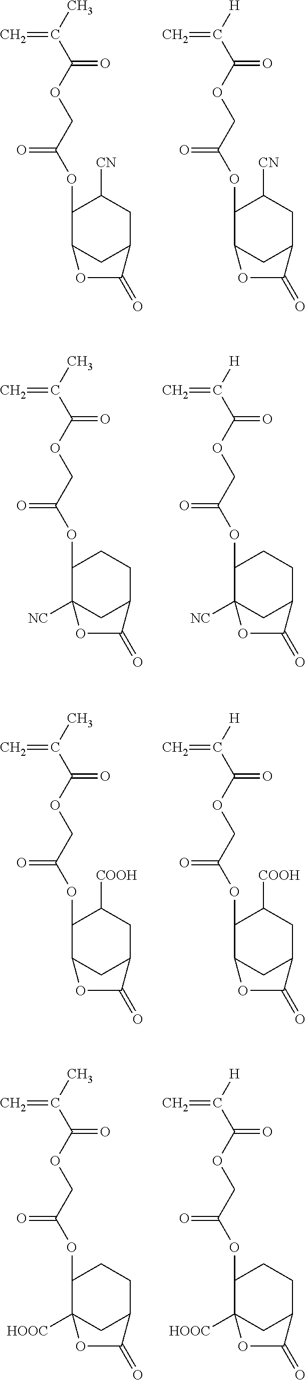

Among them, preferred are 5-oxo-4-oxatricyclo[4.2.1.0^{3,7}]nonan-2-yl acrylate, 5-oxo-4-oxatricyclo[4.2.1.0^{3,7}]nonan-2-yl methacrylate, tetrahydro-2-oxo-3-furyl acrylate, tetrahydro-2-oxo-3-furyl methacrylate, 2-(5-oxo-4-oxatricyclo[4.2.1.0^{3,7}]nonan-2-yloxy)-2-oxoethyl acrylate and 2-(5-oxo-4-oxatricyclo[4.2.1.0^{3,7}]nonan-2-yloxy)-2-oxoethyl methacrylate, and more preferred are 5-oxo-4-oxatricyclo[4.2.1.0^{3,7}]nonan-2-yl methacrylate, tetrahydro-2-oxo-3-furyl methacrylate and 2-(5-oxo-4-oxatricyclo[4.2.1.0^{3,7}]nonan-2-yloxy)-2-oxoethyl methacrylate.

When Resin (A) contains the structural unit derived from the monomer having no acid-labile group and having a lactone ring, the content thereof is usually 5 to 65% by mole and preferably 10 to 60% by mole and more preferably 10 to 55% by mole based on total molar of all the structural units of Resin (A).

Resin (A) can contain a structural unit derived from a monomer having an acid-labile group containing a lactone ring. Examples of the monomer having an acid-labile group containing a lactone ring include the followings.

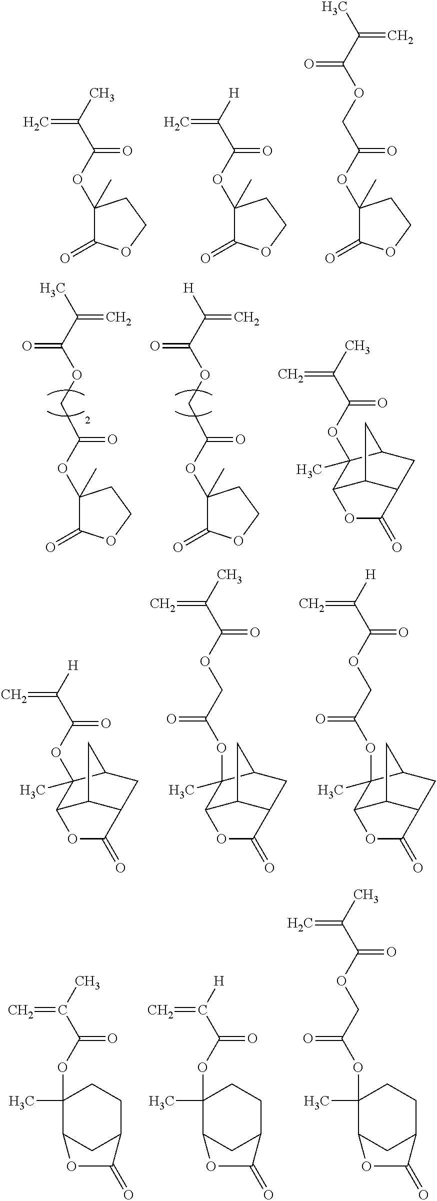

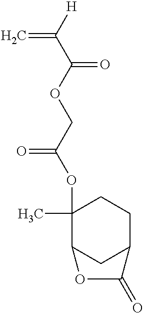

Resin (A) can contain a structural unit derived from a monomer having a sultone structure such as a group represented by the formula (T3), preferably a group represented by the formula (T4).

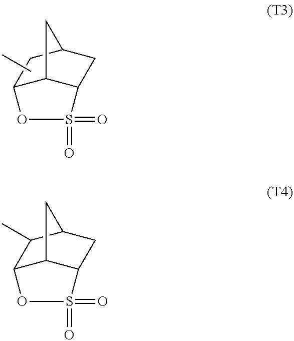

wherein one or more hydrogen atoms contained in the sultone ring can be replaced by a halogen atom, a hydroxyl group, a C1-C12 alkyl group, a C1-C12 alkoxyl group, a C6-C12 aryl group, a C7-C13 aralkyl group or a C2-C4 acyl group, and one or more —CH₂— contained in the ring may be replaced by —CO— or —O—.

Examples of the C1-C12 alkyl group include a methyl group and an ethyl group. Examples of the C1-C12 alkoxyl group include a methoxy group and an ethoxy group. Examples of the C6-C12 aryl group include a phenyl group and a naphthyl group. Examples of the C7-C13 aralkyl group include a benzyl group, and examples of the C2-C4 acyl group include an avetyl group.

Examples of the monomer having a sultone structure include the followings.

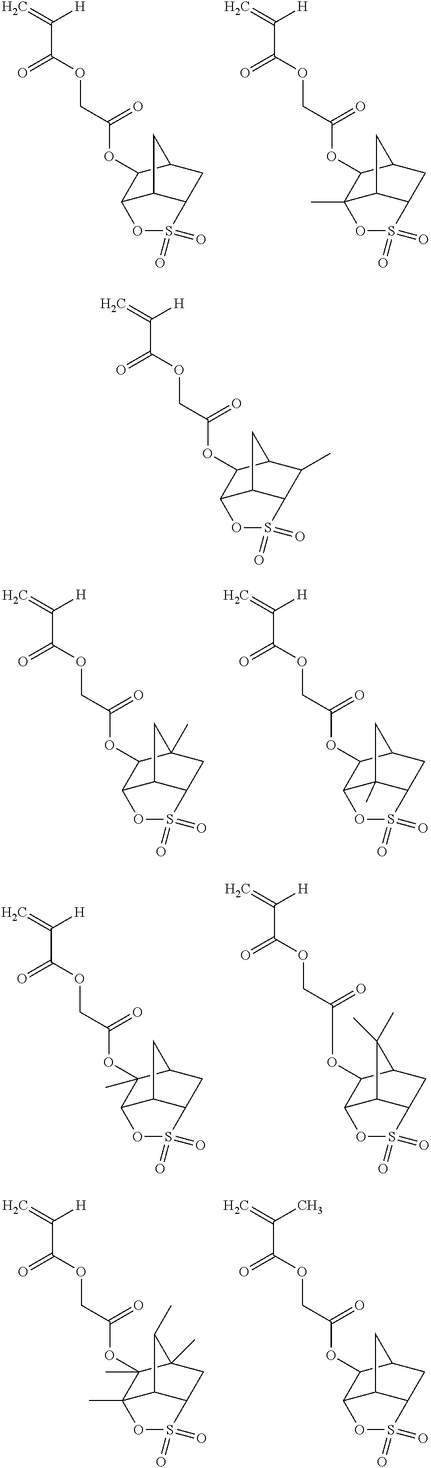

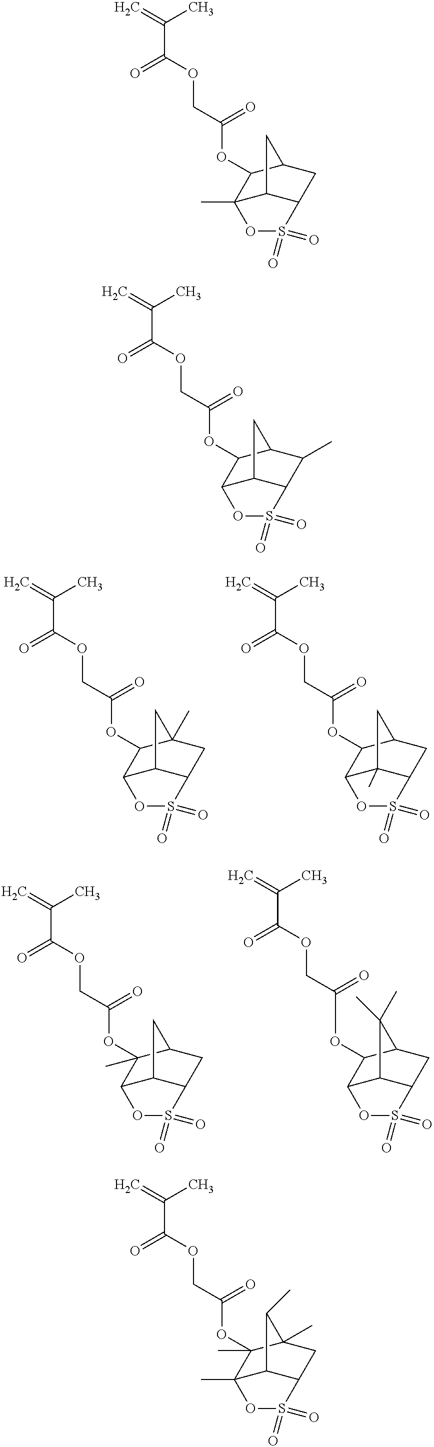

The content of the structural unit derived from a monomer having a sultone structure in Resin (A) is usually 0 to 10% by mole based on total molar of all the structural units of Resin (A).

Preferable Resin (A) is a resin containing the structural units derived from Compound (I), the structural units derived from the monomer having an acid-labile group, and the structural units derived from the monomer having one or more hydroxyl groups and/or the monomer having a lactone ring. The monomer having an acid-labile group is preferably the monomer represented by the formula (a1-1) or the monomer represented by the formula (a1-2), and is more preferably the monomer represented by the formula (a1-1). The monomer having one or more hydroxyl groups is preferably the monomer represented by the formula (a2-1), and the monomer having a lactone ring is preferably the monomer represented by the formula (a3-1) or (a3-2).

Resin (A) can be produced according to known polymerization methods such as radical polymerization.

Resin (A) usually has 2,500 or more of the weight-average molecular weight, and preferably 3,000 or more of the weight-average molecular weight. Resin (A) usually has 50,000 or less of the weight-average molecular weight, and preferably has 30,000 or less of the weight-average molecular weight. The weight-average molecular weight can be measured with gel permeation chromatography.

The content of Resin (A) in the photoresist composition of the present invention is preferably 80% by weight or more based on 100% by weight of the solid component. In this specification, “solid component” means components other than solvent in the photoresist composition.

The photoresist composition of the present invention can contain two or more kinds of Resin (A).

The photoresist composition of the present invention contains an acid generator represented by the formula (II):

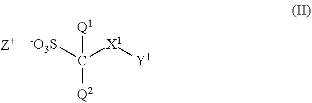

wherein Q¹ and Q² each independently represent a fluorine atom or a C1-C6 perfluoroalkyl group, X¹ represents a single bond or a C1-C17 divalent saturated hydrocarbon group in which one or more —CH₂— can be replaced by —O— or —CO—,
Y¹ represents a C1-C36 aliphatic hydrocarbon group which can have one or more substituents, a C3-C36 saturated cyclic hydrocarbon group which can have one or more substituents, or a C6-C36 aromatic hydrocarbon group which can have one or more substituents, and one or more —CH₂— in the aliphatic hydrocarbon group and the saturated cyclic hydrocarbon group can be replaced by —O— or —CO—, and Z⁺ represents an organic counter cation (hereinafter, simply referred to as Acid Generator (II)). The photoresist composition of the present invention can contain two or more kinds of Acid Generator (II).

Acid Generator (II) is a substance which is decomposed to generate an acid by applying a radiation such as a light, an electron beam or the like on the substance itself or on a photoresist composition containing the substance. The acid generated from Acid Generator (II) acts on Resin (A) resulting in cleavage of the acid-labile group existing in Resin (A).

Examples of the C1-C6 perfluoroalkyl group include a trifluoromethyl group, a pentafluoroethyl group, a heptafluoropropyl group, a nonafluorobutyl group, an undecafluoropentyl group and a tridecafluorohexyl group, and a trifluoromethyl group is preferable. Q¹ and Q² each independently preferably represent a fluorine atom or a trifluoromethyl group, and Q¹ and Q² are more preferably fluorine atoms.

Examples of the C1-C17 divalent saturated hydrocarbon group include a C1-C17 linear alkylene group such as a methylene group, an ethylene group, a propane-1,3-diyl group, a propane-1,2-diyl group, a butane-1,4-diyl group, a butane-1,3-diyl group, a pentane-1,5-diyl group, a hexane-1,6-diyl group, a heptane-1,7-diyl group, an octane-1,8-diyl group, a nonane-1,9-diyl group, a decane-1,10-diyl group, a undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group, a C1-C17 branched alkylene group such as a 1-methyl-1,3-propylene group, a 2-methyl-1,3-propylene group, a 2-methyl-1,2-propylene group, a 1-methyl-1,4-butylene group, and a 2-methyl-1,4-butylene group,

a divalent saturated monocyclic hydrocarbon group such as a cycloalkylene group such as a 1,3-cyclobutylene group, a 1,3-cyclopentylene group, a 1,4-cyclohexylene group, and a 1,5-cyclooctylene group, and a divalent saturated polycyclic hydrocarbon group such as a 1,4-norbornylene group, a 2,5-norbornylene group, a 1,5-adamantylene group and a 2,6-adamantylene group.

The C1-C17 divalent saturated hydrocarbon group can have one or more substituents, and examples of the substituent include a halogen atom, a hydroxyl group, a carboxyl group, a C6-C18 aromatic group, a C7-C21 aralkyl group such as a benzyl group, a phenethyl group, a phenylpropyl group, a trityl group, a naphthylmethyl group and a naphthyethyl group, a C2-C4 acyl group and a glycidyloxy group.

Examples of the C1-C17 saturated hydrocarbon group in which one or more methylene groups are replaced by —O— or —CO— include *—CO—O—X³—, *—CO—O—X⁵—CO—O—X⁴—, *—X⁶—O—CO—, *—X⁸—O—X⁷—, *—CO—O—X⁹—O—, and *—CO—O—X¹¹—O—X¹⁰—CO—O—, wherein X³ represents a single bond or a C1-C15 alkanediyl group, X⁴ represents a single bond or a C1-C12 alkanediyl group, X⁵ represents a C1-C13 alkanediyl group, with proviso that total carbon number of X⁴ and X⁵ is 1 to 13, X⁶ represents a C1-C15 alkanediyl group, X⁷ represents a C1-C15 alkanediyl group, X⁸ represents a C1-C15 alkanediyl group, with proviso that total carbon number of X⁷ and X⁸ is 1 to 16, X⁹ represents a C1-C14 alkanediyl group, X¹⁰ represents a C1-C11 divalent saturated hydrocarbon group, X¹¹ represents a C1-C11 divalent saturated hydrocarbon group, with proviso that total carbon number of X¹⁰ and X¹¹ is 1 to 12, and * represents a binding position to —C(Q¹)(Q²)—.

Examples of *—CO—O—X³— include *—CO—O— and *—CO—O—CH₂—. Examples of *—CO—O—X⁵—CO—O—X⁴— include *—CO—O—CH₂—CO—O—, *—CO—O—(CH₂)₂CO—O—, *—CO—O—(CH₂)₃—CO—O—, *—CO—O—(CH₂)₄—CO—O—, *—CO—O—(CH₂)₆CO—O—, *—CO—O—(CH₂)₈—CO—O—, *—CO—O—CH₂—CH(CH₃)—CO—O— and —CO—CH₂—C(CH₃)₂CO—O—. Examples of *—X⁶—O—CO— include *—CH₂—O—CO—, *—(CH₂)₂—O—CO—, *—(CH₂)₃—O—CO—, *—(CH₂)₄—O—CO—, *—(CH₂)₆—O—CO— and *—(CH₂)₈—O—CO—. Examples of *—X⁸—O—X⁷— include *—CH₂—O—CH₂—. Examples of *—CO—O—X⁹—O— include *—CO—O—CH₂—O—, *—CO—O—(CH₂)₂—O—, *—CO—(CH₂)₃—O—. *—CO—O—(CH₂)₄—O— and *—CO—O—(CH₂)₆—O—. Examples of *—CO—O—X¹¹—O—X¹⁰—CO—O— include the followings.

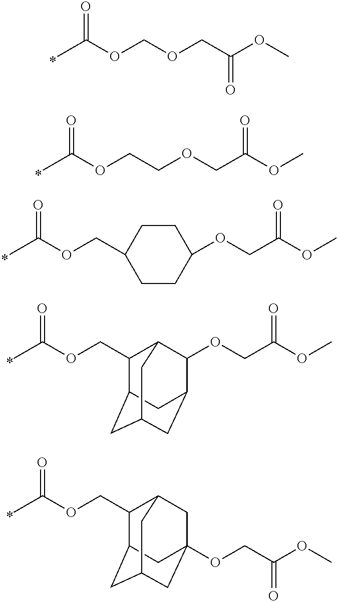

The saturated hydrocarbon group can have one or more substituents, and examples of the substituent include a halogen atom, a hydroxyl group, a carboxyl group, a C6-C18 aromatic hydrocarbon group, a C7-C21 aralkyl group such as a benzyl group, a phenethyl group, a phenylpropyl group, a trityl group, a naphthylmethyl group and a naphthyethyl group, a C2-C4 acyl group and a glycidyloxy group.

Examples of the substituent in Y¹ include a halogen atom, a hydroxyl group, an oxo group, a glycidyloxy group, a C2-C4 acyl group, a C1-C12 alkoxy group, a C2-C7 alkoxycarbonyl group, a C1-C12 aliphatic hydrocarbon group, a C1-C12 hydroxy-containing aliphatic hydrocarbon group, a C3-C16 saturated cyclic hydrocarbon group, a C6-C18 aromatic hydrocarbon group, a C7-C21 aralkyl group and —(CH₂)ⱼ₂—O—CO in which R^{b1} represents a C1-C16 aliphatic hydrocarbon group, a C3-C16 saturated cyclic hydrocarbon group or a C6-C18 aromatic hydrocarbon group and j2 represents an integer of 0 to 4. Examples of the halogen atom include a fluorine atom, a chlorine atom, a bromine atom and an iodine atom. Examples of the acyl group include an acetyl group and a propionyl group, and examples of the alkoxy group include a methoxy group, an ethoxy group, a propoxy group, an isopropoxy group and a butoxy group. Examples of the alkoxycarbonyl group include a methoxycarbonyl group, an ethoxycarbonyl group, a propoxycarbonyl group, an isopropoxycarbonyl group and a butoxycarbonyl group. Examples of the aliphatic hydrocarbon group include the same as described above. Examples of the hydroxyl-containing aliphatic hydrocarbon group include a hydroxymethyl group. Examples of the C3-C16 saturated cyclic hydrocarbon group include the same as described above, and examples of the aromatic hydrocarbon group include a phenyl group, a naphthyl group, an anthryl group, a p-methylphenyl group, a p-tert-butylphenyl group and a p-adamantylphenyl group. Examples of the aralkyl group include a benzyl group, a phenethyl group, a phenylpropyl group, a trityl group, a naphthylmethyl group and a naphthylethyl group.

Examples of the C1-C18 aliphatic hydrocarbon group represented by Y include a methyl group, an ethyl group, a propyl group, an isopropyl group, a butyl group, an isobutyl group, a sec-butyl group, a tert-butyl group, a pentyl group, a neopentyl group, a 1-methylbutyl group, a 2-methylbutyl group, a 1,2-dimethylpropyl group, a 1-ethylpropyl group, a hexyl group, a-1-methylpentyl group, a heptyl group, an octyl group, a 2-ethylhexyl group, a nonyl group, a decyl group, an undecyl group and a dodecyl group, and a C1-C6 alkyl group is preferable. Examples of the C3-C18 saturated cyclic hydrocarbon group represented by Y¹ include the groups represented by the formulae (Y1) to (Y26):

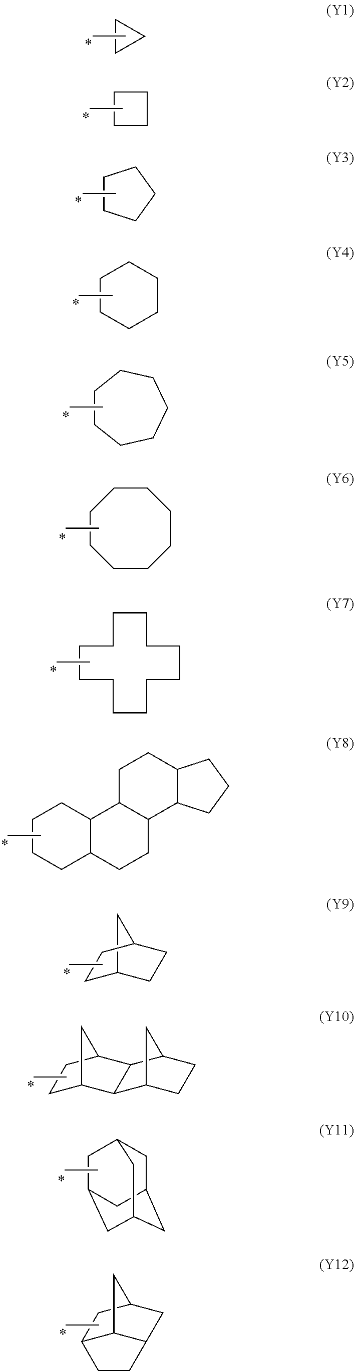

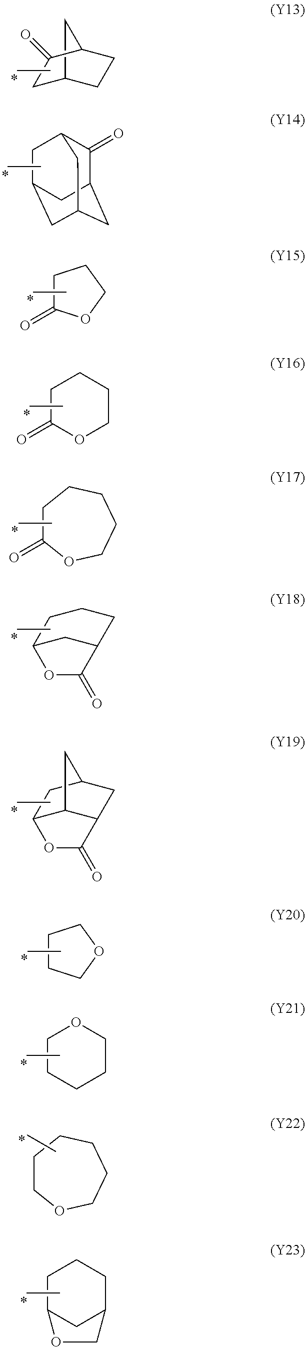

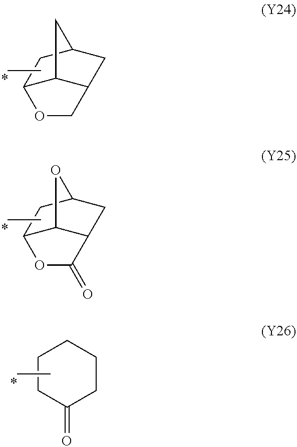

wherein * represents a binding position to X¹.

Among them, preferred are the groups represented by the formulae (Y1) to (Y19), and more preferred are the groups represented by the formulae (Y11), (Y14), (Y15) and (Y19). The groups represented by the formulae (Y11) and (Y14) are especially preferable.

Examples of Y¹ having one or more substituents include the followings:

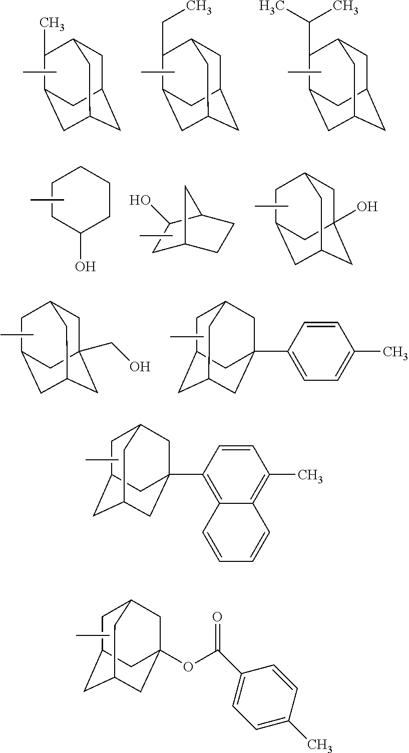

Y¹ is preferably an adamantyl group which can have one or more substituents, and is more preferably an adamantyl group or an oxoadamantyl group.

Among the sulfonic acid anions of Acid Generator (II), preferred is a sulfonic acid anion having the group represented by *—CO—O—X³—, and more preferred are a sulfonic anion having the group represented by *—CO—O— or *—CO—O—CH₂—, and still more preferred are sulfonic anions represented by the formulae (IIa-1) to (IIa-9).

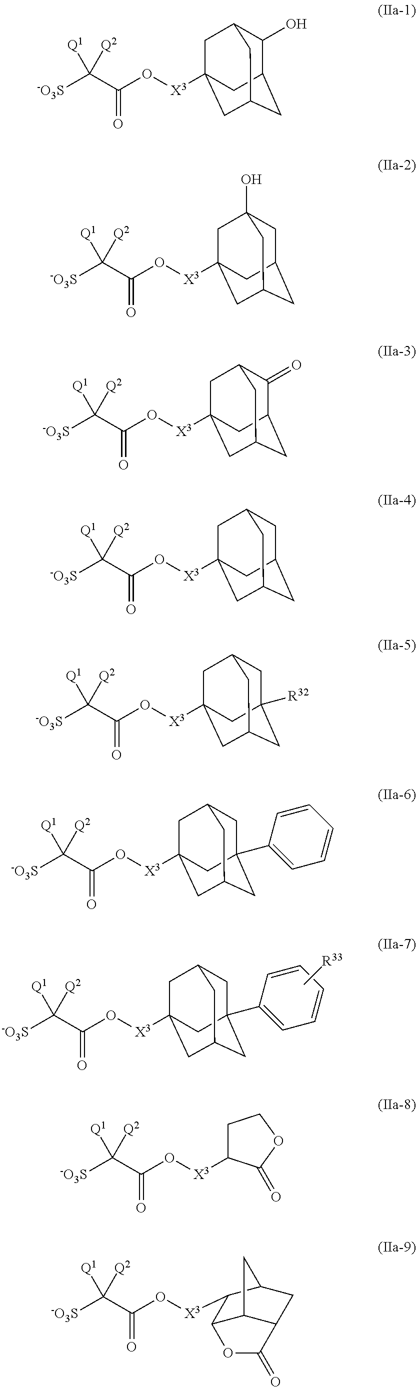

wherein Q¹, Q² and X³ are the same as defined above, and R³² and R³³ each independently represent a C1-C4 aliphatic hydrocarbon group, preferably a methyl group.

Specific examples of the sulfonic anion include the followings.

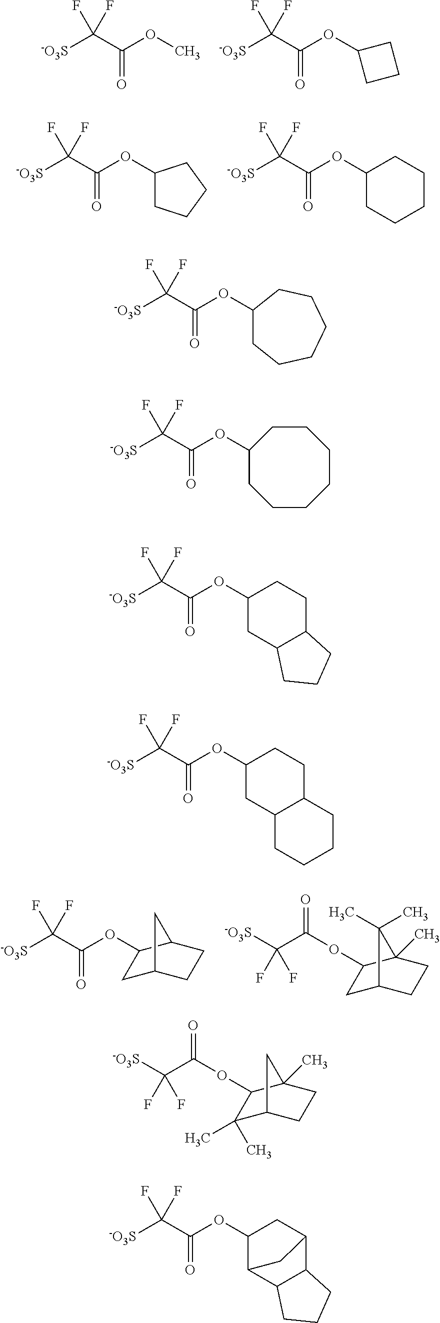

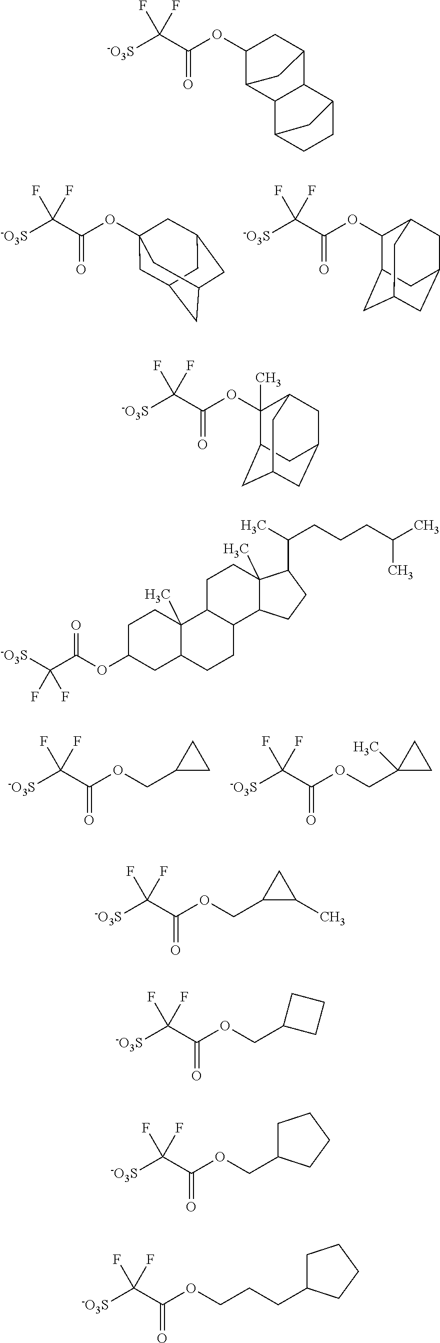

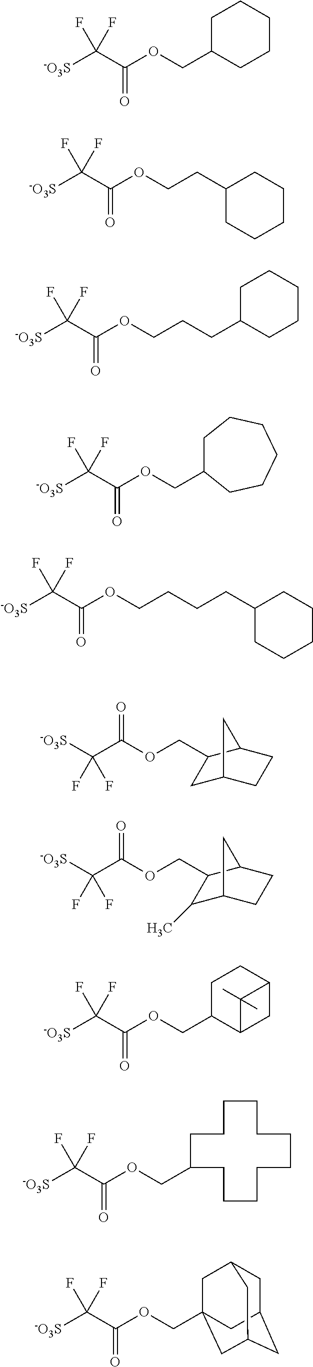

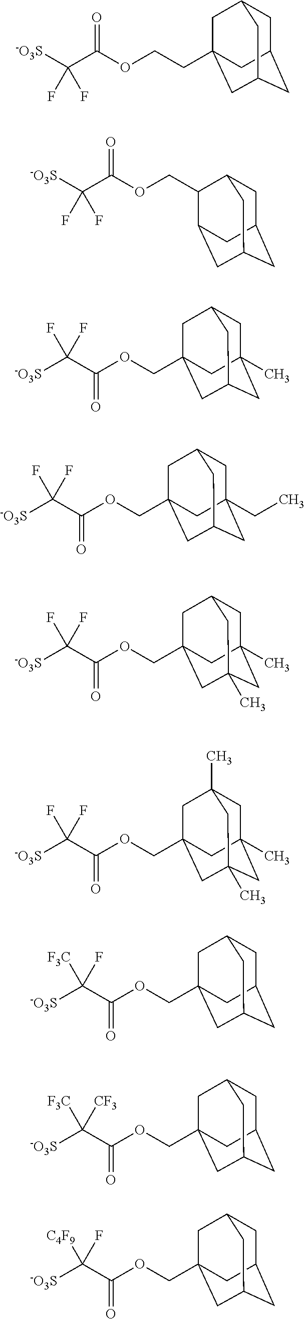

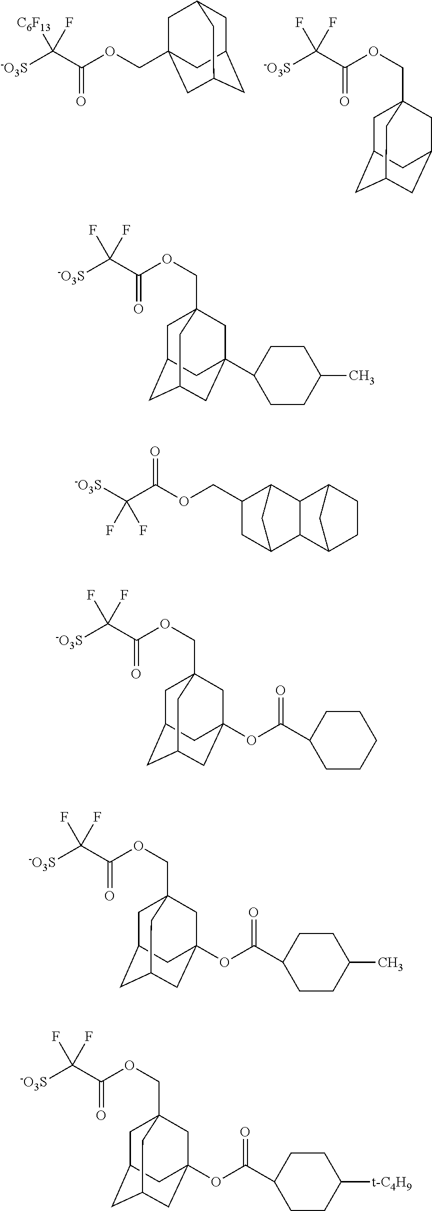

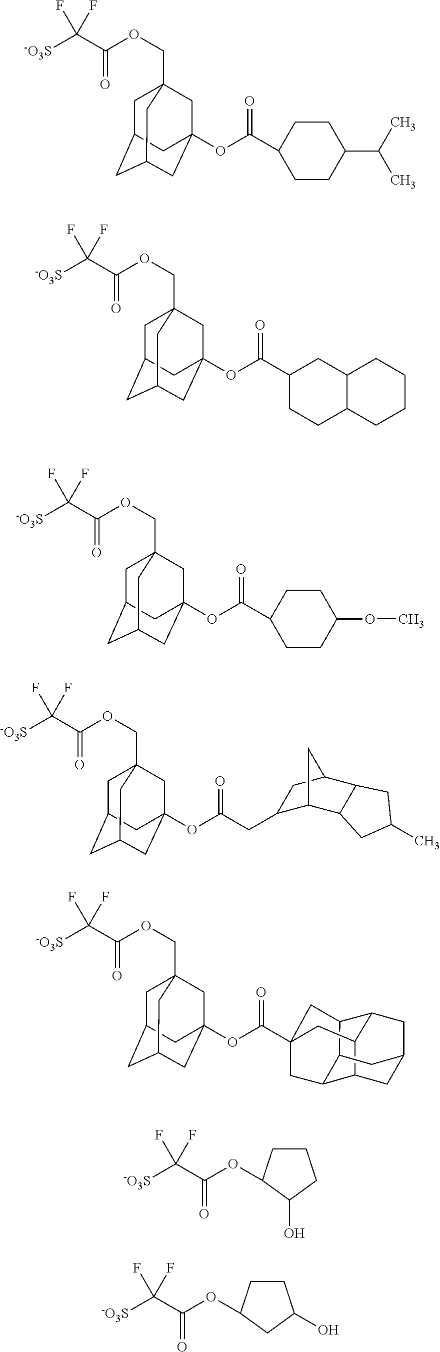

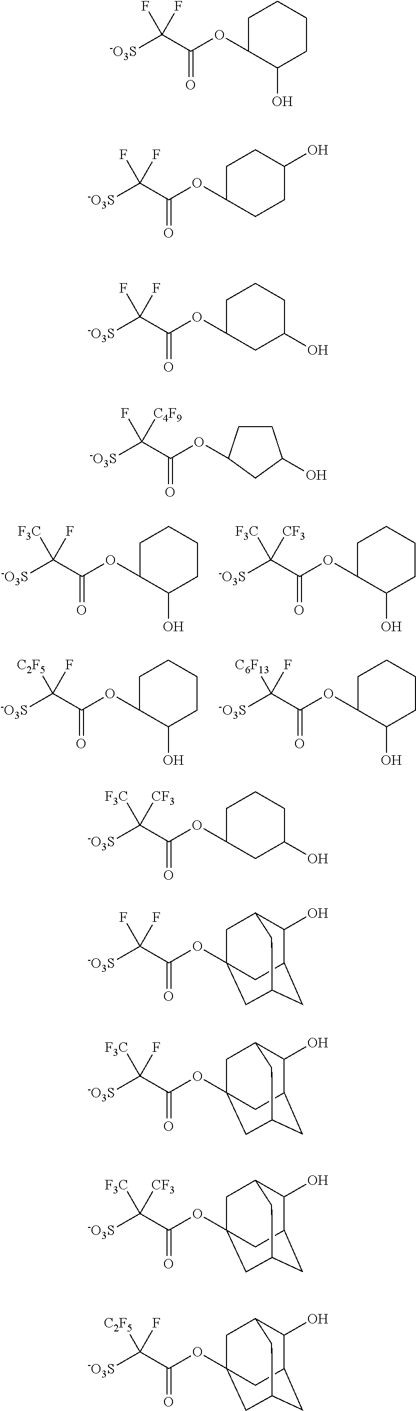

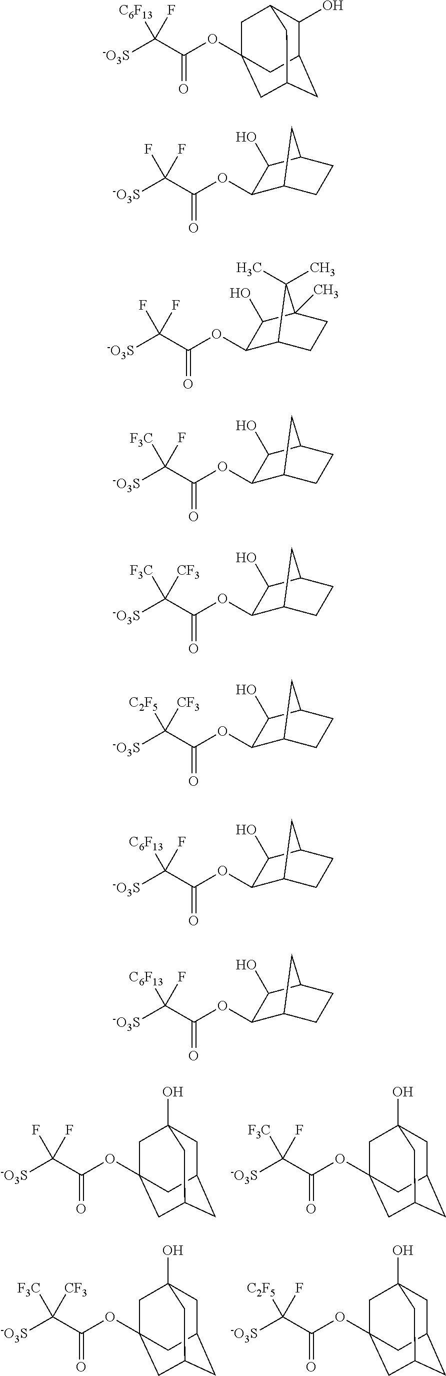

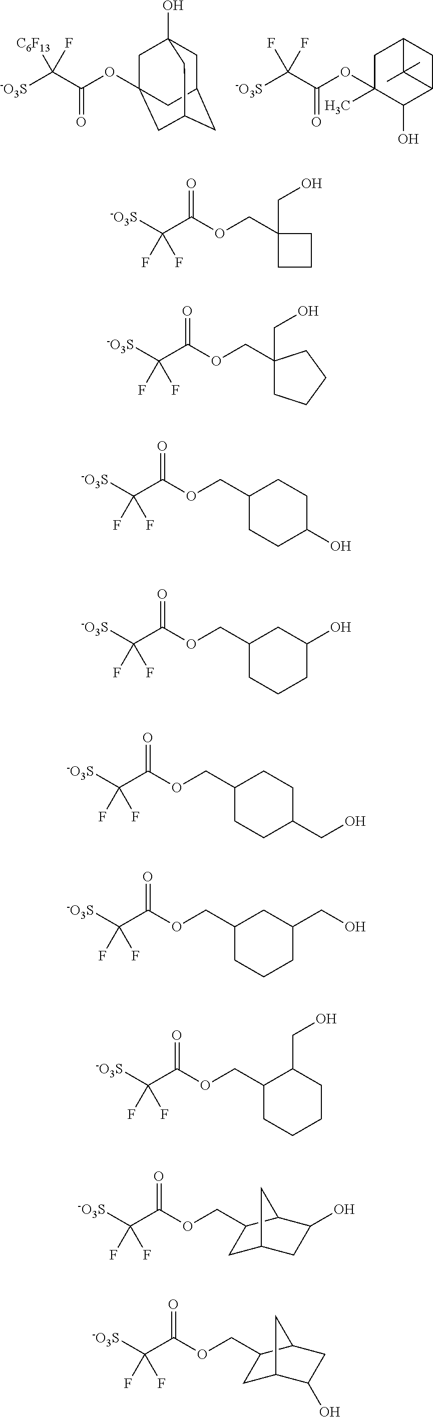

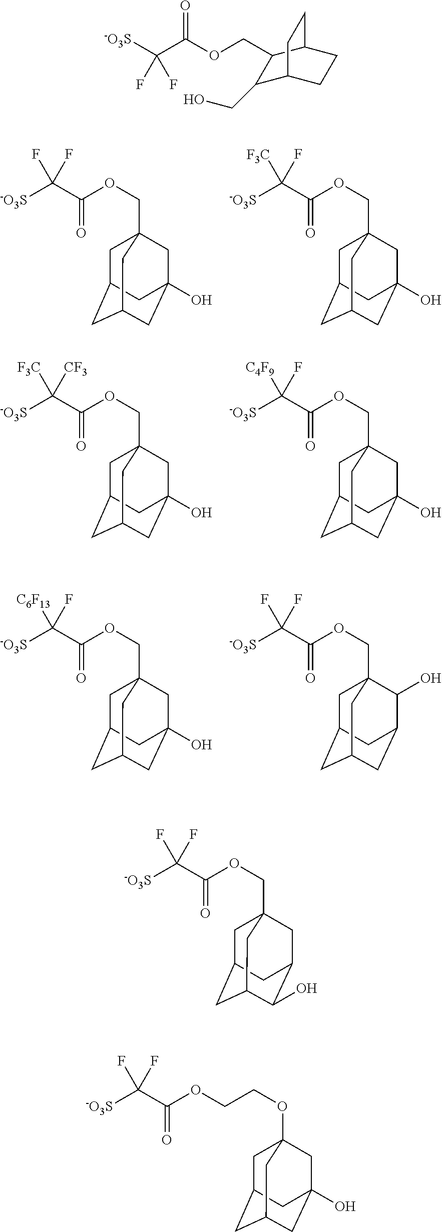

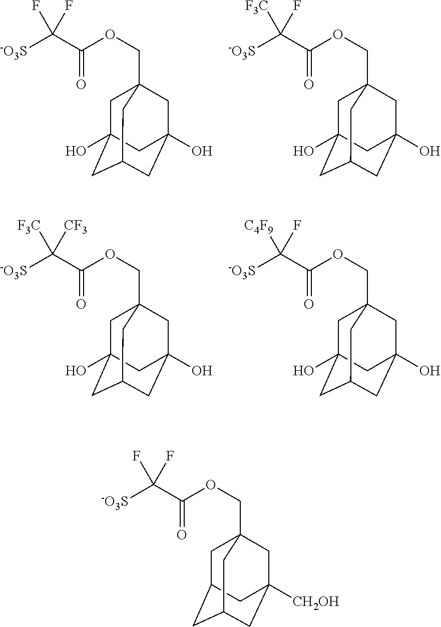

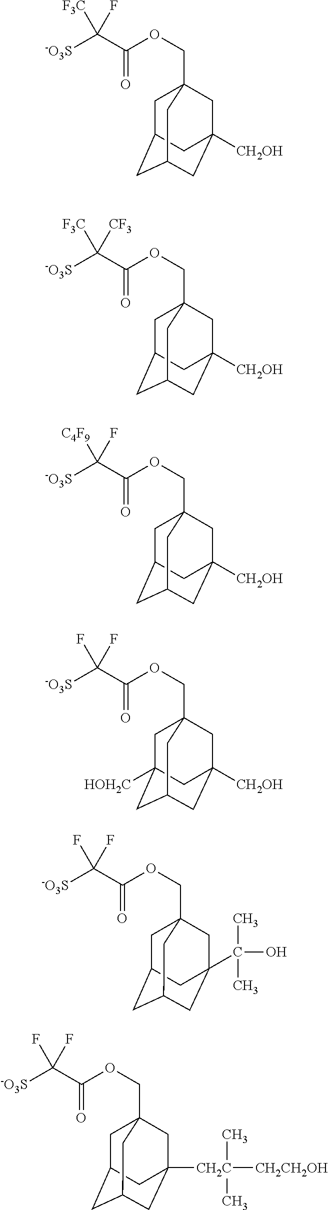

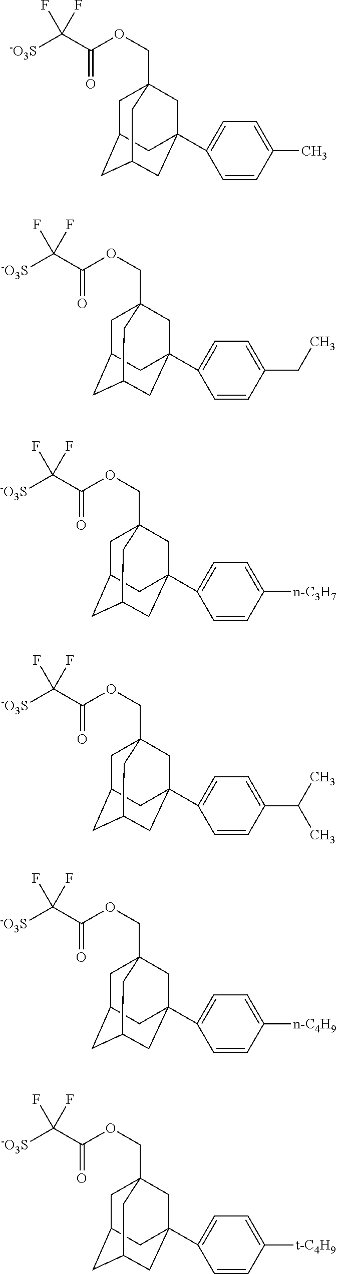

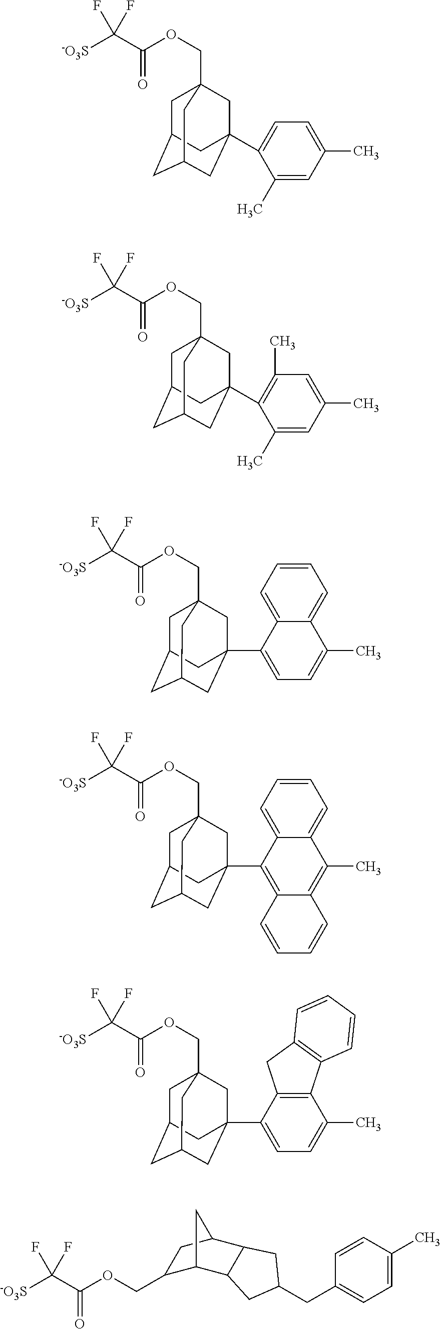

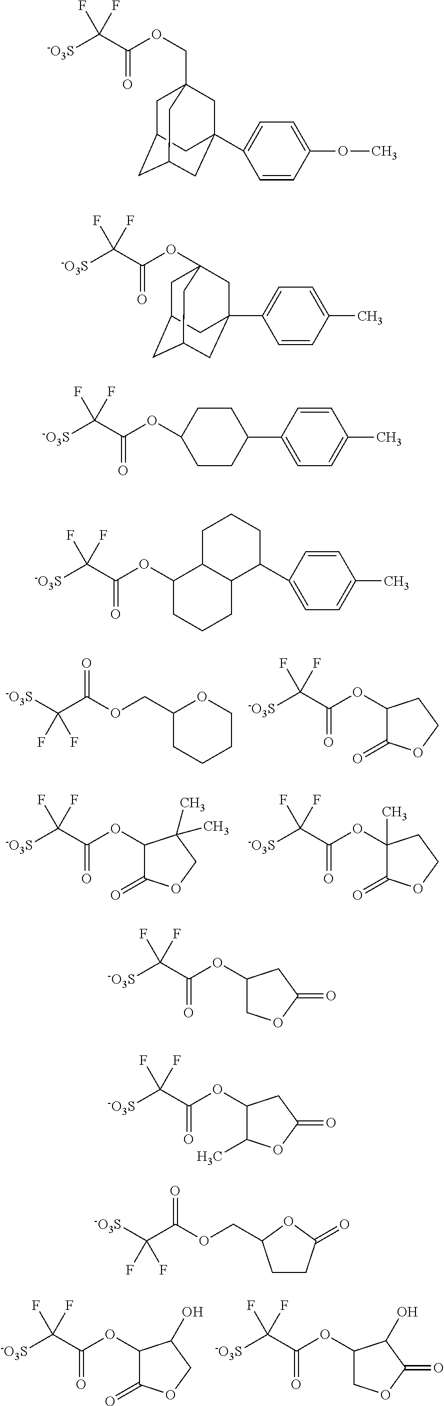

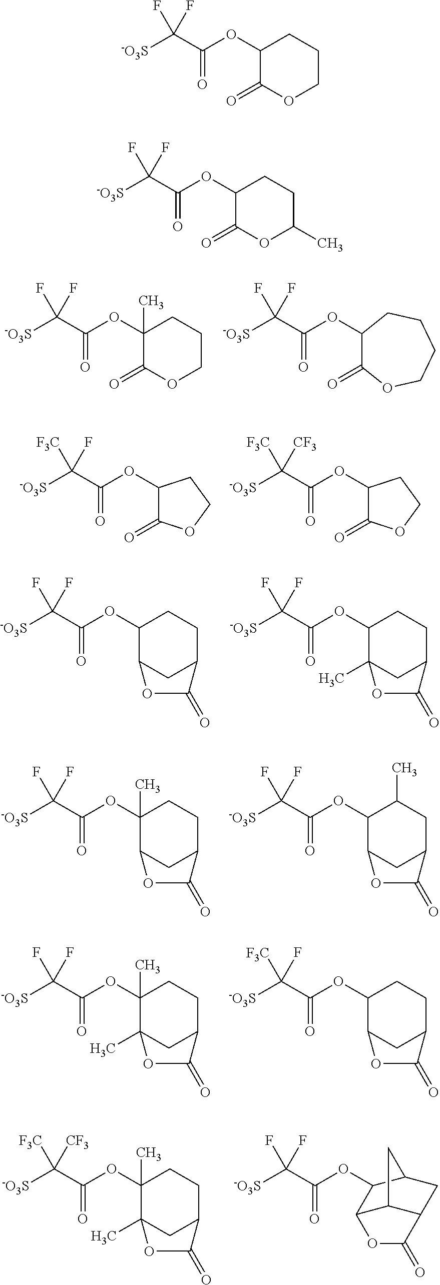

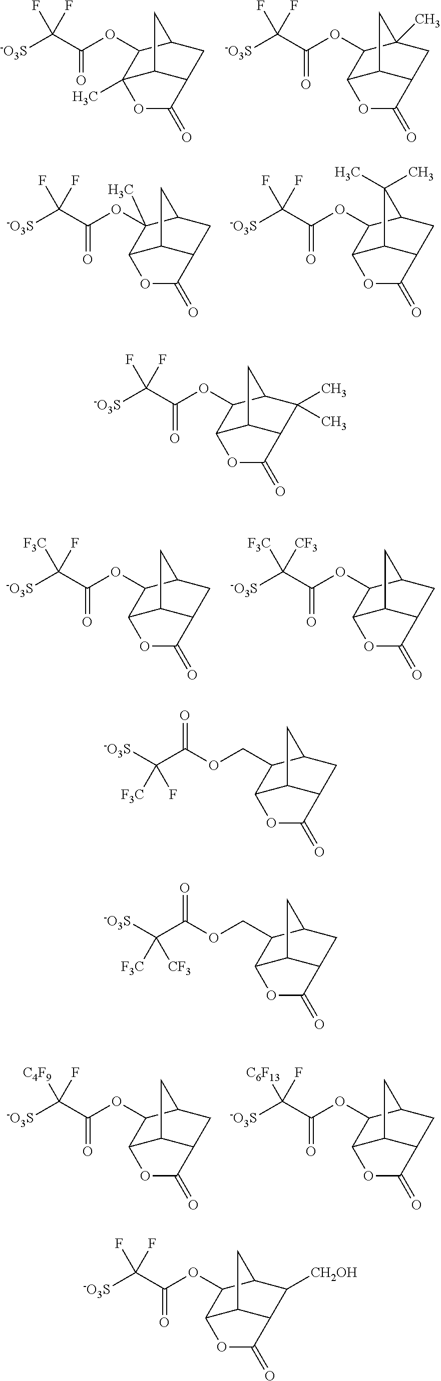

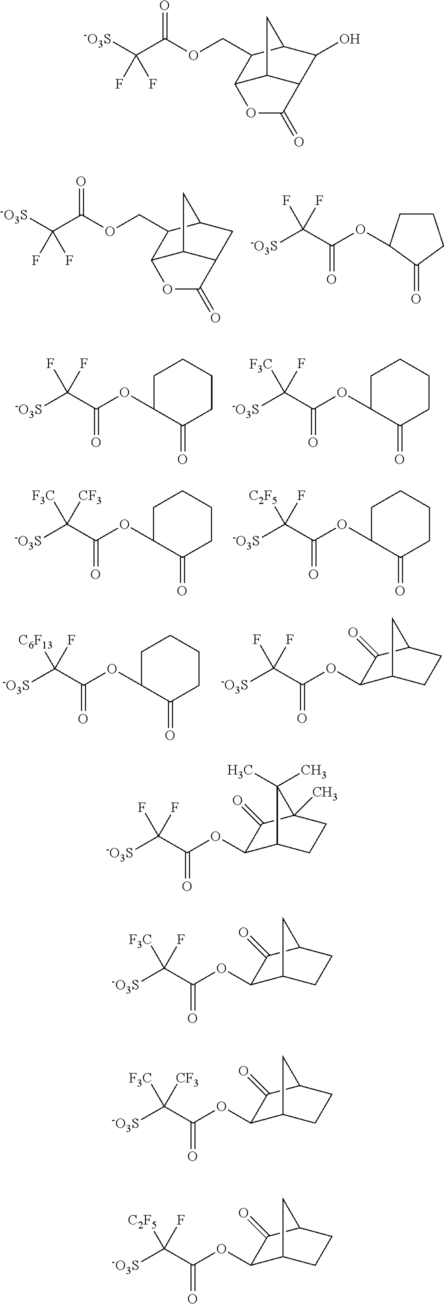

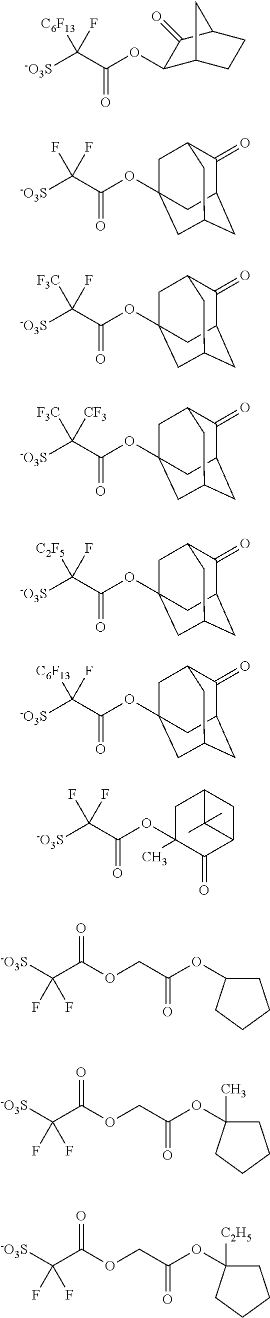

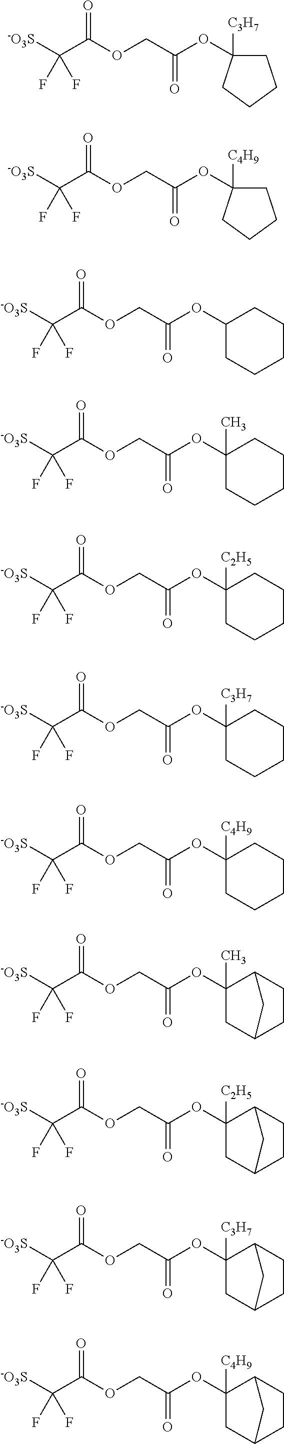

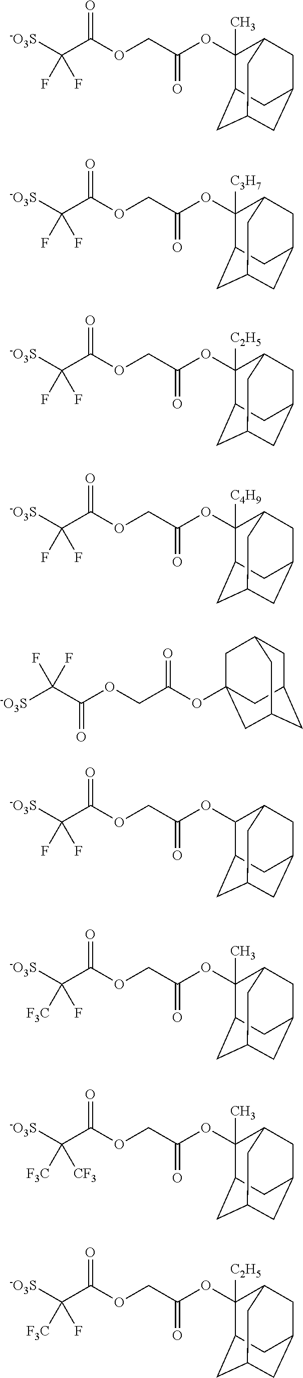

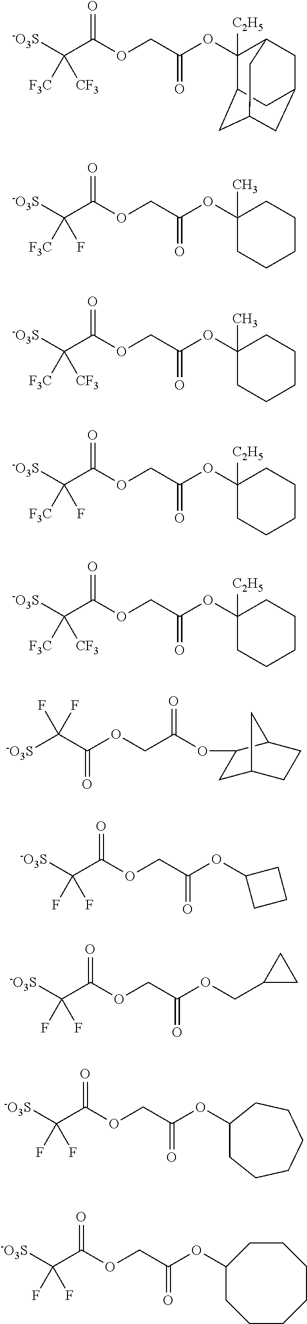

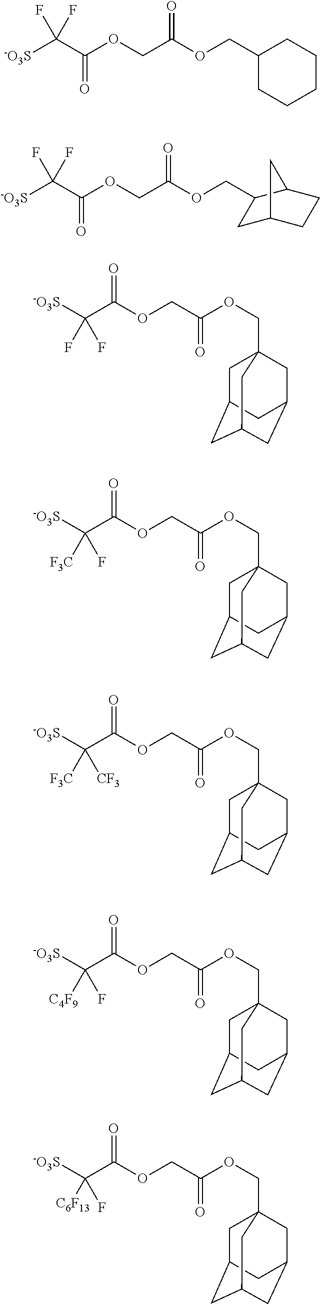

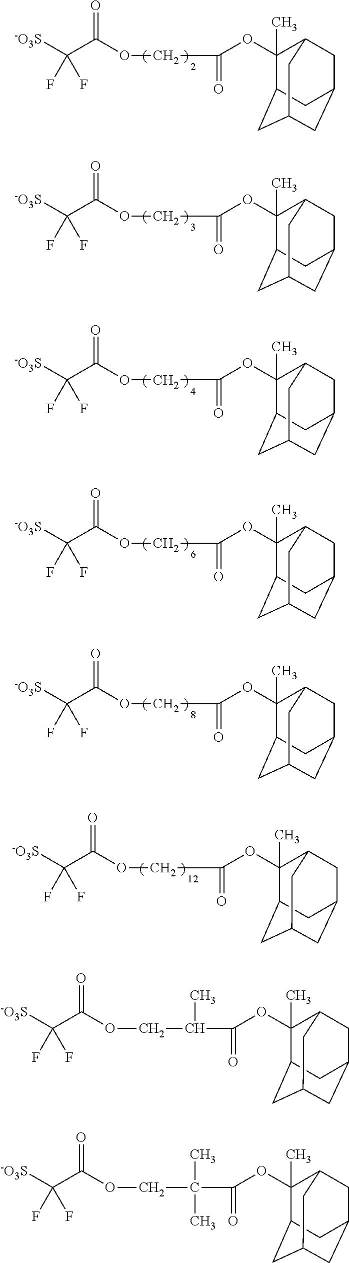

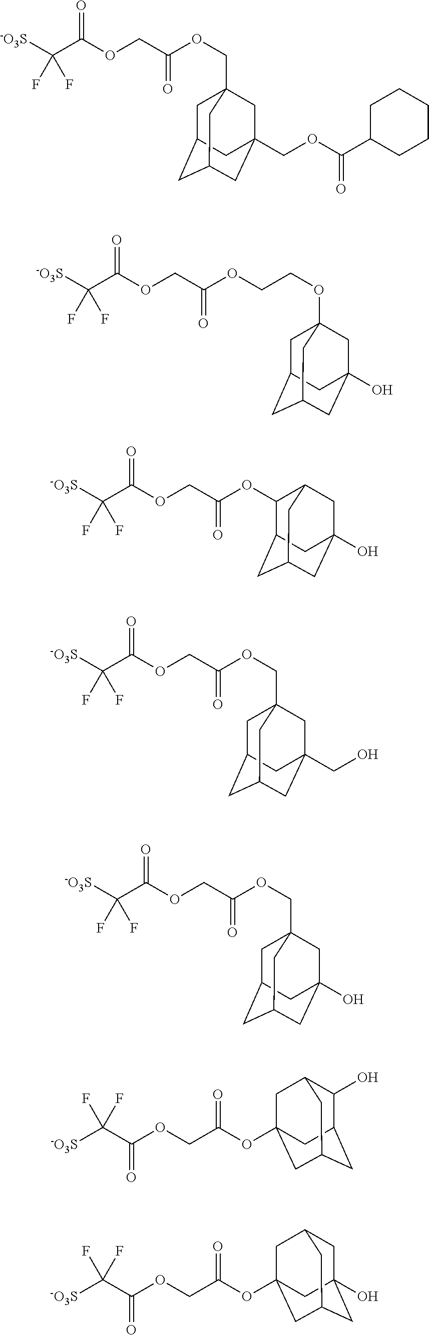

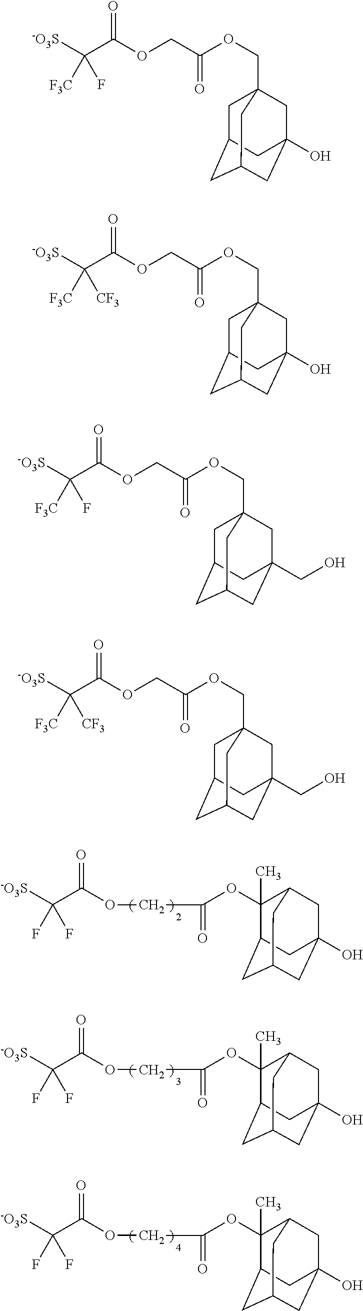

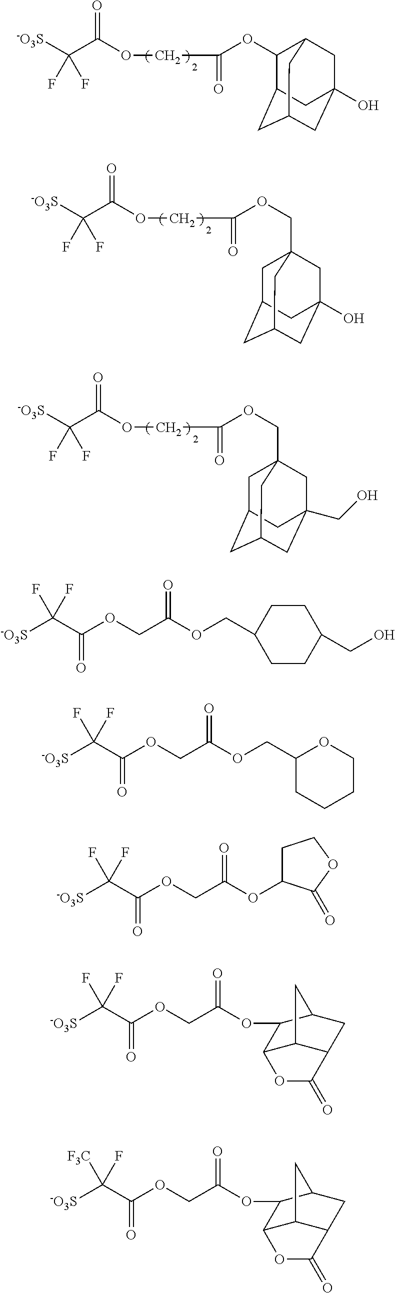

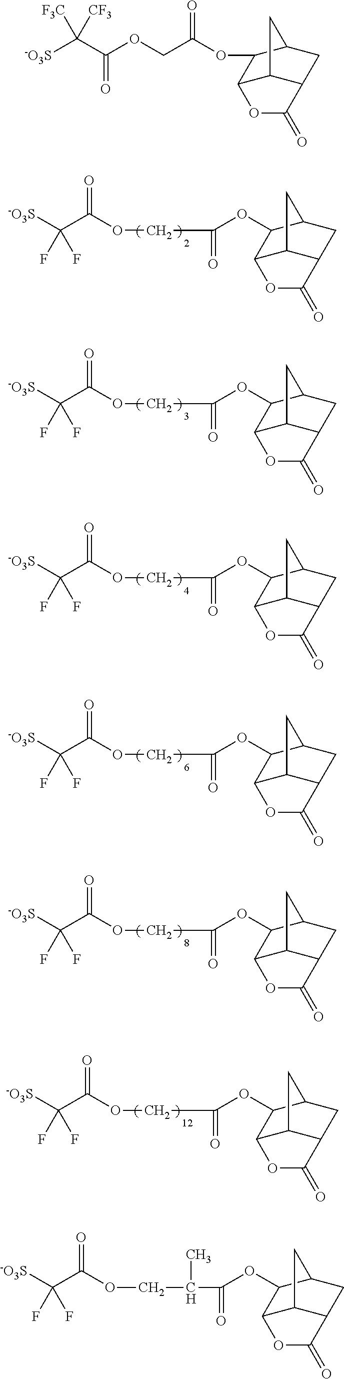

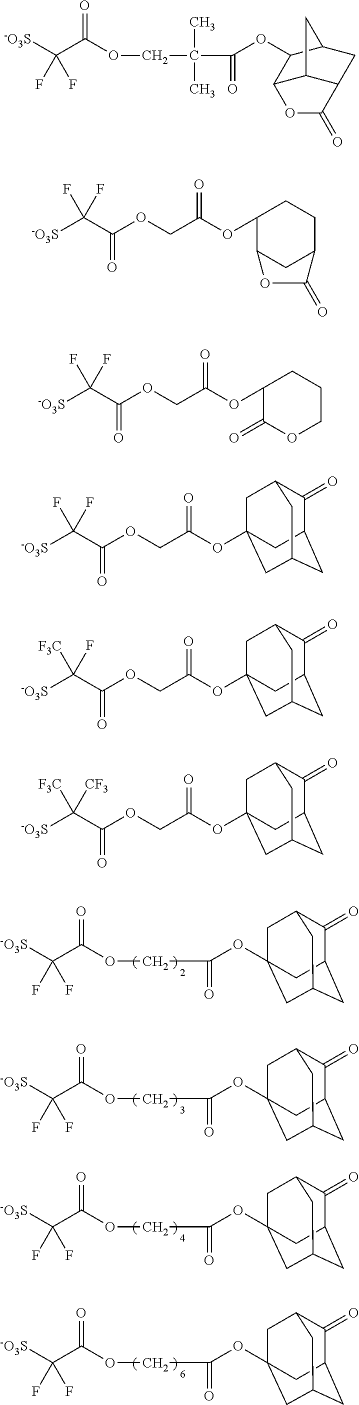

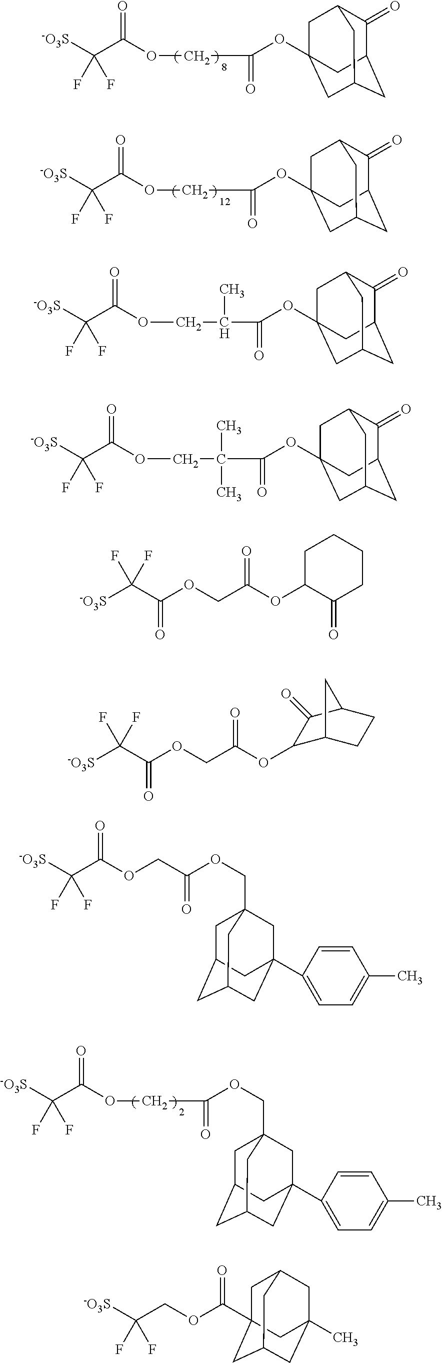

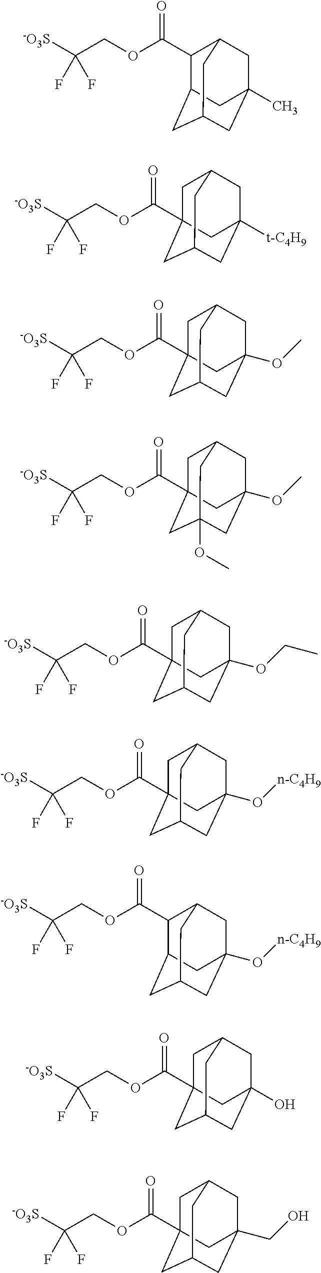

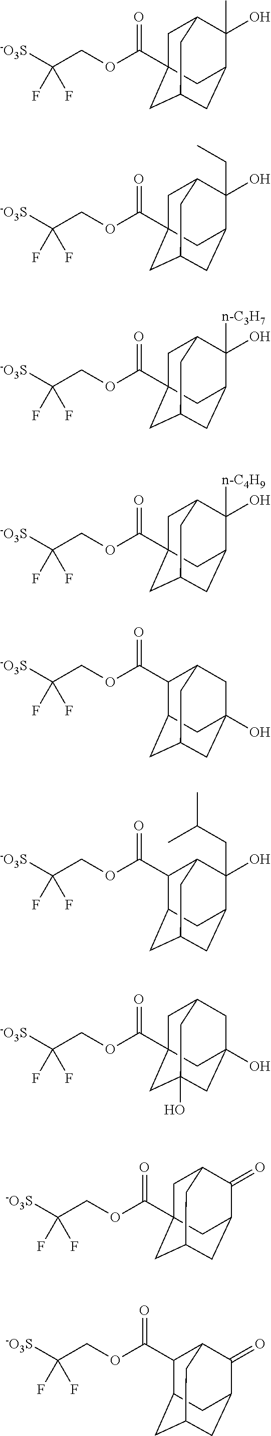

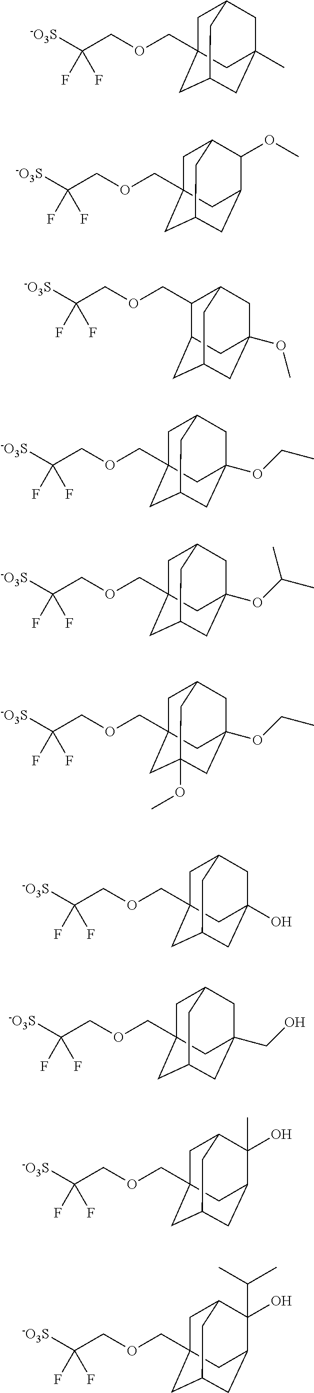

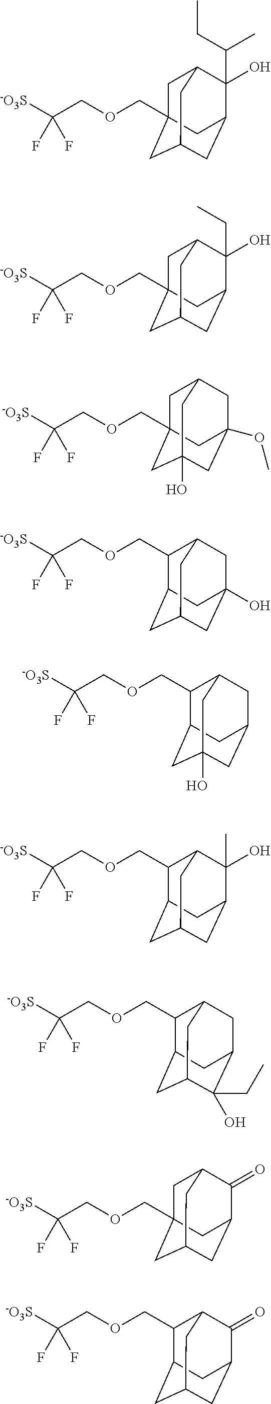

Among them, preferred are the following sulfonic anions.

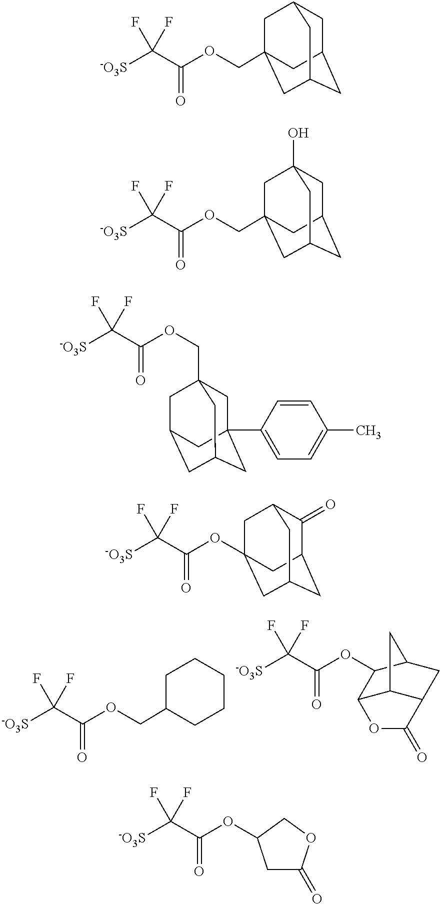

Examples of the cation part represented by Z⁺ include an onium cation such as a sulfonium cation, an iodonium cation, an ammonium cation, a benzothiazolium cation and a phosphonium cation, and a sulfonium cation and an iodonium cation are preferable, and an arylsulfonium cation is more preferable.

Preferable examples of the cation part represented by Z⁺ include the cations represented by the formulae (b2-1) to (b2-4):

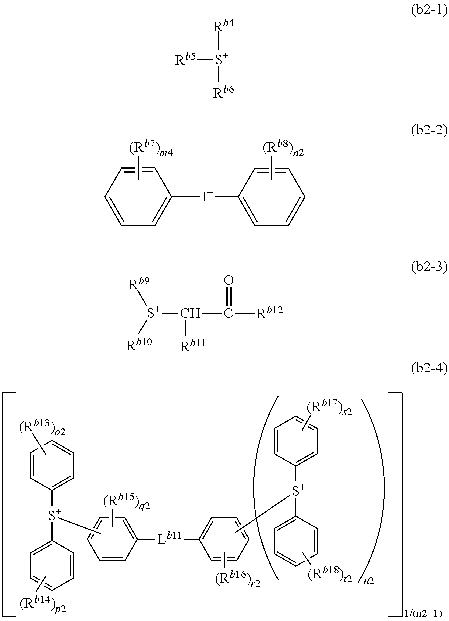

wherein R^{b4}, R^{b5} and R^{b6} each independently represent a C1-C30 aliphatic hydrocarbon group which can have one or more substituents selected from the group consisting of a hydroxyl group, a C1-C12 alkoxy group and a C6-C18 aromatic hydrocarbon group, a C3-C36 saturated cyclic hydrocarbon group which can have one or more substituents selected from the group consisting of a halogen atom, a C2-C4 acyl group and a glycidyloxy group, or a C6-C18 aromatic hydrocarbon group which can have one or more substituents selected from the group consisting of a halogen atom, a hydroxyl group, a C1-C36 aliphatic hydrocarbon group, a C3-C36 saturated cyclic hydrocarbon group or a C1-C12 alkoxy group,
R^{b7} and R^{b8} are independently in each occurrence a hydroxyl group, a C1-C12 aliphatic hydrocarbon group or a C1-C12 alkoxy group, m4 and n2 independently represents an integer of 0 to 5, R^{b9} and R^{b10} each independently represent a C1-C36 aliphatic hydrocarbon group or a C3-C36 saturated cyclic hydrocarbon group, or R^{b9} and R^{b10} are bonded to form a C2-C11 divalent acyclic hydrocarbon group which forms a ring together with the adjacent S⁺, and one or more —CH₂— in the divalent acyclic hydrocarbon group may be replaced by —CO—, —O— or —S—, and
R^{b11} represents a hydrogen atom, a C1-C36 aliphatic hydrocarbon group, a C3-C36 saturated cyclic hydrocarbon group or a C6-C18 aromatic hydrocarbon group, R^{b12} represents a C1-C12 aliphatic hydrocarbon group, a C6-C18 saturated cyclic hydrocarbon group or a C6-C18 aromatic hydrocarbon group and the aromatic hydrocarbon group can have one or more substituents selected from the group consisting of a C1-C12 aliphatic hydrocarbon group, a C1-C12 alkoxy group, a C3-C18 saturated cyclic hydrocarbon group and an C2-C13 acyloxy group, or R^{b11} and R^{b12} are bonded each other to form a C1-C10 divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S—, and
R^{b13}, R^{b14}, R^{b15}, R^{b16}, R^{b17} and R^{b18} each independently represent a hydroxyl group, a C1-C12 aliphatic hydrocarbon group or a C1-C12 alkoxy group, L^{b11} represents —S— or —O— and o2, p2, s2 and t2 each independently represents an integer of 0 to 5, q2 and r2 each independently represents an integer of 0 to 4, and u2 represents 0 or 1.

The aliphatic hydrocarbon group represented by R^{b9} to R^{b11} has preferably 1 to 12 carbon atoms. The saturated cyclic hydrocarbon group represented by R^{b9} to R^{b11} has preferably 3 to 18 carbon atoms and more preferably 4 to 12 carbon atoms.

Examples of the aliphatic hydrocarbon group, the saturated cyclic hydrocarbon group and the aromatic hydrocarbon group include the same as described above. Preferable examples of the aliphatic hydrocarbon group include a methyl group, an ethyl group, a propyl group, an isopropyl group, a butyl group, a sec-butyl group, a tert-butyl group, a pentyl group, a hexyl group, an octyl group and a 2-ethylhexyl group. Preferable examples of the saturated cyclic hydrocarbon group include a cyclopropyl group, a cyclobutyl group, a cyclopentyl group, a cyclohexyl group, a cycloheptyl group, a cyclodecyl group, a 2-alkyl-2-adamantyl group, a 1-(1-adamantyl)-1-alkyl group and an isobornyl group. Preferable examples of the aromatic group include a phenyl group, a 4-methylphenyl group, a 4-ethylphenyl group, a 4-tert-butylphenyl group, a 4-cyclohexylphenyl group, a 4-methoxyphenyl group, a biphenyl group and a naphthyl group. Examples of the aliphatic hydrocarbon group having an aromatic hydrocarbon group include a benzyl group. Examples of the alkoxy group include a methoxy group, an ethoxy group, a propoxy group, an isopropoxy group, a butoxy group, a sec-butoxy group, a tert-butoxy group, a pentyloxy group, a hexyloxy group, a heptyloxy group, an octyloxy group, a 2-ethylhexyloxy group, a nonyloxy group, a decyloxy group, an undecyloxy group and a dodecyloxy group.

Examples of the C3-C12 divalent acyclic hydrocarbon group formed by bonding R^{b9} and R^{b10} include a trimethylene group, a tetramethylene group and a pentamethylene group. Examples of the ring group formed together with the adjacent S⁺ and the divalent acyclic hydrocarbon group include a thiolan-1-ium ring (tetrahydrothiphenium ring), a thian-1-ium ring and a 1,4-oxathian-4-ium ring. A C3-C7 divalent a cyclic hydrocarbon group is preferable.

Examples of the C1-C10 divalent acyclic hydrocarbon group formed by bonding R^{b11} and R^{b12} include a methylene group, an ethylene group, a trimethylene group, a tetramethylene group and a pentamethylene group and examples of the ring group include the followings.

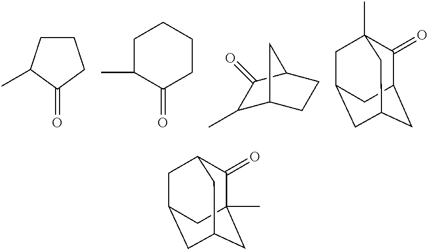

Among the above-mentioned cations, the cation represented by the formula (b2-1) is preferable, and the cation represented by the formula (b2-1-1) is more preferable and a triphenylsulfonium cation is especially preferable.

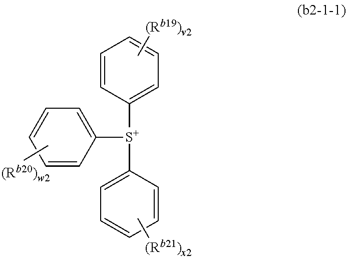

wherein R^{b19}, R^{b20} and R^{b21} are independently in each occurrence a halogen atom, a hydroxyl group, a C1-C36 aliphatic hydrocarbon group, a C3-C36 saturated cyclic hydrocarbon group or a C1-C12 alkoxy group, and one or more hydrogen atoms in the aliphatic hydrocarbon group can be replaced by a hydroxyl group, a C1-C12 alkoxy group or a C6-C18 aromatic hydrocarbon group, one or more hydrogen atoms of the saturated cyclic hydrocarbon group can be replaced by a halogen atom, a C2-C4 acyl group or a glycidyloxy group, and v2, w2 and x2 independently each represent an integer of 0 to 5. The aliphatic hydrocarbon group preferably has 1 to 12-carbon atoms, and the saturated cyclic hydrocarbon group preferably has 4 to 36 carbon atoms, and it is preferred that v2, w2 and x2 independently each represent 0 or 1. It is preferred that R^{b19}, R^{b20} and R^{b21} are independently halogen atom (preferably a fluorine atom), a hydroxyl group, a C1-C12 alkyl group or a C1-C12 alkoxy group.

Examples of the cation represented by the formula (b2-1) include the followings.

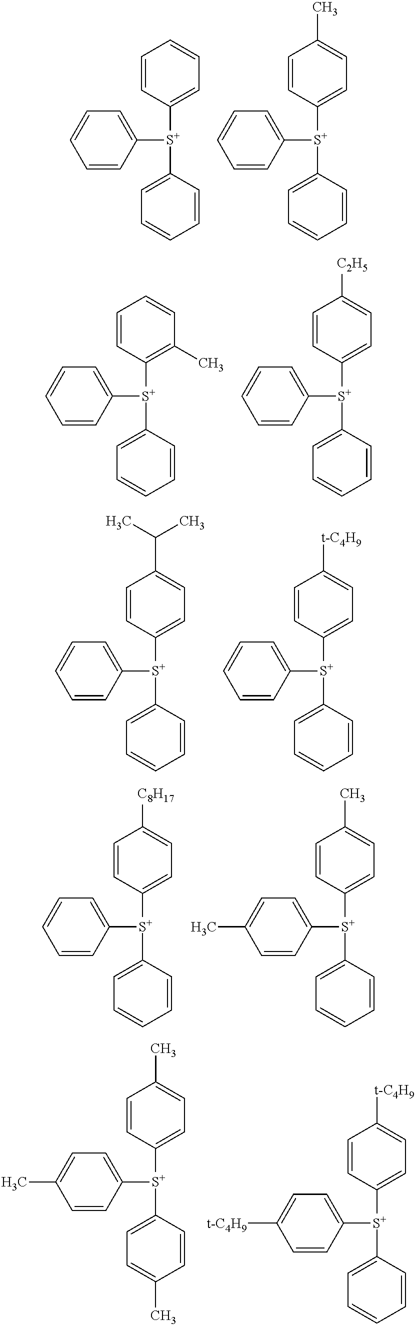

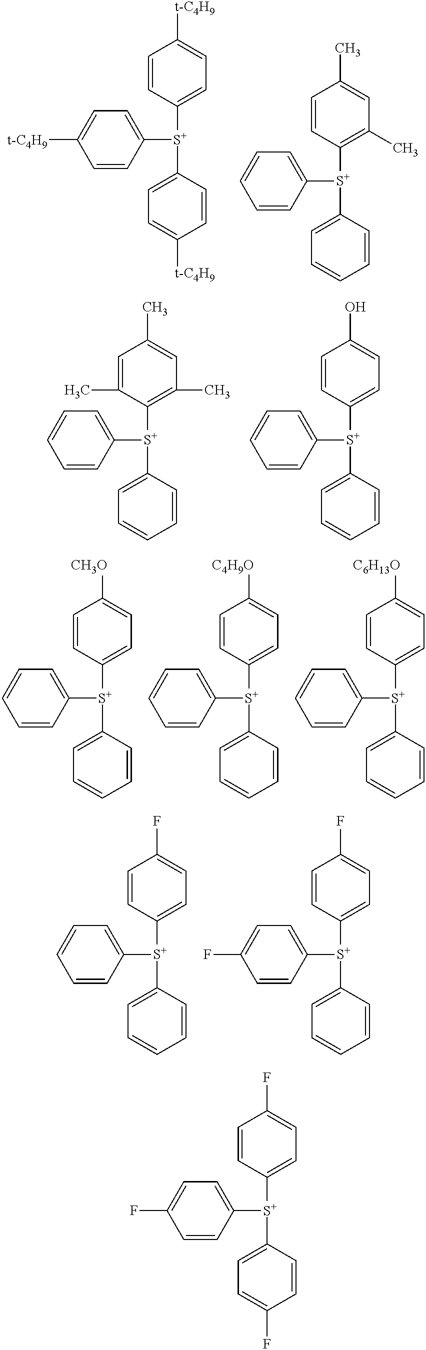

Examples of the cation represented by the formula (b2-2) include the followings.

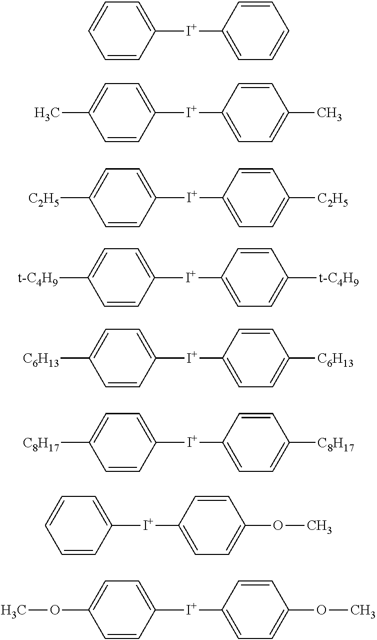

Examples of the cation represented by the formula (b2-3) include the followings.

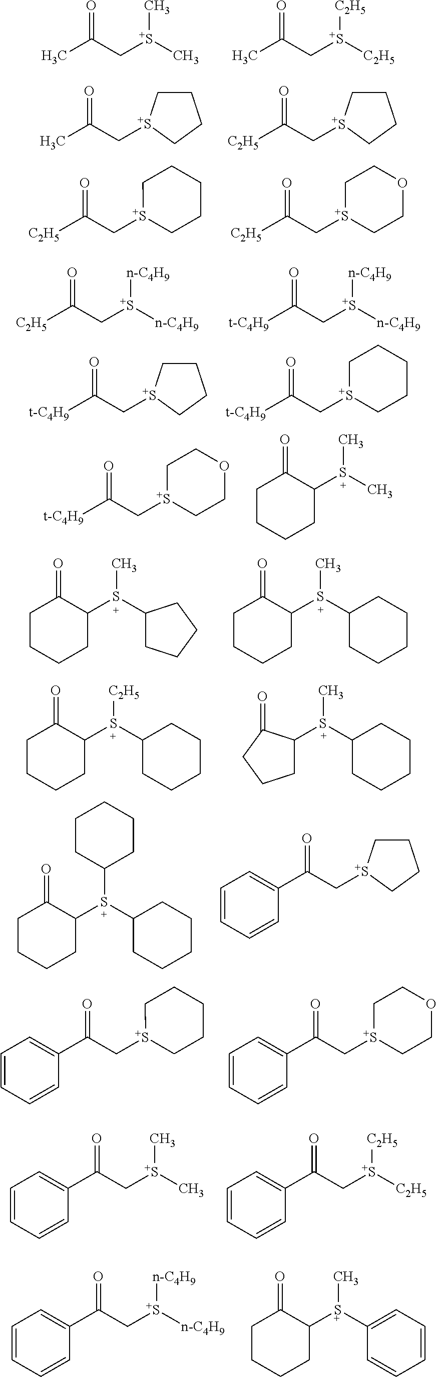

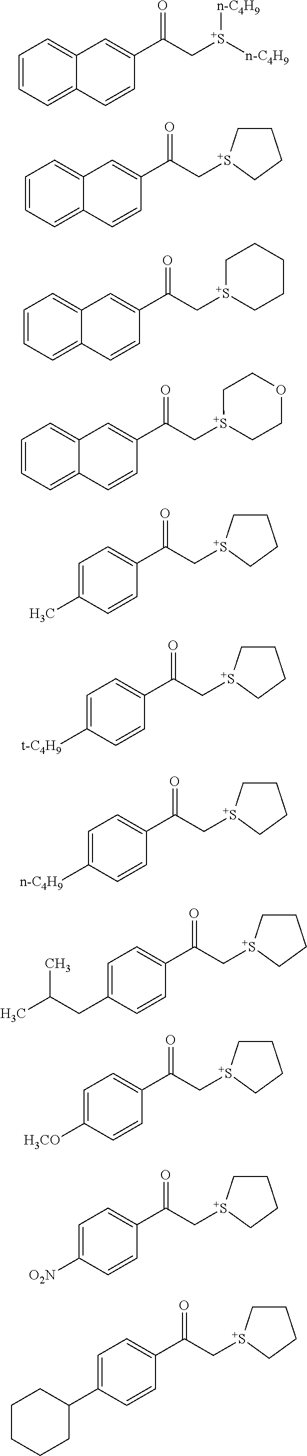

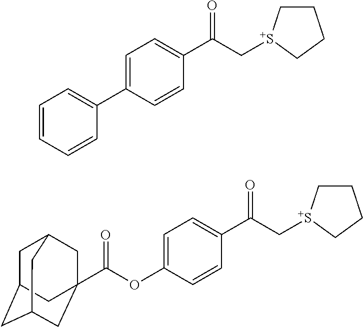

Examples of the cation represented by the formula (b2-4) include the followings.

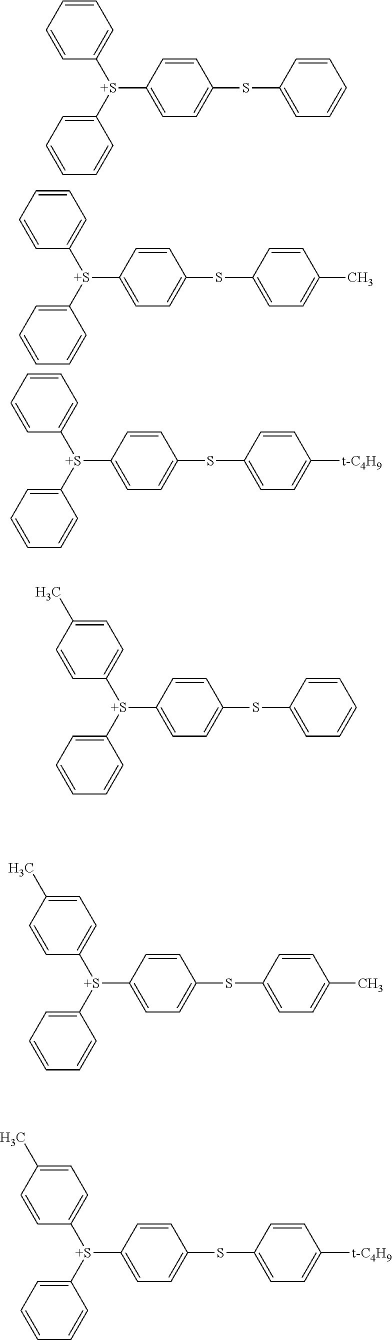

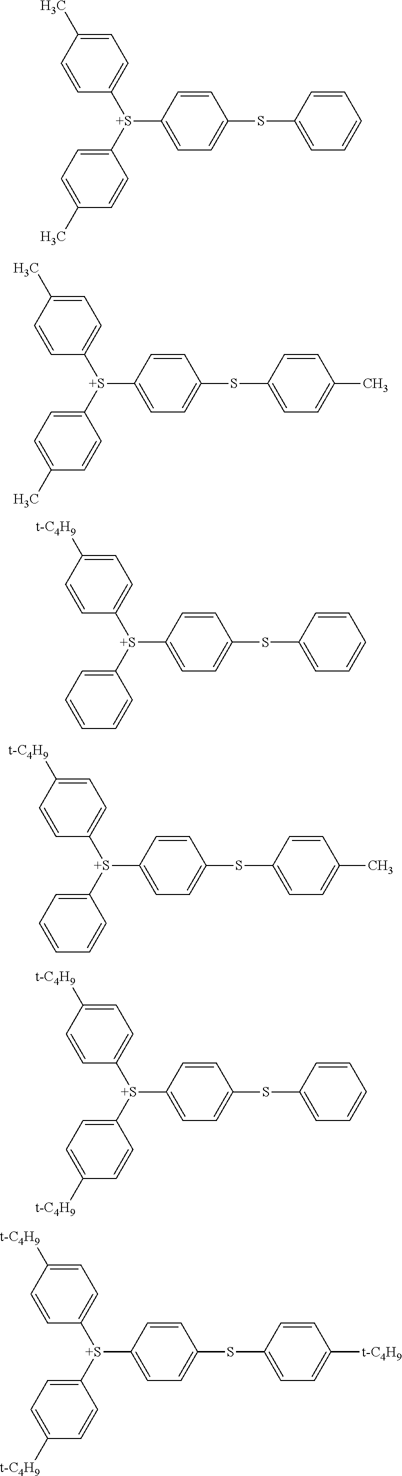

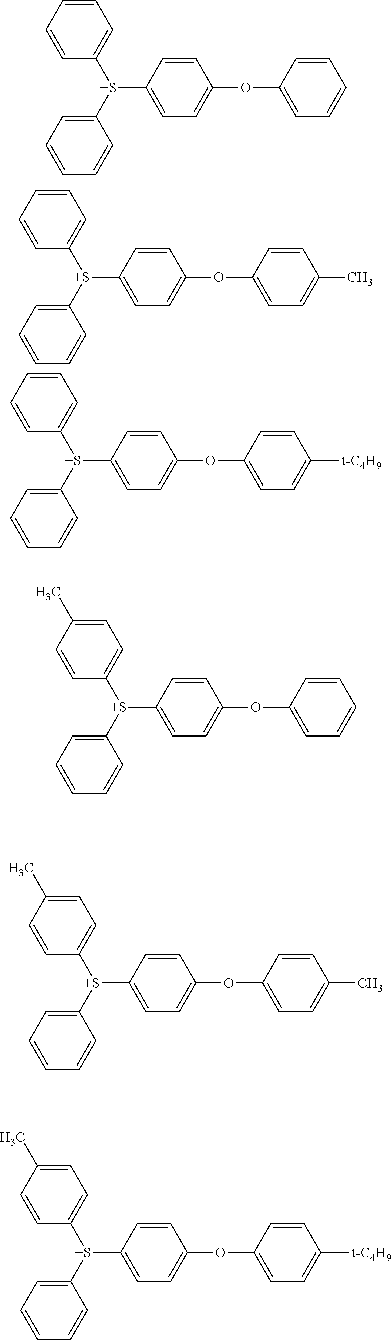

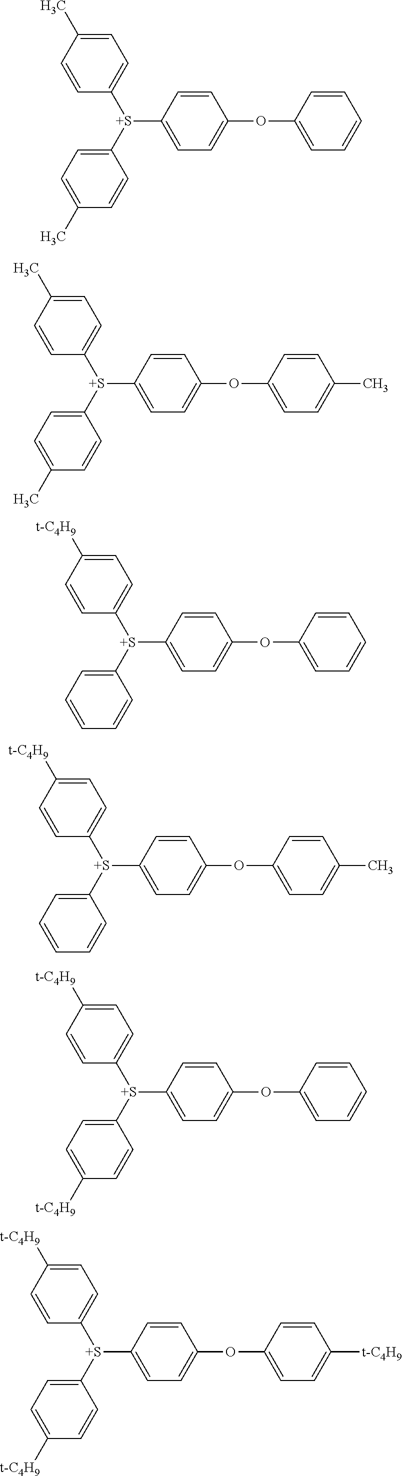

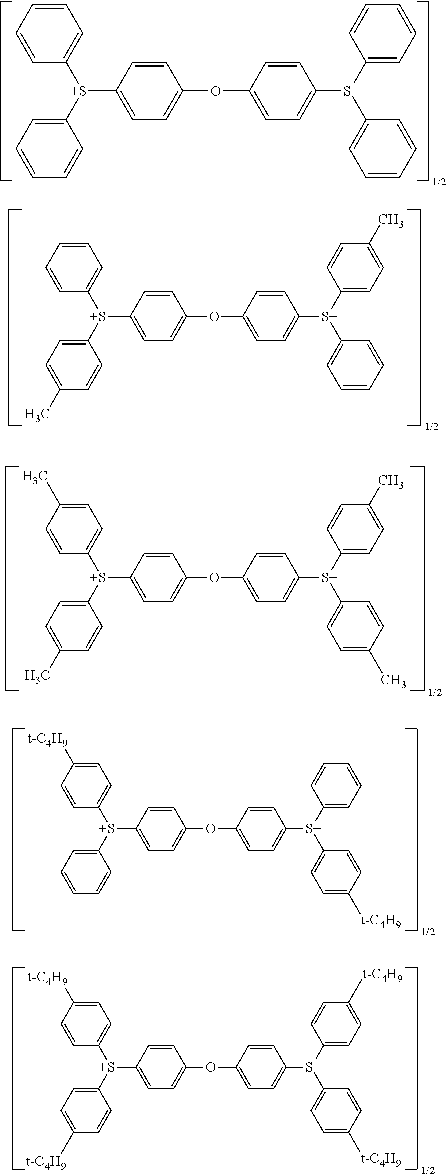

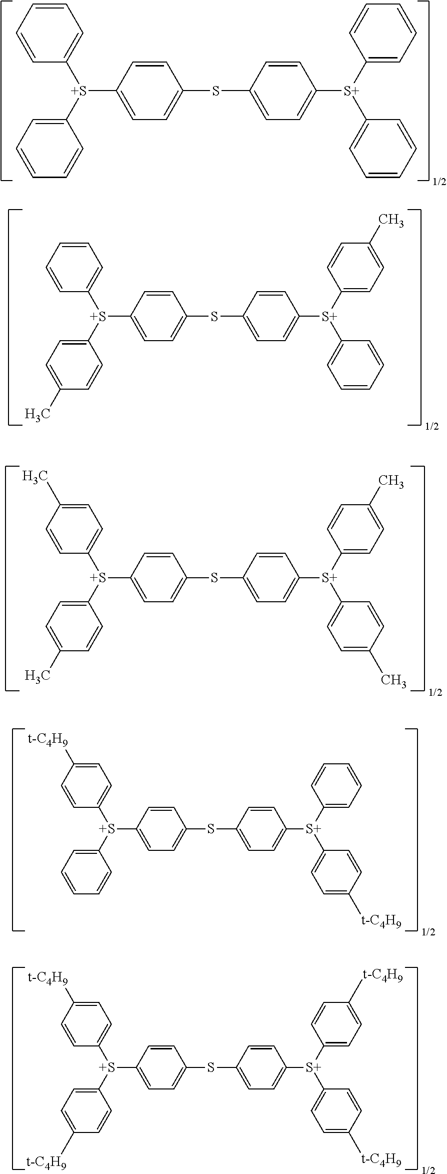

Examples of Acid Generator (II) include a salt wherein the anion part is any one of the above-mentioned anion part and the cation part is any one of the above-mentioned cation part. Preferable examples of Acid Generator (II) include a combination of any one of anions represented by the formulae (IIa-1) to (IIa-9) and the cation represented by the formulae (b2-1-1).

The salt represented by the formulae (II-1) to (II-17) are preferable, and the salt represented by the formulae (II-1), (II-2), (II-6), (II-11), (II-12), (II-13) and (II-14) are more preferable.

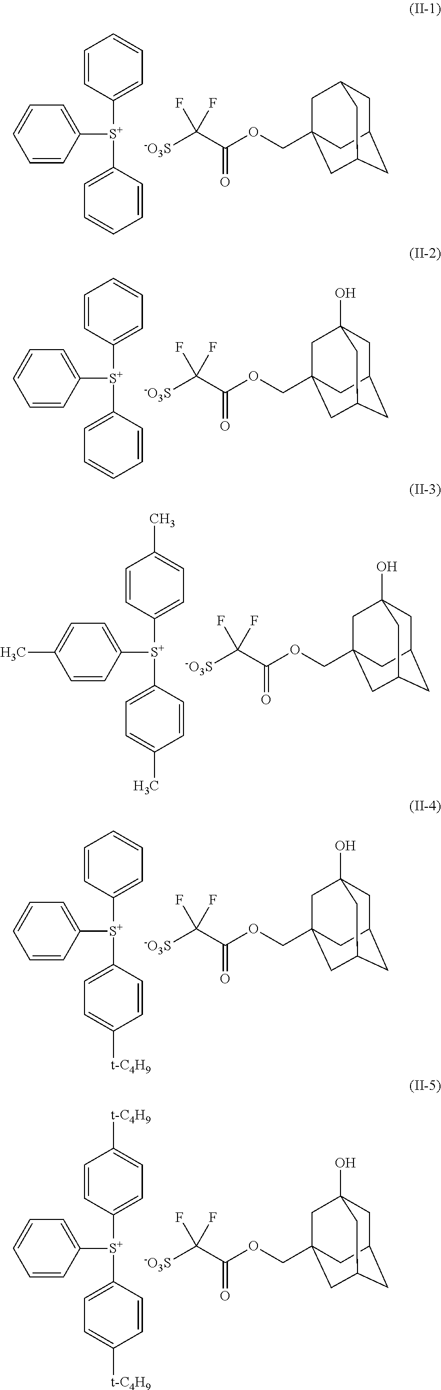

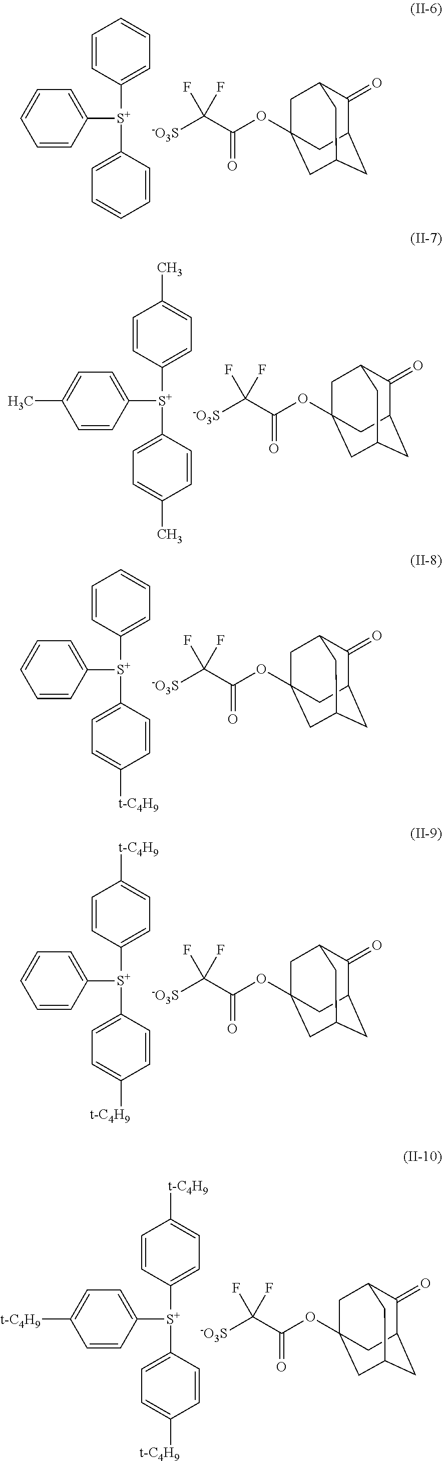

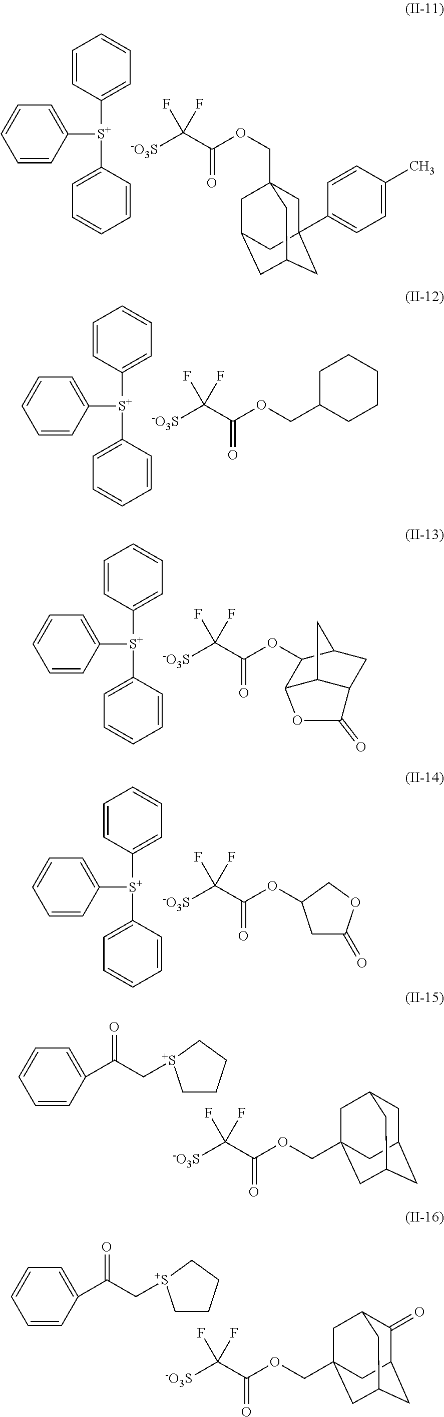

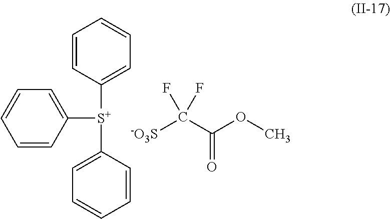

Two or more kinds of Acid Generator (II) can be used in combination.

Acid Generator (II) can be produced according to know methods.

The content of Acid Generator (II) is preferably 1 part by weight or more and more preferably 3 parts by weight or more per 100 parts by weight of Resin (A). The content of the acid generator is preferably 30 parts by weight or less and more preferably 25 parts by weight or less per 100 parts by weight of Resin (A).

The photoresist composition of the present invention can contain a basic compound as a quencher.

The basic compound is preferably a basic nitrogen-containing organic compound, and examples thereof include an amine compound such as an aliphatic amine and an aromatic amine and an ammonium salt. Examples of the aliphatic amine include a primary amine, a secondary amine and a tertiary amine. Examples of the aromatic amine include an aromatic amine in which aromatic ring has one or more amino groups such as aniline and a heteroaromatic amine such as pyridine. Preferable examples thereof include an aromatic amine represented by the formula (C2):

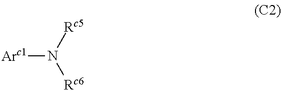

wherein Ar^{c1} represents an aromatic hydrocarbon group, and R^{c5} and R^{c6} each independently represent a hydrogen atom, an aliphatic hydrocarbon group, a saturated cyclic hydrocarbon group or an aromatic hydrocarbon group, and the aliphatic hydrocarbon group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group.

The aliphatic hydrocarbon group is preferably an alkyl group and the saturated cyclic hydrocarbon group is preferably a cycloalkyl group. The aliphatic hydrocarbon group preferably has 1 to 6 carbon atoms. The saturated cyclic hydrocarbon group preferably has 5 to 10 carbon atoms. The aromatic hydrocarbon group preferably has 6 to 10 carbon atoms.

As the aromatic amine represented by the formula (C2), an amine represented by the formula (C2-1):

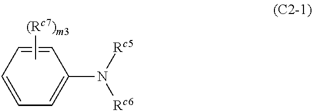

wherein R^{c5} and R^{c6} are the same as defined above, and R^{c7} is independently in each occurrence an aliphatic hydrocarbon group, an alkoxy group, a saturated cyclic hydrocarbon group or an aromatic hydrocarbon group, and the aliphatic hydrocarbon group, the alkoxy group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group, and m3 represents an integer of 0 to 3, is preferable. The aliphatic hydrocarbon group is preferably an alkyl group and the saturated cyclic hydrocarbon group is preferably a cycloalkyl group. The aliphatic hydrocarbon group preferably has 1 to 6 carbon atoms.

The saturated cyclic hydrocarbon group preferably has 5 to 10 carbon atoms. The aromatic hydrocarbon group preferably has 6 to 10 carbon atoms. The alkoxy group preferably has 1 to 6 carbon atoms.

Examples of the aromatic amine represented by the formula (C2) include 1-naphthylamine, 2-naphthylamine, aniline, diisopropylaniline, 2-methylaniline, 3-methylaniline, 4-methylaniline, 4-nitroaniline, N-methylaniline, N,N-dimethylaniline, and diphenylamine, and among them, preferred is diisopropylaniline and more preferred is 2,6-diisopropylaniline.

Other examples of the basic compound include amines represented by the formulae (C3) to (C11):

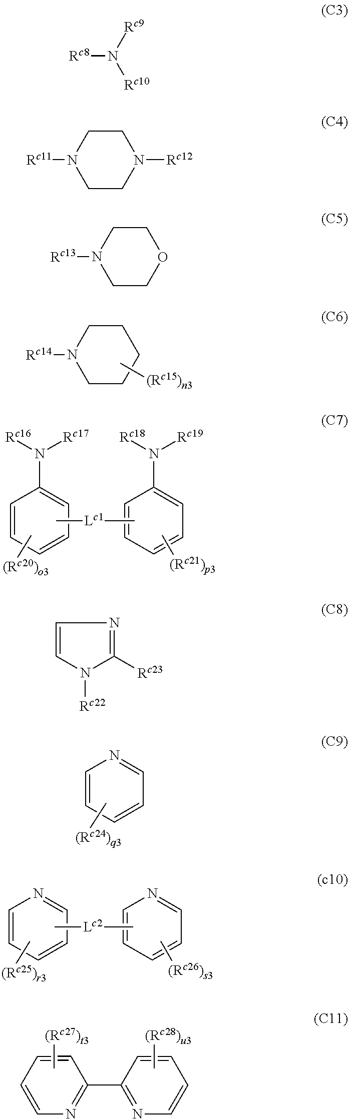

wherein R^{c8}, R^{c20}, R^{c21}, and R^{c23} to R^{c28} each independently represent an aliphatic hydrocarbon group, an alkoxy group, a saturated cyclic hydrocarbon group or an aromatic hydrocarbon group, and the aliphatic hydrocarbon group, the alkoxy group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group,
R^{c9}, R^{c10}, R^{c11} to R^{c14}, R^{c16} to R^{c19} and R^{c22} each independently represents a hydrogen atom, an aliphatic hydrocarbon group, a saturated cyclic hydrocarbon group or an aromatic hydrocarbon group, and the aliphatic hydrocarbon group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group,
R^{c15} is independently in each occurrence an aliphatic hydrocarbon group, a saturated cyclic hydrocarbon group or an alkanoyl group, L^{c1} and L^{c2} each independently represents a divalent aliphatic hydrocarbon group, —CO—, —C(═NH)—, —C(═NR^{c3})—, —S—, —S—S— or a combination thereof and R^{c3} represents a C1-C4 alkyl group, O3 to u3 each independently represents an integer of 0 to 3 and n3 represents an integer of 0 to 8.

The aliphatic hydrocarbon group has preferably 1 to 6 carbon atoms, and the saturated cyclic hydrocarbon group has preferably 3 to 6 carbon atoms, and the alkanoyl group has preferably 2 to 6 carbon atoms, and the divalent aliphatic hydrocarbon group has preferably 1 to 6 carbon atoms. The divalent aliphatic hydrocarbon group is preferably an alkylene group.

Examples of the amine represented by the formula (C3) include hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethydipentylamine, ethyldihexylamine, ethydiheptylamine, ethyldioctylamine, ethyldinonylamine, ethyldidecylamine, dicyclohexylmethylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane and 4,4′-diamino-3,3′-diethyldiphenylmethane.

Examples of the amine represented by the formula (C4) include piperazine. Examples of the amine represented by the formula (C5) include morpholine. Examples of the amine represented by the formula (C6) include piperidine and hindered amine compounds having a piperidine skeleton as disclosed in JP 11-52575 A. Examples of the amine represented by the formula (C7) include 2,2′-methylenebisaniline. Examples of the amine represented by the formula (C8) include imidazole and 4-methylimidazole. Examples of the amine represented by the formula (C9) include pyridine and 4-methylpyridine. Examples of the amine represented by the formula (C10) include di-2-pyridyl ketone, 1,2-di(2-pyridyl)ethane, 1,2-di(4-pyridyl)ethane, 1,3-di(4-pyridyl) propane, 1,2-bis(2-pyridyl)ethene, 1,2-bis(4-pyridyl)ethene, 1,2-di(4-pyridyloxy)ethane, 4,4′-dipyridyl sulfide, 4,4′-dipyridyl disulfide, 2,2′-dipyridylamine and 2,2′-dipicolylamine. Examples of the amine represented by the formula (C11) include bipyridine.

Examples of the ammonium salt include tetramethylammonium hydroxide, tetraisopropylammonium hydroxide, tetrabutylammonium hydroxide, tetrahexylainmonium hydroxide, tetraoctylammonium hydroxide, phenyltrimethylammonium hydroxide, 3-(trifluoromethyl)phenyltrimethylammonium hydroxide, tetrabutylammonium salicylate and (2-hydroxyethyl)trimethylammonium hydroxide (commonly known as “choline”).

When the basic compound is used, the photoresist composition preferably includes 0.01 to 1% by weight of the basic compound based on sum of solid component.

The photoresist composition of the present invention usually contains one or more solvents. Examples of the solvent include a glycol ether ester such as ethyl cellosolve acetate, methyl cellosolve acetate and propylene glycol monomethyl ether acetate; a glycol ether such as propylene glycol monomethyl ether; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone.

The amount of the solvent is usually 90% by weight or more, preferably 92% by weight or more preferably 94% by weight or more based on total amount of the photoresist composition of the present invention. The amount of the solvent is usually 99.9% by weight or less and preferably 99% by weight or less based on total amount of the photoresist composition of the present invention.

The photoresist composition of the present invention can contain, if necessary, a small amount of various additives such as a sensitizer, a dissolution inhibitor, other polymers, a surfactant, a stabilizer and a dye as long as the effect of the present invention is not prevented.

The photoresist compositions of the present invention can be usually produced by mixing Resin (A), Acid Generator (II), a solvent, and if necessary, the basic compound and the other additives followed by filtration with a filter such as a filter having a diameter of 0.2

The photoresist compositions of the present invention are useful for a chemically amplified photoresist composition.

A photoresist pattern can be produced by the following steps (1) to (5):

(1) a step of applying the first or second photoresist composition of the present invention on a substrate,

(2) a step of forming a photoresist film by conducting drying,

(3) a step of exposing the photoresist film to radiation,

(4) a step of baking the exposed photoresist film, and

(5) a step of developing the baked photoresist film with an alkaline developer, thereby forming a photoresist pattern.

The applying of the photoresist composition on a substrate is usually conducted using a conventional apparatus such as spin coater. The photoresist composition is preferably filtrated with filter having 0.2 μm of a pore size before applying. Examples of the substrate include a silicon wafer or a quartz wafer on which a sensor, a circuit, a transistor or the like is formed.

The formation of the photoresist film is usually conducted using a heating apparatus such as hot plate or a decompressor, and the heating temperature is usually 50 to 200° C., and the operation pressure is usually 1 to 1.0*10⁵ Pa.

The photoresist film obtained is exposed to radiation using an exposure system. The exposure is usually conducted through a mask having a pattern corresponding to the desired photoresist pattern. Examples of the exposure source include a light source radiating laser light in a UV-region such as a KrF excimer laser (wavelength: 248 nm), an ArF excimer laser (wavelength: 193 nm) and a F₂ laser (wavelength: 157 nm), and a light source radiating harmonic laser light in a far UV region or a vacuum UV region by wavelength conversion of laser light from a solid laser light source (such as YAG or semiconductor laser).

The temperature of baking of the exposed photoresist film is usually 50 to 200° C., and preferably 70 to 150° C.

The development of the baked photoresist film is usually carried out using a development apparatus. The alkaline developer used may be any one of various alkaline aqueous solution used in the art. Generally, an aqueous solution of tetramethylammonium hydroxide or (2-hydroxyethyl)trimethylammonium hydroxide (commonly known as “choline”) is often used. After development, the photoresist pattern formed is preferably washed with ultrapure water, and the remained water on the photoresist pattern and the substrate is preferably removed.

The photoresist composition of the present invention provides a photoresist pattern showing good Line Width Roughness (LWR), and therefore, the photoresist composition of the present invention is suitable for ArF excimer laser lithography, KrF excimer laser lithography, ArF immersion lithography, EUV (extreme ultraviolet) lithography, EUV immersion lithography and EB (electron beam) lithography. Further, the photoresist composition of the present invention can especially be used for ArF immersion lithography, EUV lithography and EB lithography. Furthermore, the photoresist composition of the present invention can also be used in double imaging.

### EXAMPLES

The present invention will be described more specifically by Examples, which are not construed to limit the scope of the present invention.

The “%” and “part(s)” used to represent the content of any component and the amount of any material used in the following examples and comparative examples are on a weight basis unless otherwise specifically noted. The weight-average molecular weight of any material used in the following examples is a value found by gel permeation chromatography [HLC-8120GPC Type, Column (Three Columns): TSKgel Multipore HXL-M with a guard column, manufactured by TOSOH CORPORATION, Solvent: tetrahydrofuran, Flow rate: 1.0 mL/min., Detector: RI detector, Column temperature: 40° C., Injection volume: 100 μL] using standard polystyrene as a standard reference material. The contents of the structural units in the obtained resin were calculated based on the results of liquid chromatography analysis of the amount of the unreacted monomers in the reaction mixture.

In Resin Synthesis Examples, Monomer (B), Monomer (C), Monomer (D), Monomer (E), Monomer (F), Monomer (G), Monomer (H), Monomer (I), Monomer (J) and Monomer (K) represented by the followings were used.

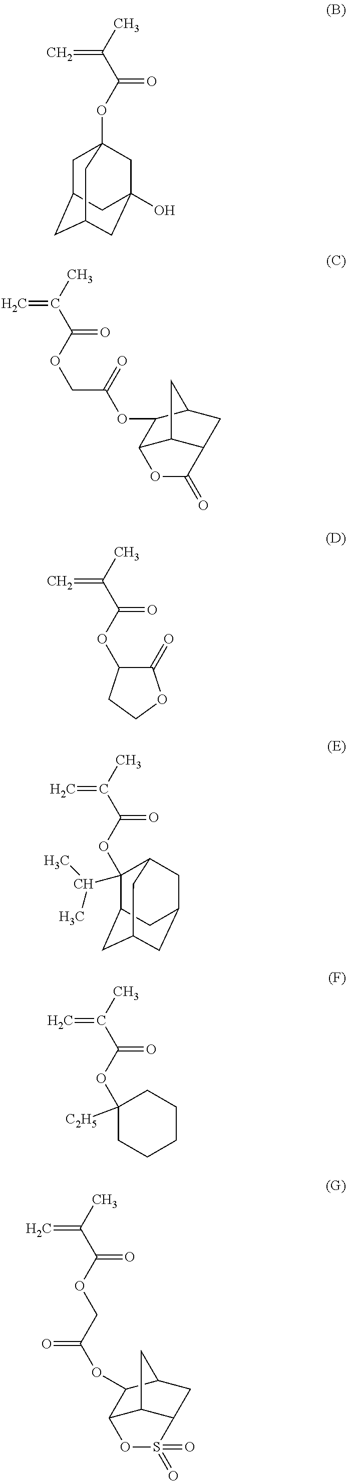

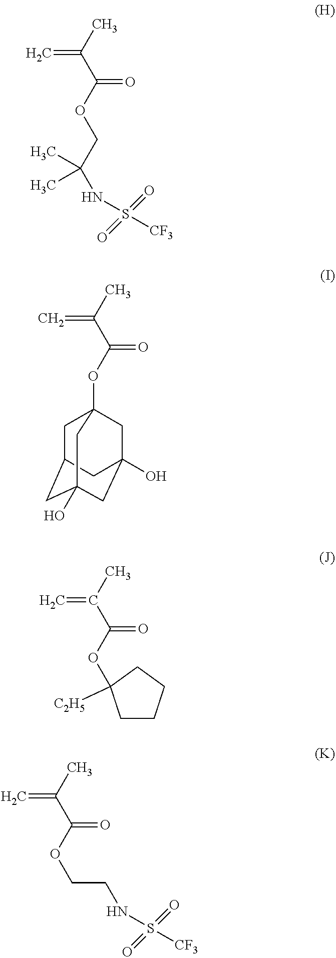

### Resin Synthesis Example 1

Monomer (E), Monomer (F), Monomer (I), Monomer (G), Monomer (H) and Monomer (D) were mixed in a molar ratio of 44/9/8/19/7/13 (Monomer (E)/Monomer (F)/Monomer (I)/Monomer (G)/Monomer (H)/Monomer (D)), and 1,4-dioxane of which amount was 1.5 times part based on total parts of all monomers was added to prepare a solution. To the solution, 2,2′-azobisisobutyronitrile as an initiator in a ratio of 1 mol % based on all monomer molar amount and 2,2′-azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation. The precipitate was isolated and then washed three times with a mixture of methanol and water to obtain a copolymer having a weight-average molecular weight of about 7.6×10³ in a yield of 55%. This is called as Resin A1. Resin A1 contains the structural unit derived from Monomer (E), the structural unit derived from Monomer (F), the structural unit derived from Monomer (I), the structural unit derived from Monomer (G), the structural unit derived from Monomer (H) and the structural unit derived from Monomer (D). The molar ratio of the structural units in Resin A1 was 32.6/9.0/10.0/8.2/23.8/16.5 (structural unit derived from Monomer (E)/structural unit derived from Monomer (F)/structural unit derived from Monomer (I)/structural unit derived from Monomer (G)/structural unit derived from Monomer (H)/structural unit derived from Monomer (D)).

### Resin Synthesis Example 2

Monomer (E), Monomer (F), Monomer (I), Monomer (H), Monomer (C) and Monomer (D) were mixed in a molar ratio of 44/9/8/7/19/13 (Monomer (E)/Monomer (F)/Monomer (I)/Monomer (H)/Monomer (C)/Monomer (D)), and 1,4-dioxane of which amount was 1.5 times part based on total parts of all monomers was added to prepare a solution. To the solution, 2,2′-azobisisobutyronitrile as an initiator in a ratio of 1 mol % based on all monomer molar amount and 2,2′-azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation. The precipitate was isolated and then washed three times with a mixture of methanol and water to obtain a copolymer having a weight-average molecular weight of about 7.2×10³ in a yield of 64%. This is called as Resin A2. Resin A2 contains the structural unit derived from Monomer (E), the structural unit derived from Monomer (F), the structural unit derived from Monomer (I), the structural unit derived from Monomer (H), the structural unit derived from Monomer (C) and the structural unit derived from Monomer (D). The molar ratio of the structural units in Resin A2 was 32.5/9.1/10.0/8.3/23.7/16.5 (structural unit derived from Monomer (E)/structural unit derived from Monomer (F)/structural unit derived from Monomer (I)/structural unit derived from Monomer (H)/structural unit derived from Monomer (C)/structural unit derived from Monomer (D)).

### Resin Synthesis Example 3

Monomer (E), Monomer (F), Monomer (B), Monomer (H), Monomer (C) and Monomer (D) were mixed in a molar ratio of 44/9/8/7/19/13 (Monomer (E)/Monomer (F)/Monomer (I)/Monomer (H)/Monomer (C)/Monomer (D)), and 1,4-dioxane of which amount was 1.5 times part based on total parts of all monomers was added to prepare a solution. To the solution, 2,2′-azobisisobutyronitrile as an initiator in a ratio of 1 mol % based on all monomer molar amount and 2,2′-azobis(2,4-dimethylvaleronitrile) as an initiator in a ratio of 3 mol % based on all monomer molar amount were added, and the obtained mixture was heated at 75° C. for about 5 hours. The reaction mixture obtained was poured into a large amount of a mixture of methanol and water to cause precipitation. The precipitate was isolated and then washed three times with a mixture of methanol and water to obtain a copolymer having a weight-average molecular weight of about 7.4×10³ in a yield of 68%. This is called as Resin A3. Resin A3 contains the structural unit derived from Monomer (E), the structural unit derived from Monomer (F), the structural unit derived from Monomer (B), the structural unit derived from Monomer (H), the structural unit derived from Monomer (C) and the structural unit derived from Monomer (D). The molar ratio of the structural units in Resin A3 was 32.0/9.2/10.1/8.5/23.6/16.6 (structural unit derived from Monomer (E)/structural unit derived from Monomer (F)/structural unit derived from Monomer (B)/structural unit derived from Monomer (H)/structural unit derived from Monomer (C)/structural unit derived from Monomer (D)).

### Resin Synthesis Example 4

Monomer (D), Monomer (B) and Monomer (J) were mixed in a molar ratio of 25/25/50 (Monomer (D)/Monomer (B)/Monomer (J)), and 1,4-dioxane of which amount was 1.5 times part based on total parts of all monomers was added to prepare a solution. To the solution, 2,2′-azobisisobutyronitrile as an initiator in a ratio of 0.7 mol % based on all monomer molar amount and 2,2′-azobis(2,4-dimethylvaleronitrile) as an initiator in a ratio of 2.1 mol % based on all monomer molar amount were added, and the obtained mixture was heated at 70° C. for about 5 hours. The reaction mixture obtained was poured into a large amount of a mixture of methanol and water to cause precipitation. The precipitate was isolated and then washed three times with a mixture of methanol and water to obtain a copolymer having a weight-average molecular weight of about 1.2×10⁴ in a yield of 70%. This is called as Resin X1. Resin X1 contains the structural unit derived from Monomer (D), the structural unit derived from Monomer (B) and the structural unit derived from Monomer (J). The molar ratio of the structural units in Resin X1 was 25/25/50 (structural unit derived from Monomer (D)/structural unit derived from Monomer (B)/structural unit derived from Monomer (J)).

### Resin Synthesis Example 5

Monomer (D), Monomer (B), Monomer (J) and Monomer (K) were mixed in a molar ratio of 25/25/40/10 (Monomer (D)/Monomer (B)/Monomer (J)/Monomer (K)), and 1,4-dioxane of which amount was 1.5 times part based on total parts of all monomers was added to prepare a solution. To the solution, 2,2′-azobisisobutyronitrile as an initiator in a ratio of 0.7 mol % based on all monomer molar amount and 2,2′-azobis(2,4-dimethylvaleronitrile) as an initiator in a ratio of 2.1 mol % based on all monomer molar amount were added, and the obtained mixture was heated at 75° C. for about 5 hours. The reaction mixture obtained was poured into a large amount of a mixture of methanol and water to cause precipitation. The precipitate was isolated and then washed three times with a mixture of methanol and water to obtain a copolymer having a weight-average molecular weight of about 1.1×10⁴ in a yield of 68%. This is called as Resin X2. Resin X2 contains the structural unit derived from Monomer (D), the structural unit derived from Monomer (B), the structural unit derived from Monomer (J) and the structural unit derived from Monomer (K). The molar ratio of the structural units in Resin X2 was 25/25/40/10 (structural unit derived from Monomer (D)/structural unit derived from Monomer (B)/structural unit derived from Monomer (J)/structural unit derived from Monomer (K)).

### Examples 1 to 5 and Reference Example 1

### Resin

### Resin A1, A2, A3, X1, X2

### <Acid Generator>

### B1:

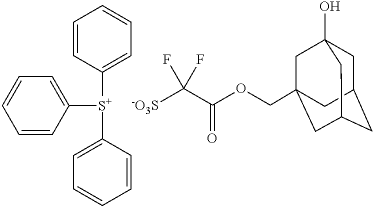

B2: tolydiphenylsulfonium perfluorobutanesulfonate

### <Quencher>

C1: 2,6-diisopropylaniline

### <Solvent>

S1: propylene glycol monomethyl ether acetate 265 parts

propylene glycol monomethyl ether 20 parts

2-heptanone 20 parts

γ-butyrolactone 3.5 parts

The following components were mixed and dissolved, further, filtrated through a fluorine resin filter having pore diameter of 0.2 μm, to prepare photoresist compositions.

Resin (kind and amount are described in Table 1)

Acid generator (kind and amount are described in Table 1)

Quencher (kind and amount are described in Table 1)

Solvent S1

TABLE 1

| | | Acid | | | |
|---|---|---|---|---|---|
| | Resin | generator | Quencher | | |
| | (kind/amount | (kind/amount | (kind/amount | PB | PEB |
| Ex. No. | (part)) | (part)) | (part)) | (° C.) | (° C.) |
| Ex. 1 | A1/10 | B1/0.70 | C1/0.065 | 100 | 90 |
| Ex. 2 | A2/10 | B1/0.70 | C1/0.065 | 100 | 90 |
| Ex. 3 | A3/10 | B1/0.70 | C1/0.065 | 100 | 90 |
| Ex. 4 | A2/10 | B1/0.70 | C1/0.065 | 100 | 90 |
| Ex. 5 | X1/8 | B1/0.70 | C1/0.065 | 100 | 90 |
| | X2/2 | | | | |
| Ref. Ex. 1 | X1/8 | B2/0.70 | C1/0.065 | 100 | 90 |
| | X2/2 | | | | |

Silicon wafers having a diameter of 12 inches were each coated with “ARC-29”, which is an organic anti-reflective coating composition available from Nissan Chemical Industries, Ltd., and then baked under the conditions: 205° C., 60 seconds, to form an organic anti-reflective coating having a thickness of 78 nm. Each of the photoresist compositions prepared as above was spin-coated over the anti-reflective coating so that the thickness of the resulting film became 85 nm after drying. The silicon wafers thus coated with the respective photoresist compositions were each prebaked on a direct hotplate at a temperature shown in column of “PB” of Table 1 for 60 seconds. Using an ArF excimer stepper for immersion exposure (“XT-1900Gi” manufactured by ASML, NA=1.35, ¾ Annular, X-Y deflection), each wafer thus formed with the respective photoresist film was subjected to contact hole pattern using a photomask for forming a contact hole pattern having a hole pitch of 100 nm and a hole diameter of 70 nm, with the exposure quantity being varied stepwise.

After the immersion exposure, each wafer was subjected to post-exposure baking on a hotplate at a temperature shown in column of “PEB” of Table 1 for 60 seconds and then to paddle development for 60 seconds with an aqueous solution of 2.38% tetramethylammonium hydroxide.

Each of line and space patterns developed on the organic anti-reflective coating substrate after the development was observed with a scanning electron microscope, the results of which are shown in Tables 2.

Effective Sensitivity (ES): It is expressed as the amount of exposure that the hole diameter of the contact hole pattern become 55 nm after exposure through a photomask for forming a contact hole pattern having a hole diameter of 70 nm and development.

CD uniformity (CDU): The photoresist patterns were obtained using a photomask for forming a contact hole pattern having a hole diameter of 70 nm at the exposure amount of ES. Each of patterns developed on the organic anti-reflective coating substrate after the development was observed with a scanning electron microscope. The hole diameter of the contact hole patterns was twenty four times measured and its average diameter was calculated. The average diameters of four hundred holes on the same wafer were respectively measured. When population was the average diameters of four hundred holes, the standard deviation was calculated. When the standard deviation is 2.00 nm or less, CDU is good and its evaluation is marked by “◯”, and when the standard deviation is more than 2.00 nm, CDU is bad and its evaluation is marked by “X”. Further, each of the standard deviations is also shown in parentheses in a column of “CDU”. The smaller the standard deviation is, the better CDU the photoresist pattern shows, and the better pattern profile is.

Focus margin (DOF): The photoresist patterns were obtained at the exposure amount of ES, with the focal point distance being varied stepwise. Each of contact hole patterns developed on the organic anti-reflective coating substrate after the development was observed and the focal point distances when the contact hole patterns of which hole diameter was 52.2 nm or more and 57.7 nm or less were obtained were measured and the difference between the max value of the focal point distance and the minimum value of the focal point distance was calculated. When the difference is 0.15 μm or more, DOF is good, and its evaluation is marked by “◯”, and when the difference is less than 0.15 μm, DOF is bad and its evaluation is marked by “X”. Further, each of the differences is also shown in parentheses in a column of “DOF”. The bigger the difference is, the better DOF the photoresist pattern shows, and the better pattern profile is.

TABLE 2

| Ex. No. | CDU | | DOF | |
|---|---|---|---|---|
| Ex. 1 | ◯ | (1.72) | ◯ | (0.21) |
| Ex. 2 | ◯ | (1.64) | ◯ | (0.21) |
| Ex. 3 | ◯ | (1.68) | ◯ | (0.21) |
| Ex. 4 | ◯ | (1.94) | ◯ | (0.15) |
| Ex. 5 | ◯ | (1.98) | ◯ | (0.15) |
| Ref. Ex. 1 | X | (2.48) | X | (0.12) |

The photoresist composition of the present invention provides a good photoresist pattern having good CDU and DOF.

What is claimed is:

1. A photoresist composition comprising a resin comprising a structural unit derived from a compound represented by the formula (I): 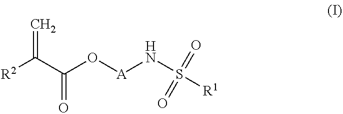
wherein R¹ represents a C1-C6 fluorine-containing alkyl group, R² represents a hydrogen atom or a methyl group, and A represents a C1-C10 divalent saturated hydrocarbon group, and being insoluble or poorly soluble in an aqueous alkali solution but becoming soluble in an aqueous alkali solution by the action of an acid, and an acid generator represented by the formula (II): 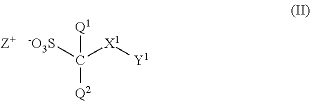
wherein Q¹ and Q² each independently represent a fluorine atom or a C1-C6 perfluoroalkyl group, X¹ represents a single bond or a C1-C17 divalent saturated hydrocarbon group in which one or more —CH₂— can be replaced by —O— or —CO—,
Y¹ represents a C1-C36 aliphatic hydrocarbon group which can have one or more substituents, a C3-C36 saturated cyclic hydrocarbon group which can have one or more substituents, or a C6-C36 aromatic hydrocarbon group which can have one or more substituents, and one or more —CH₂— in the aliphatic hydrocarbon group and the saturated cyclic hydrocarbon group can be replaced by —O— or —CO—, and Z⁺ represents an organic counter cation.

2. The photoresist composition according to claim 1, wherein X¹ is *—CO—O—X³— wherein X³ represents a single bond or a C1-C15 alkylene group and * represents a binding position to —C(Q¹)(Q²)-.

3. The photoresist composition according to claim 1, wherein Z⁺ is a triarylsulfonium cation.

4. The photoresist composition according to claim 1, which further comprises a basic compound.

5. A process for producing a photoresist pattern comprising the following steps (1) to (5):
(1) a step of applying the photoresist composition according to claim 1 on a substrate,
(2) a step of forming a photoresist film by conducting drying,
(3) a step of exposing the photoresist film to radiation,
(4) a step of baking the exposed photoresist film, and
(5) a step of developing the baked photoresist film with an alkaline developer, thereby forming a photoresist pattern.
